(19) United States
(12) Patent Application Publication
(10) Pub. No.: US 2023/0040424 A1
(43) Pub. Date: Feb. 9, 2023

(54) LOCALIZATION OF COMPONENTS IN A COMPONENT COMMUNITY

(71) Applicant: View, Inc., Milpitas, CA (US)

(72) Inventors: Sajith Kamalnath Gopinathanasari, Milpitas, CA (US); Jue Wang, San Jose, CA (US); Manoj Madan Kumar, Sunnyvale, CA (US); Nitesh Trikha, Pleasanton, CA (US); Aditya Dayal, Sunnyvale, CA (US); Ahmed Mustafa, Fremont, CA (US); Erik J. Christensen, Modesto, CA (US); Himay Rashmikant Shukla, Fremont, CA (US)

(21) Appl. No.: 17/791,507

(22) PCT Filed: Jan. 6, 2021
(86) PCT No.: PCT/US2021/012313

§ 371 Date: Jul. 7, 2022

Related U.S. Application Data
(63) Continuation-in-part of application No. 17/251,100, filed on Dec. 10, 2020.
Application No. 17/251,100 is a continuation-in-part of application No. 16/099,424, filed on Nov. 6, 2018, now Pat. No. 11,114,742.
Application No. PCT/US2021/012313 is a continuation-in-part of application No. 17/083,128, filed on Oct. 28, 2020.
Application No. 17/083,128 is a continuation of application No. 16/664,089, filed on Oct. 25, 2019, now Pat. No. 11,294,254.
Application No. 16/664,089 is a continuation-in-part of application No. PCT/US2019/030467, filed on May 2, 2019.
Application No. 16/664,089 is a continuation-in-part of application No. PCT/US2018/029460, filed on Apr. 25, 2018.
Application No. PCT/US2021/012313 is a continuation-in-part of application No. 29/652,869, filed on Dec. 22, 2020, now Pat. No. D954820.
Application No. 29/652,869 is a continuation-in-part of application No. 16/696,887, filed on Nov. 26, 2019, now Pat. No. 11,280,671.
Application No. 16/696,887 is a continuation of application No. 15/287,646, filed on Oct. 6, 2016, now Pat. No. 10,533,892.
Application No. 15/287,646 is a continuation-in-part of application No. 14/998,019, filed on Oct. 6, 2015, now Pat. No. 10,690,540.
Application No. PCT/US2021/012313 is a continuation-in-part of application No. 16/462,916, filed on May 21, 2019, now Pat. No. 11,137,659.
Application No. 16/462,916 is a continuation-in-part of application No. 16/082,793, filed on Sep. 6, 2018, now Pat. No. 10,935,864.
Application No. 16/462,916 is a continuation-in-part of application No. 14/951,410, filed on Nov. 24, 2015, now Pat. No. 10,303,035.
Application No. 14/951,410 is a continuation-in-part of application No. 14/401,081, filed on Nov. 13, 2014, now abandoned.
Application No. 14/951,410 is a continuation-in-part of application No. 14/468,778, filed on Aug. 26, 2014, now Pat. No. 9,442,341.
Application No. 14/468,778 is a continuation of application No. 13/479,137, filed on May 23, 2012, now Pat. No. 9,128,346.
Application No. 13/479,137 is a continuation of application No. 13/049,750, filed on Mar. 16, 2011, now Pat. No. 8,213,074.
Application No. 13/049,750 is a continuation-in-part of application No. 12/971,576, filed on Dec. 17, 2010, now Pat. No. 9,081,246.
Application No. 14/951,410 is a continuation-in-part of application No. 13/449,248, filed on Apr. 17, 2012, now abandoned.
(60) Provisional application No. 63/133,725, filed on Jan. 4, 2021.
(60) Provisional application No. 62/958,653, filed on Jan. 8, 2020.
(60) Provisional application No. 62/827,674, filed on Apr. 1, 2019.
(60) Provisional application No. 62/683,572, filed on Jun. 11, 2018.
(60) Provisional application No. 62/379,163, filed on Aug. 24, 2016.
(60) Provisional application No. 62/352,508, filed on Jun. 20, 2016.
(60) Provisional application No. 62/340,936, filed on May 24, 2016.
(60) Provisional application No. 62/333,103, filed on May 6, 2016.
(60) Provisional application No. 62/666,033, filed on May 2, 2018.
(60) Provisional application No. 62/490,457, filed on Apr. 26, 2017.
(60) Provisional application No. 62/506,514, filed on May 15, 2017.
(60) Provisional application No. 62/507,704, filed on May 17, 2017.
(60) Provisional application No. 62/523,606, filed on Jun. 22, 2017.
(60) Provisional application No. 62/607,618, filed on Dec. 19, 2017.
(60) Provisional application No. 62/370,174, filed on Aug. 2, 2016.
(60) Provisional application No. 62/305,892, filed on Mar. 9, 2016.
(60) Provisional application No. 62/085,179, filed on Nov. 26, 2014.
(60) Provisional application No. 62/248,181, filed on Oct. 29, 2015.
(60) Provisional application No. 61/652,021, filed on May 25, 2012.
(60) Provisional application No. 61/289,319, filed on Dec. 22, 2009.

(51) Int. Cl. G02F 1/163; G05B 19/042; G06F 3/044; G05B 15/02; H01L 27/32; G02F 1/15; B32B 17/10; E06B 9/24; G02F 1/155; G06F 3/041; H01L 51/52; H02J 50/80; H02J 50/20; G09F 19/22; G06F 3/14; G09G 3/38

(52) U.S. Cl. CPC G02F 1/163; G05B 19/0426; G06F 3/044; G05B 15/02; H01L 27/3234; G02F 1/15; B32B 17/10513; E06B 9/24; G02F 1/155; G06F 3/0412; H01L 51/52; H02J 50/80; H02J 50/20; G05B 19/042; G09F 19/227; G06F 3/1446; G09G 3/38; H04K 3/45

(57) ABSTRACT

The present disclosure describes one or more communities of components (e.g., comprising one or more sensors and/or transceivers) that are configured to automatically locate and/or self-locate their members. The community of components includes a plurality of stationary components, and may include at least one transitory component.

### PRIORITY APPLICATIONS

This application claims priority from U.S. Provisional Patent Application Ser. No. 63/133,725, filed Jan. 4, 2021, titled, “LOCALIZATION OF COMPONENTS IN A COMPONENT COMMUNITY,” from U.S. Provisional Patent Application Ser. No. 62/958,653, filed Jan. 8, 2020, titled, “Sensor Auto-location,” and from U.S. patent application Ser. No. 29/652,869, filed Dec. 22, 2020, titled “TRANSCEIVER TAG,” and is a Continuation-in-Part of (I) U.S. patent application Ser. No. 16/696,887, filed Nov. 26, 2019, titled, “MULTI-SENSOR DEVICE AND SYSTEM WITH A LIGHT DIFFUSING ELEMENT AROUND A PERIPHERY OF A RING OF PHOTOSENSORS AND AN INFRARED SENSOR,” that claims priority to U.S. patent application Ser. No. 15/287,646, filed Oct. 6, 2016, now U.S. Pat. No. 10,533,892, issued Jan. 14, 2020, titled, “MULTI-SENSOR DEVICE AND SYSTEM WITH A LIGHT DIFFUSING ELEMENT AROUND A PERIPHERY OF A RING OF PHOTOSENSORS AND AN INFRARED SENSOR,” that is a Continuation of U.S. patent application Ser. No. 14/998,019, filed Oct. 6, 2015, now U.S. Pat. No. 10,690,540, issued Jun. 23, 2020, titled, “MULTI-SENSOR HAVING A LIGHT DIFFUSING ELEMENT AROUND A PERIPHERY OF A RING OF PHOTOSENSORS,” (II) U.S. patent application Ser. No. 17/251,100, filed Dec. 10, 2020, titled “OPTICALLY SWITCHABLE WINDOWS FOR SELECTIVELY IMPEDING PROPAGATION OF LIGHT FROM AN ARTIFICIAL SOURCE,” that claims priority to U.S. patent application Ser. No. 16/099,424, filed Nov. 6, 2018, titled, “WINDOW ANTENNAS,” that is a National Stage of International Patent Application Serial No. PCT/US17/31106, filed May 4, 2017, that claims priority to, e.g., U.S. Provisional Patent Application Ser. No. 62/379,163, filed Aug. 24, 2017, titled, WINDOW ANTENNAS,” to U.S. Provisional Patent Application Ser. No. 62/352,508, filed Jun. 20, 2016, titled, WINDOW ANTENNAS,” to U.S. Provisional Patent Application Ser. No. 62/340,936, filed May 24, 2016, titled, WINDOW ANTENNAS,” and to U.S. Provisional Patent Application Ser. No. 62/333,103, filed May 6, 2016, titled, WINDOW ANTENNAS,” (III) U.S. patent application Ser. No. 16/946,947, filed Jul. 13, 2020, titled, “AUTOMATED COMMISSIONING OF CONTROLLERS IN A WINDOW NETWORK,” that is a Continuation of U.S. patent application Ser. No. 16/462,916, filed May 21, 2019, titled, “AUTOMATED COMMISSIONING OF CONTROLLERS IN A WINDOW NETWORK,” that is a Continuation of U.S. patent application Ser. No. 16/082,793, filed Sep. 6, 2018, titled, “METHOD OF COMMISSIONING ELECTROCHROMIC WINDOWS,” that is a National Stage of International Patent Application Serial No. PCT/US17/62634 filed Nov. 20, 2017, titled, “AUTOMATED COMMISSIONING OF CONTROLLERS IN A WINDOW NETWORK,” that claims priority to, e.g., U.S. Provisional Patent Application Ser. No. 62/551,649, filed Aug. 29, 2017, titled, “AUTOMATED COMMISSIONING OF CONTROLLERS IN A WINDOW NETWORK,” and to U.S. Provisional Patent Application Ser. No. 62/426,126, filed Nov. 23, 2016, titled, “AUTOMATED COMMISSIONING OF CONTROLLERS IN A WINDOW NETWORK,” (IV) U.S. patent application Ser. No. 16/980,305, filed Sep. 11, 2020, titled, “WIRELESSLY POWERED AND POWERING ELECTROCHROMIC WINDOWS,” that is a National Stage of International Patent Application Serial No. PCT/US19/22129 filed Mar. 13, 2019, titled, “WIRELESSLY POWERED AND POWERING ELECTROCHROMIC WINDOWS,” that claims priority to U.S. Provisional Patent Application Ser. No. 62/642,478, filed Mar. 13, 2018, titled, “WIRELESSLY POWERED AND POWERING ELECTROCHROMIC WINDOWS,” (V) U.S. patent application Ser. No. 15/727,258, filed Oct. 6, 2017 titled, “COMMISSIONING WINDOW NETWORKS,” that claims priority to, e.g., U.S. Provisional Patent Application Ser. No. 62/551,649, filed Aug. 29, 2017, titled, “AUTOMATED COMMISSIONING OF CONTROLLERS IN A WINDOW NETWORK,” and to U.S. Provisional Patent Application Ser. No. 62/426,126, filed Nov. 23, 2016, titled, “AUTOMATED COMMISSIONING OF CONTROLLERS IN A WINDOW NETWORK,” and (VI) U.S. patent application Ser. No. 17/083,128, filed Oct. 28, 2020, titled, “BUILDING NETWORK,” that is a Continuation of U.S. patent application Ser. No. 16/664,089, filed on Oct. 25, 2019, titled, “BUILDING NETWORK,” that is a National Stage of International Patent Application Serial No. PCT/US18/29460, filed Apr. 25, 2018, titled, “TINTABLE WINDOW SYSTEM FOR BUILDING SERVICES,” each of which and each of their families, is incorporated herein in its entirety by reference.

### BACKGROUND

A community of components may be placed at locations in an enclosure to analyze, detect and/or react to one or more of: data, temperature, humidity, sound, electromagnetic waves, position, distance, movement, speed, vibration, volatile compounds (VOCs), dust, light, glare, color, gases, and/or other aspects of the enclosure. A location of the component may be important to interpretation of the data it is connecting. A location of the component may be important to its calibration, replacement, maintenance, and/or repair. A lack of knowledge about a component's location, may make its calibration, replacement, maintenance, and/or repair difficult to perform. After placement of a community of components, locations of one or more of the components may be forgotten and/or may change. The location of the component may be determined and/or verified externally, e.g., by a person. The external localization of the component (e.g., transceiver and/or sensor) may be labor intensive, time consuming, and/or prone to (e.g., human) errors.

### SUMMARY

Various aspects disclosed herein alleviate at least in part one or more shortcomings related to localization of one or more components within an enclosure. Various aspects disclosed herein may relate to a community (e.g., assembly, group, and/or network) of components configured to analyze, detect and/or react to one or more of the characteristics of the enclosure. The components may be configured to react to various signals. The signals may comprise data (e.g., received). The signals may comprise a (e.g., digital) signal.

In another aspect, a method of locating a transceiver (e.g., a component comprising a transceiver), the method comprises: (a) using a coordinator transceiver to coordinate transmission of a plurality of signals by a plurality of transceivers that includes the coordinator transceiver, a first transceiver and a second transceiver; (b) using the first transceiver to transmit a first signal at a first time scheduled by the coordinator transceiver; and (c) using the second transceiver to sense the first signal at a second time to facilitate determination of a location of the first transceiver relative to the second transceiver.

In some embodiments, the coordinator transceiver coordinates transmission of a second signal by the second transceiver. In some embodiments, the second signal is utilized to determine the location of the second transceiver with respect to at least one other transceiver of the plurality of transceivers. In some embodiments, the at least one transceivers of the plurality of transceivers are stationary. In some embodiments, the at least two of the plurality of transceivers are stationary. In some embodiments, the plurality of transceivers comprises a third transceiver, and wherein the plurality of transceivers is located in the same plane. In some embodiments, the plurality of transceivers is not located in the same plane. In some embodiments, the first signal comprises identification data, time data, and/or location data. In some embodiments, the location data comprises a distance and/or an angle. In some embodiments, the distance comprises a distance between two transceivers. In some embodiments, the angle is an angle between two transceivers. In some embodiments, the time and/or location data is utilized to find a topology of the plurality of transceivers. In some embodiments, the topology comprises a two-dimensional topology. In some embodiments, the topology comprises a three-dimensional topology. In some embodiments, the plurality of transceivers comprises a transceiver having a known position. In some embodiments, the known position comprises a location within an enclosure and/or or third-party data. In some embodiments, establishing the known position utilizes a traveler. In some embodiments, the plurality of transceivers are stationary and are disposed in a facility, and wherein the plurality of transceivers are configured to locate (e.g., in real time) a transitory transceiver in the facility. In some embodiments, the transitory transceiver is configured to be (i) carried by an occupant of the facility, and/or (iii) attach to an asset disposed in the facility. In some embodiments, at least one transceiver of the plurality of transceivers is disposed in a housing comprising (i) sensors or (ii) a sensor and an emitter. In some embodiments, the housing is disposed in a fixture of a facility. In some embodiments, components of the housing are configured to facilitate adjustment of an environment of the facility in which the housing is disposed. In some embodiments, the plurality of transceivers is operatively coupled to a network of a facility in which the plurality of transceivers are disposed. In some embodiments, the network (i) is configured to facilitate power and data communication on a single cable, (ii) is configured to facilitate at least a third generation, fourth generation or fifth generation cellular communication, (iii) comprises at least a portion that is the first network installed in the facility, (iv) comprises at least a portion disposed in an envelope of the facility, (v) is configured to facilitate control of the facility, (vi) is configured to facilitate media communication, data communication, cellular communication, and power communication, (vii) comprises a coaxial cable, an optical cable, and/or a twisted wire and/or (vii) comprises wired and/or wireless communication. In some embodiments, the network is configured to facilitate adjusting an environment of the facility, adjust energy usage of the facility, generate safety alerts, and/or generate health alerts. In some embodiments, the network is configured to operatively couple to a control system. In some embodiments, the control system is configured to control at least one device in the facility comprising a tintable window, a media display, a speaker, lighting, an automatic door, an alarm system, a heater, a cooler, ventilation system, or a heating ventilation and air conditioning system (HVAC). In some embodiments, the automatic door is configured to open, shut and/or translate automatically. In some embodiments, the media display is operatively couple to the tintable window. In some embodiments, the media display comprises a transparent display. In some embodiments, the media display comprises a light emitting diode array comprising an organic light emitting diode array.

In another aspect, a non-transitory computer readable medium for locating a transceiver, which non-transitory computer readable medium comprises program instructions that, when executed by one or more processors, are configured cause the one or more processors to execute operations comprising: (a) using, or directing use of, a coordinator transceiver to coordinate transmission of a plurality of signals by a plurality of transceivers that includes the coordinator transceiver, a first transceiver and a second transceiver; (b) using, or directing use of, the first transceiver to transmit a first signal at a first time scheduled by the coordinator transceiver; and (c) using, or directing use of, the second transceiver to sense the first signal at a second time to facilitate determination of a location of the first transceiver relative to the second transceiver.

In some embodiments, the operations comprise using, or directing use of, the coordinator transceiver to coordinate transmission of a second signal by the second transceiver. In some embodiments, the operations comprise using, or directing use of, the second signal for determination of the location of the second transceiver with respect to at least one other transceiver of the plurality of transceivers. In some embodiments, at least one of the transceivers of the plurality of transceivers are stationary. In some embodiments, at least two of the plurality of transceivers are stationary. In some embodiments, the plurality of transceivers comprises a third transceiver, and wherein the plurality of transceivers is located in the same plane. In some embodiments, the plurality of transceivers is not located in the same plane. In some embodiments, the first signal comprises an identification data, a time data, and/or location data. In some embodiments, the location data comprises a distance and/or an angle. In some embodiments, the distance is a distance between two transceivers. In some embodiments, the angle is an angle between two transceivers. In some embodiments, the time and/or location data is utilized to find a topology of the plurality of transceivers. In some embodiments, the topology is a two-dimensional topology. In some embodiments, the topology is a three-dimensional topology. In some embodiments, the plurality of transceivers comprises a transceiver having a known position. In some embodiments, the known position comprises a location within an enclosure and/or third-party data. In some embodiments, establishing the known position utilizes a traveler. In some embodiments, the plurality of transceivers are stationary and are disposed in a facility, and wherein the plurality of transceivers are configured to locate (e.g., in real time) a transitory transceiver in the facility. In some embodiments, the transitory transceiver is configured to be (i) carried by an occupant of the facility, and/or (iii) attach to an asset disposed in the facility. In some embodiments, at least one transceiver of the plurality of transceivers is disposed in a housing comprising (i) sensors or (ii) a sensor and an emitter. In some embodiments, the housing is disposed in a fixture of a facility. In some embodiments, components of the housing are configured to facilitate adjustment of an environment of the facility in which the housing is disposed. In some embodiments, the one or more processors are operatively coupled to a network of a facility in which the plurality of transceivers are disposed. In some embodiments, the plurality of transceivers are operatively coupled to a network of a facility in which the plurality of transceivers are disposed. In some embodiments, the network (i) is configured to facilitate power and data communication on a single cable, (ii) is configured to facilitate at least a third generation, fourth generation or fifth generation cellular communication, (iii) comprises at least a portion that is the first network installed in the facility, (iv) comprises at least a portion disposed in an envelope of the facility, (v) is configured to facilitate control of the facility, (vi) is configured to facilitate media communication, data communication, cellular communication, and power communication, (vii) comprises a coaxial cable, an optical cable, and/or a twisted wire and/or (vii) comprises wired and/or wireless communication. In some embodiments, the network is configured to facilitate adjusting an environment of the facility, adjust energy usage of the facility, generate safety alerts, and/or generate health alerts. In some embodiments, the operations further comprise (i) adjusting, or directing adjustment of, an environment of the facility, (ii) adjusting, or directing adjustment of, (iii) adjusting, or directing adjustment of, energy usage of the facility, (iv) generating, or directing generation of, safety alerts, and/or (v) generating, or directing generation of, health alerts. In some embodiments, the network is configured to operatively couple to a control system. In some embodiments, the one or more processors are configured to operatively couple to, or are included in, the control system. In some embodiments, the operations further comprise controlling, or directing control of, at least one device in the facility comprising a tintable window, a media display, a speaker, lighting, an automatic door, an alarm system, a heater, a cooler, ventilation system, or a heating ventilation and air conditioning system (HVAC). In some embodiments, the automatic door is configured to open, shut and/or translate automatically. In some embodiments, the media display is operatively couple to the tintable window. In some embodiments, the media display comprises a transparent display. In some embodiments, the media display comprises a light emitting diode array comprising an organic light emitting diode array.

In another aspect, an apparatus for locating a transceiver, which apparatus comprises at least one controller comprising circuitry, the at least one controller is configure to: (a) operatively couple to a coordinator transceiver and to a plurality of transceivers; (b) use, or direct use of, a coordinator transceiver to coordinate transmission of a plurality of signals by a plurality of transceivers that includes the coordinator transceiver, a first transceiver and a second transceiver; (c) use, or direct use of, the first transceiver to transmit a first signal at a first time scheduled by the coordinator transceiver; and (d) use, or direct use of, the second transceiver to sense the first signal at a second time to facilitate determination of a location of the first transceiver relative to the second transceiver.

In some embodiments, the at least one controller is configured to use, or direct use of, the coordinator transceiver to coordinate transmission of a second signal by the second transceiver. In some embodiments, the at least one controller is configured to use, or direct use of, the second signal for determination of the location of the second transceiver with respect to at least one other transceiver of the plurality of transceivers. In some embodiments, at least one of the transceivers of the plurality of transceivers are stationary. In some embodiments, at least two of the plurality of transceivers are stationary. In some embodiments, the plurality of transceivers comprises a third transceiver, and wherein the plurality of transceivers is located in the same plane. In some embodiments, the plurality of transceivers is not located in the same plane. In some embodiments, the first signal comprises an identification data, a time data, and/or location data. In some embodiments, the location data comprises a distance and/or an angle. In some embodiments, the distance is a distance between two transceivers. In some embodiments, the angle is an angle between two transceivers. In some embodiments, the time and/or location data is utilized to find a topology of the plurality of transceivers. In some embodiments, the topology is a two-dimensional topology. In some embodiments, the topology is a three-dimensional topology. In some embodiments, the plurality of transceivers comprises a transceiver having a known position. In some embodiments, the known position comprises a location within an enclosure and/or third-party data. In some embodiments, establishing the known position utilizes a traveler. In some embodiments, the plurality of transceivers are stationary and are disposed in a facility, and wherein the plurality of transceivers are configured to locate (e.g., in real time) a transitory transceiver in the facility. In some embodiments, the transitory transceiver is configured to be (i) carried by an occupant of the facility, and/or (iii) attach to an asset disposed in the facility. In some embodiments, at least one transceiver of the plurality of transceivers is disposed in a housing comprising (i) sensors or (ii) a sensor and an emitter. In some embodiments, the housing is disposed in a fixture of a facility. In some embodiments, components of the housing are configured to facilitate adjustment of an environment of the facility in which the housing is disposed. In some embodiments, the at least one controller is operatively coupled to a network of a facility in which the plurality of transceivers are disposed. In some embodiments, the plurality of transceivers are operatively coupled to a network of a facility in which the plurality of transceivers are disposed. In some embodiments, the network (i) is configured to facilitate power and data communication on a single cable, (ii) is configured to facilitate at least a third generation, fourth generation or fifth generation cellular communication, (iii) comprises at least a portion that is the first network installed in the facility, (iv) comprises at least a portion disposed in an envelope of the facility, (v) is configured to facilitate control of the facility, (vi) is configured to facilitate media communication, data communication, cellular communication, and power communication, (vii) comprises a coaxial cable, an optical cable, and/or a twisted wire and/or (vii) comprises wired and/or wireless communication. In some embodiments, the network is configured to facilitate adjusting an environment of the facility, adjust energy usage of the facility, generate safety alerts, and/or generate health alerts. In some embodiments, the at least one controller is configured to (i) adjust, or direct adjustment of, an environment of the facility, (ii) adjust, or direct adjustment of, (iii) adjust, or direct adjustment of, energy usage of the facility, (iv) generate, or direct generation of, safety alerts, and/or (v) generate, or direct generation of, health alerts. In some embodiments, the network is configured to operatively couple to a control system. In some embodiments, the at least one controller is configured to operatively couple to, or is part of, the control system. In some embodiments, the at least one controller is configured to control, or direct control of, at least one device in the facility comprising a tintable window, a media display, a speaker, lighting, an automatic door, an alarm system, a heater, a cooler, ventilation system, or a heating ventilation and air conditioning system (HVAC). In some embodiments, the automatic door is configured to open, shut and/or translate automatically. In some embodiments, the media display is operatively couple to the tintable window. In some embodiments, the media display comprises a transparent display. In some embodiments, the media display comprises a light emitting diode array comprising an organic light emitting diode array.

In another aspect, a method of locating a transitory transceiver, the method comprises:

(a) transmitting at a first time a wireless signal from the transitory transceiver operatively coupled to a clock, which wireless signal is received by at least three stationary sensors at one or more second time, which at least three stationary sensors (I) have known locations in a facility and (II) are operatively coupled to at least three clocks that are synchronized among the at least three stationary sensors; (b) calculating one or more time differences between (i) the one or more second times and (ii) the first time, to generate one or more results; and (c) using the one or more results to locate the transitory transceiver with respect to the at least three stationary sensors.

In some embodiments, the at least three stationary sensors each (A) has a known location of the locations in the facility and (B) is operatively coupled to a clock of the at least three clocks. In some embodiments the facility comprises a building, a floor of a building, or a room of a building. In some embodiments the facility is a private facility. In some embodiments the at least three stationary sensors are included in at least three stationary transceivers (e.g., respectively), wherein the one or more time differences are one or more first time differences, wherein the one or more results are one or more first results, and wherein the method further comprises: (d) transmitting at one or more third times at least three wireless signals from the at least three stationary transceivers, which at least three wireless signals are received by the transitory transceiver at one or more fourth third times; (e) calculating one or more second time differences between (A) the one or more fourth times and (B) the one or more third times, to generate one or more second results; and (f) using the one or more first results and the one or more second results to re-synchronize the at least three clocks. In some embodiments each of the at least three stationary transceivers transmit a wireless signal of the at least three wireless signals. In some embodiments, synchronization of the at least three clocks corrects for a clock domain, a clock offset, and/or time drift for the at least three stationary transceivers. In some embodiments, synchronization of the at least three clocks corrects for a clock domain, a clock offset, and/or time drift for each of the at least three stationary transceivers. In some embodiments the synchronization further comprises synchronization of the clock of the transitory transceiver. In some embodiments using the one or more first results and the one or more second results is to re-synchronize each of the at least three clocks. In some embodiments the wireless signal is an electromagnetic signal that facilitates locating the transitory transceiver within at most about five, ten, or twenty centimeters. In some embodiments, the wireless signal is an electromagnetic signal comprising ultrawide radio waves. In some embodiments the transitory transceiver is a transitory radio. In some embodiments at least one of the at least three stationary sensors is an anchor (or is included in an anchor) whose location is independently verified. In some embodiments the transitory transceiver is configured to be (A) carried by a person or (B) attached to an asset. In some embodiments the transitory transceiver is operatively coupled to an accelerometer. In some embodiments the method further comprises detecting movement of the transitory transceiver using the accelerometer. In some embodiments, the transitory transceiver transmits the wireless signal when the accelerometer detects movement of the transitory transceiver. In some embodiments the transitory transceiver, the accelerometer, and/or the clock are disposed in a casing. In some embodiments the method further comprises providing power to the transitory transceiver using a rechargeable battery and/or power supply inlet. In some embodiments the method further comprises controlling transmission of the wireless signal by a controller disposed in the casing. In some embodiments the method further comprises using an antenna operatively coupled to the transitory transceiver, which antenna is disposed in the casing. In some embodiments the antenna is configured for ultra high and/or ultrawide band, radio frequency. In some embodiments the transceiver is configured for ultra high and/or ultrawide band, radio frequency. In some embodiments the method further comprises controlling transmission of the wireless signal by considering at least one characteristic of an intended carrier of the transitory transceiver. In some embodiments the intended carrier is verified as a carrier of the transitory transceiver. In some embodiments the at least one characteristic comprises animate or inanimate nature of the intended carrier. In some embodiments the at least one characteristic comprises function of the intended carrier. In some embodiments the at least one characteristic comprises average mobility speed of the intended carrier. In some embodiments the method further comprises updating firmware and/or software of the transitory transceiver and/or any circuitry operatively coupled thereto, wherein the transitory transceiver and the circuitry are disposed in a casing. In some embodiments the method further comprises signaling status of the transitory transceiver, energy status, and/or any circuitry operatively coupled to the transitory transceiver, wherein the transitory transceiver is disposed a casing, and wherein signaling the status is performed within the casing and/or using the casing. In some embodiments, the at least three stationary sensors are coupled to a network, wherein at least a portion of the network is disposed in the facility. In some embodiments at least a portion of the network is disposed in an envelope of the facility. In some embodiments the network comprises a wireless or a wired network. In some embodiments the network comprises a coaxial cable, an optical cable, and/or a twisted wire. In some embodiments the method further comprises using the network for media, cellular, and local communication. In some embodiments the method further comprises using the network for to communicate at least a third generation, fourth generation, or fifth generation wireless communication. In some embodiments the method further comprises using the network for adjusting an environment of the facility. In some embodiments, adjusting the environment comprises temperature, gas content, volatile organic content, particulate content, lighting, gas speed, and/or internal atmosphere refresh rate. In some embodiments the stationary sensor is disposed in a housing that comprises (A) at least two sensors or (B) a sensor and an emitter. In some embodiments the method further comprises using the network for adjusting an environment of the facility, adjust energy usage of the facility, generate safety alerts, and/or generate health alerts. In some embodiments the housing is disposed in a fixture of the facility. In some embodiments the housing is disposed in a ceiling, or in a framing portion. In some embodiments the framing portion is a window framing portion of a tintable window.

In another aspect, an apparatus for locating a transitory transceiver, the apparatus comprises at least one controller comprising circuitry, which at least one controller is configured to: (a) operatively couple to a transitory transceiver; (b) direct the transitory transceiver to transmit at a first time a wireless signal from the transitory transceiver operatively coupled to a clock, which wireless signal is received by at least three stationary sensors at one or more second time, which at least three stationary sensors (I) have known locations in a facility and (II) operatively coupled to at least three clocks that are synchronized among the at least three stationary sensors; (c) calculate, or direct calculation of, one or more time differences between (i) the one or more second times and (ii) the first time, to generate one or more results; and (d) use, or direct usage of, the one or more results to locate the transitory transceiver with respect to the at least three stationary sensors.

In some embodiments, the controller configured to direct the transitory transceiver to transmit the wireless signal is different than the controller configured to (A) calculate, or direct calculation of, one or more time differences and/or (B) use, or direct usage of, the one or more results to locate the transitory transceiver. In some embodiments the at least one controller is at least two controllers. In some embodiments the at least one controller comprises a microcontroller and a hierarchical control system. In some embodiments the at least three stationary sensors each (A) has a known location of the locations in the facility and (B) is operatively coupled to a clock of the at least three clocks. In some embodiments the facility comprises a building, a floor of a building, or a room of a building. In some embodiments the facility is a private facility. In some embodiments the at least three stationary sensors are included in at least three stationary transceivers (e.g., respectively, such that each sensor is included in a different transceiver), wherein the one or more time differences are one or more first time differences, wherein the one or more results are one or more first results, and wherein the at least one controller is further configured to: (d) operatively couple to the at least three stationary transceivers; (e) direct the at least three stationary transceivers to transmit at one or more third times at least three wireless signals, which at least three wireless signals are received by the transitory transceiver at one or more fourth third times; (e) calculate, or direct calculation of, one or more second time differences between (A) the one or more fourth times and (B) the one or more third times, to generate one or more second results; and (f) use, or direct usage of, the one or more first results and the one or more second results to re-synchronize the at least three clocks. In some embodiments the at least one controller is configured to direct each of the at least three stationary transceivers to transmit a wireless signal of the at least three wireless signals. In some embodiments synchronization of the at least three clocks corrects for a clock domain, a clock offset, and/or time drift for the at least three stationary transceivers. In some embodiments synchronization of the at least three clocks corrects for a clock domain, a clock offset, and/or time drift for each of the at least three stationary transceivers. In some embodiments the synchronization further comprises synchronization of the clock of the transitory transceiver. In some embodiments the at least one controller is configured to using, or direct usage of, the one or more first results and the one or more second results to re-synchronize each of the at least three clocks. In some embodiments the wireless signal is an electromagnetic signal that facilitates locating the transitory transceiver within at most about five, ten, or twenty centimeters. In some embodiments, the wireless signal is an electromagnetic signal comprising ultrawide radio waves. In some embodiments the transitory transceiver is a transitory radio. In some embodiments at least one of the at least three stationary sensors is (or is included in) an anchor whose location is independently verified. In some embodiments the transitory transceiver is configured to be (A) carried by a person or (B) attached to an asset. In some embodiments the transitory transceiver is operatively coupled to an accelerometer. In some embodiments the at least one controller is configured to (A) operatively coupled to the accelerometer, and (B) receive input from the accelerometer indicative of movement of the transitory transceiver. In some embodiments the at least one controller is configured to direct the transitory transceiver to transmit the wireless signal when the at least one controller receives input from the accelerometer indicative of movement of the transitory transceiver. In some embodiments the transitory transceiver, the accelerometer, and/or the clock are disposed in a casing. In some embodiments the transitory transceiver is configured to utilize a rechargeable battery and/or power supply inlet. In some embodiments a controller of the at least one controller is disposed in the casing. In some embodiments the at least one controller is operatively coupled to an antenna an antenna operatively coupled to the transitory transceiver, which antenna is disposed in the casing. In some embodiments the antenna is configured for ultra high and/or ultrawide band, radio frequency. In some embodiments the transceiver is configured for ultra high and/or ultrawide band, radio frequency. In some embodiments the at least one controller is configured to control, or direct control of, transmission of the wireless signal by considering at least one characteristic of an intended carrier of the transitory transceiver. In some embodiments the intended carrier is verified as a carrier of the transitory transceiver. In some embodiments the at least one characteristic comprises animate or inanimate nature of the intended carrier. In some embodiments the at least one characteristic comprises function of the intended carrier. In some embodiments the at least one characteristic comprises average mobility speed of the intended carrier. In some embodiments the at least one controller is configured to update, or direct update of, firmware and/or software of the transitory transceiver and/or any circuitry operatively coupled thereto, wherein the transitory transceiver and the circuitry are disposed in a casing. In some embodiments the at least one controller is configured to signal, or direct signaling of, status of the transitory transceiver, energy status, and/or any circuitry operatively coupled to the transitory transceiver, wherein the transitory transceiver is disposed a casing, and wherein signaling the status is performed within the casing and/or using the casing. In some embodiments, the at least three stationary sensors are coupled to a network, wherein at least a portion of the network is disposed in the facility. In some embodiments at least a portion of the network is disposed in an envelope of the facility. In some embodiments the network comprises a wireless or a wired network. In some embodiments the network comprises a coaxial cable, an optical cable, and/or a twisted wire. In some embodiments the network is configured for media, cellular, and local communication. In some embodiments the network if configured to facilitate at least a third generation, fourth generation, or fifth generation wireless communication. In some embodiments the network is configured to facilitate adjusting an environment of the facility. In some embodiments, adjusting the environment comprises temperature, gas content, volatile organic content, particulate content, lighting, gas speed, and/or internal atmosphere refresh rate. In some embodiments the stationary sensor is disposed in a housing that comprises (A) at least two sensors or (B) a sensor and an emitter. In some embodiments the network is configured to facilitate adjusting an environment of the facility, adjust energy usage of the facility, generate safety alerts, and/or generate health alerts. In some embodiments the housing is disposed in a fixture of the facility. In some embodiments the housing is disposed in a ceiling, or in a framing portion. In some embodiments the framing portion is a window framing portion of a tintable window.

In another aspect, a non-transitory computer readable medium for locating a transitory transceiver, the non-transitory computer readable medium, when read by one or more processors operatively coupled to the transitory transceiver, is configured to execute operations comprising: (b) directing the transitory transceiver to transmit at a first time a wireless signal from the transitory transceiver operatively coupled to a clock, which wireless signal is received by at least three stationary sensors at one or more second time, which at least three stationary sensors (I) have known locations in a facility and (II) operatively coupled to at least three clocks that are synchronized among the at least three stationary sensors; (c) calculating, or directing calculation of, one or more time differences between (i) the one or more second times and (ii) the first time, to generate one or more results; and (d) using, or directing usage of, the one or more results to locate the transitory transceiver with respect to the at least three stationary sensors.

In some embodiments, the processor configured to direct the transitory transceiver to transmit the wireless signal is different from the processor configured to (A) calculate, or direct calculation of, one or more time differences and/or (B) use, or direct usage of, the one or more results to locate the transitory transceiver. In some embodiments the one or more processors is at least two processors. In some embodiments the one or more processors are included in a microcontroller and in a hierarchical control system. In some embodiments the at least three stationary sensors each (A) has a known location of the locations in the facility and (B) is operatively coupled to a clock of the at least three clocks. In some embodiments the facility comprises a building, a floor of a building, or a room of a building. In some embodiments the facility is a private facility. In some embodiments the at least three stationary sensors are included (e.g., respectively) in at least three stationary transceivers, wherein the one or more time differences are one or more first time differences, wherein the one or more results are one or more first results, and wherein the one or more processors are configured to operatively couple to the at least three stationary transceivers, and wherein the operations comprise: (e) directing the at least three stationary transceivers to transmit at one or more third times at least three wireless signals, which at least three wireless signals are received by the transitory transceiver at one or more fourth third times; (e) calculating, or directing calculation of, one or more second time differences between (A) the one or more fourth times and (B) the one or more third times, to generate one or more second results; and (f) using, or directing usage of, the one or more first results and the one or more second results to re-synchronize the at least three clocks. In some embodiments the operations comprise directing each of the at least three stationary transceivers to transmit a wireless signal of the at least three wireless signals. In some embodiments synchronization of the at least three clocks corrects for a clock domain, a clock offset, and/or time drift for the at least three stationary transceivers. In some embodiments synchronization of the at least three clocks corrects for a clock domain, a clock offset, and/or time drift for each of the at least three stationary transceivers. In some embodiments the synchronization further comprises synchronization of the clock of the transitory transceiver. In some embodiments the operations comprise using, or directing usage of, the one or more first results and the one or more second results to re-synchronize each of the at least three clocks. In some embodiments the wireless signal is an electromagnetic signal that facilitates locating the transitory transceiver within at most about five, ten, or twenty centimeters. In some embodiments, the wireless signal is an electromagnetic signal comprising ultrawide radio waves. In some embodiments the transitory transceiver is a transitory radio. In some embodiments at least one of the at least three stationary sensors is (or is included in) an anchor whose location is independently verified. In some embodiments the transitory transceiver is configured to be (A) carried by a person or (B) attached to an asset. In some embodiments the transitory transceiver is operatively coupled to an accelerometer. In some embodiments the one or more processors are configured to operatively coupled to the accelerometer, and wherein the operations comprise receiving input from the accelerometer indicative of movement of the transitory transceiver. In some embodiments the operations comprise directing the transitory transceiver to transmit the wireless signal when the at least one controller receives input from the accelerometer indicative of movement of the transitory transceiver. In some embodiments the transitory transceiver, the accelerometer, and/or the clock are disposed in a casing. In some embodiments the transitory transceiver is configured to utilize a rechargeable battery and/or power supply inlet. In some embodiments a controller of the at least one controller is disposed in the casing. In some embodiments the at least one controller is operatively coupled to an antenna an antenna operatively coupled to the transitory transceiver, which antenna is disposed in the casing. In some embodiments the antenna is configured for ultra high and/or ultrawide band, radio frequency. In some embodiments the transceiver is configured for ultra high and/or ultrawide band, radio frequency. In some embodiments the at least one controller is configured to control, or direct control of, transmission of the wireless signal by considering at least one characteristic of an intended carrier of the transitory transceiver. In some embodiments the intended carrier is verified as a carrier of the transitory transceiver. In some embodiments the at least one characteristic comprises animate or inanimate nature of the intended carrier. In some embodiments the at least one characteristic comprises function of the intended carrier. In some embodiments the at least one characteristic comprises average mobility speed of the intended carrier. In some embodiments the operations comprise updating, or directing update of, firmware and/or software of the transitory transceiver and/or any circuitry operatively coupled thereto, wherein the transitory transceiver and the circuitry are disposed in a casing. In some embodiments the operations comprise signaling, or directing signaling of, status of the transitory transceiver, energy status, and/or any circuitry operatively coupled to the transitory transceiver, wherein the transitory transceiver is disposed a casing, and wherein signaling the status is performed within the casing and/or using the casing. In some embodiments, the at least three stationary sensors are coupled to a network, wherein at least a portion of the network is disposed in the facility. In some embodiments at least a portion of the network is disposed in an envelope of the facility. In some embodiments the network comprises a wireless or a wired network. In some embodiments the network comprises a coaxial cable, an optical cable, and/or a twisted wire. In some embodiments the network is configured for media, cellular, and local communication. In some embodiments the network if configured to facilitate at least a third generation, fourth generation, or fifth generation wireless communication. In some embodiments the network is configured to facilitate adjusting an environment of the facility. In some embodiments, adjusting the environment comprises temperature, gas content, volatile organic content, particulate content, lighting, gas speed, and/or internal atmosphere refresh rate. In some embodiments the stationary sensor is disposed in a housing that comprises (A) at least two sensors or (B) a sensor and an emitter. In some embodiments the network is configured to facilitate adjusting an environment of the facility, adjust energy usage of the facility, generate safety alerts, and/or generate health alerts. In some embodiments the housing is disposed in a fixture of the facility. In some embodiments the housing is disposed in a ceiling, or in a framing portion. In some embodiments the framing portion is a window framing portion of a tintable window.

In another aspect, a method of locating a transitory transceiver, the method comprises: (a) transmitting at a first time a wireless signal from the transitory transceiver operatively coupled to a clock, which wireless signal is received by at least three stationary transceivers at one or more second time, which at least three stationary transceivers (i) have at least three known locations in a facility and (ii) are operatively coupled to at least three clocks; (b) calculating one or more first time differences between (iii) the one or more second times and (iv) the first time, to generate one or more first results; (c) transmitting at one or more third times at least three wireless signals from the at least three stationary transceivers, which at least three wireless signals are received at one or more fourth times by the transitory transceiver; (d) calculating one or more second time differences between (v) the one or more fourth times and (vi) the one or more third times, to generate one or more second results; and (e) using the one or more first results and the one or more second results to (vii) locate the transitory transceiver and/or (viii) synchronize the at least three clocks.

In some embodiments, synchronization of the at least three clocks corrects for a clock domain, a clock offset, and/or time drift for the at least three stationary transceivers. In some embodiments synchronization of the at least three clocks corrects for a clock domain, a clock offset, and/or time drift for each of the at least three stationary transceivers. In some embodiments the synchronization further comprises synchronization of the clock of the transitory transceiver. In some embodiments the at least three stationary transceivers each (A) has a known location of the locations in the facility and (B) is operatively coupled to a clock of the at least three clocks. In some embodiments the facility comprises a building, a floor of a building, or a room of a building. In some embodiments the facility is a private facility. In some embodiments each of the at least three stationary transceivers transmit a wireless signal of the at least three wireless signals. In some embodiments using the one or more first results and the one or more second results is to synchronize and/or re-synchronize each of the at least three clocks. In some embodiments the wireless signal is an electromagnetic signal that facilitates locating the transitory transceiver within at most about five, ten, or twenty centimeters. In some embodiments, the wireless signal is an electromagnetic signal comprising ultrawide radio waves. In some embodiments the transitory transceiver is a transitory radio. In some embodiments at least one of the at least three stationary transceivers is an anchor whose location is independently verified. In some embodiments the transitory transceiver is configured to be (A) carried by a person or (B) attached to an asset. In some embodiments the transitory transceiver is operatively coupled to an accelerometer. In some embodiments the method further comprises detecting movement of the transitory transceiver using the accelerometer. In some embodiments, the transitory transceiver transmits the wireless signal when the accelerometer detects movement of the transitory transceiver. In some embodiments the transitory transceiver, the accelerometer, and/or the clock are disposed in a casing. In some embodiments the method further comprises providing power to the transitory transceiver using a rechargeable battery and/or power supply inlet. In some embodiments the method further comprises controlling transmission of the wireless signal by a controller disposed in the casing. In some embodiments the method further comprises using an antenna operatively coupled to the transitory transceiver, which antenna is disposed in the casing. In some embodiments the antenna is configured for ultra high and/or ultrawide band, radio frequency. In some embodiments the transceiver is configured for ultra high and/or ultrawide band, radio frequency. In some embodiments the method further comprises controlling transmission of the wireless signal by considering at least one characteristic of an intended carrier of the transitory transceiver. In some embodiments the intended carrier is verified as a carrier of the transitory transceiver. In some embodiments the at least one characteristic comprises animate or inanimate nature of the intended carrier. In some embodiments the at least one characteristic comprises function of the intended carrier. In some embodiments the at least one characteristic comprises average mobility speed of the intended carrier. In some embodiments the method further comprises updating firmware and/or software of the transitory transceiver and/or any circuitry operatively coupled thereto, wherein the transitory transceiver and the circuitry are disposed in a casing. In some embodiments the method further comprises signaling status of the transitory transceiver, energy status, and/or any circuitry operatively coupled to the transitory transceiver, wherein the transitory transceiver is disposed a casing, and wherein signaling the status is performed within the casing and/or using the casing. In some embodiments, the at least three stationary transceivers are coupled to a network, wherein at least a portion of the network is disposed in the facility. In some embodiments at least a portion of the network is disposed in an envelope of the facility. In some embodiments the network comprises a wireless or a wired network. In some embodiments the network comprises a coaxial cable, an optical cable, and/or a twisted wire. In some embodiments the method further comprises using the network for media, cellular, and local communication. In some embodiments the method further comprises using the network for to communicate at least a third generation, fourth generation, or fifth generation wireless communication. In some embodiments the method further comprises using the network for adjusting an environment of the facility. In some embodiments, adjusting the environment comprises temperature, gas content, volatile organic content, particulate content, lighting, gas speed, and/or internal atmosphere refresh rate. In some embodiments the stationary transceiver is disposed in a housing that comprises at least two sensors or a sensor and an emitter. In some embodiments the method further comprises using the network for adjusting an environment of the facility, adjust energy usage of the facility, generate safety alerts, and/or generate health alerts. In some embodiments the housing is disposed in a fixture of the facility. In some embodiments the housing is disposed in a ceiling, or in a framing portion. In some embodiments the framing portion is a window framing portion of a tintable window.

In another aspect, an apparatus for locating a transitory transceiver, the apparatus comprises at least one controller comprising circuitry, which at least one controller is configured to: (a) operatively couple to the transitory transceiver, and to at least three stationary transceivers; (b) direct the transitory transceiver to transmit at a first time a wireless signal, which transitory transceiver is operatively coupled to a clock, which wireless signal is received by the at least three stationary transceivers at one or more second time, which at least three stationary transceivers (i) have at least three known locations in a facility and (ii) are operatively coupled to at least three clocks; (c) calculate, or direct calculation of, one or more first time differences between (iii) the one or more second times and (iv) the first time, to generate one or more first results; (d) direct the at least three stationary transceivers to transmit at one or more third times at least three wireless signals, which at least three wireless signals are received at one or more fourth times by the transitory transceiver; (e) calculate, or direct calculation of, one or more second time differences between (v) the one or more fourth times and (vi) the one or more third times, to generate one or more second results; and (f) use, or direct usage of, the one or more first results and the one or more second results to (vii) locate the transitory transceiver and/or (viii) synchronize the at least three clocks.

In some embodiments, synchronization of the at least three clocks corrects for a clock domain, a clock offset, and/or time drift for the at least three stationary transceivers. In some embodiments, synchronization of the at least three clocks corrects for a clock domain, a clock offset, and/or time drift for each of the at least three stationary transceivers. In some embodiments the synchronization further comprises synchronization of the clock of the transitory transceiver. In some embodiments the controller configured to direct the transitory transceiver to transmit the wireless signal is different than the controller configured to (A) calculate, or direct calculation of, one or more time differences and/or (B) use, or direct usage of, the one or more results to locate the transitory transceiver. In some embodiments the at least one controller is at least two controllers. In some embodiments the at least one controller comprises a microcontroller and a hierarchical control system. In some embodiments the at least three stationary transceivers each (A) has a known location of the locations in the facility and (B) is operatively coupled to a clock of the at least three clocks. In some embodiments the facility comprises a building, a floor of a building, or a room of a building. In some embodiments the facility is a private facility. In some embodiments the at least one controller is configured to direct each of the at least three stationary transceivers to transmit a wireless signal of the at least three wireless signals. In some embodiments the at least one controller is configured to using, or direct usage of, the one or more first results and the one or more second results to synchronize and/or re-synchronize each of the at least three clocks. In some embodiments the wireless signal is an electromagnetic signal that facilitates locating the transitory transceiver within at most about five, ten, or twenty centimeters. In some embodiments, the wireless signal is an electromagnetic signal comprising ultrawide radio waves. In some embodiments the transitory transceiver is a transitory radio. In some embodiments at least one of the at least three stationary transceivers is an anchor whose location is independently verified. In some embodiments the transitory transceiver is configured to be (A) carried by a person or (B) attached to an asset. In some embodiments the transitory transceiver is operatively coupled to an accelerometer. In some embodiments the at least one controller is configured to (A) operatively coupled to the accelerometer, and (B) receive input from the accelerometer indicative of movement of the transitory transceiver. In some embodiments the at least one controller is configured to direct the transitory transceiver to transmit the wireless signal when the at least one controller receives input from the accelerometer indicative of movement of the transitory transceiver. In some embodiments the transitory transceiver, the accelerometer, and/or the clock are disposed in a casing. In some embodiments the transitory transceiver is configured to utilize a rechargeable battery and/or power supply inlet. In some embodiments a controller of the at least one controller is disposed in the casing. In some embodiments the at least one controller is operatively coupled to an antenna an antenna operatively coupled to the transitory transceiver, which antenna is disposed in the casing. In some embodiments the antenna is configured for ultra high and/or ultrawide band, radio frequency. In some embodiments the transceiver is configured for ultra high and/or ultrawide band, radio frequency. In some embodiments the at least one controller is configured to control, or direct control of, transmission of the wireless signal by considering at least one characteristic of an intended carrier of the transitory transceiver. In some embodiments the intended carrier is verified as a carrier of the transitory transceiver. In some embodiments the at least one characteristic comprises animate or inanimate nature of the intended carrier. In some embodiments the at least one characteristic comprises function of the intended carrier. In some embodiments the at least one characteristic comprises average mobility speed of the intended carrier. In some embodiments the at least one controller is configured to update, or direct update of, firmware and/or software of the transitory transceiver and/or any circuitry operatively coupled thereto, wherein the transitory transceiver and the circuitry are disposed in a casing. In some embodiments the at least one controller is configured to signal, or direct signaling of, status of the transitory transceiver, energy status, and/or any circuitry operatively coupled to the transitory transceiver, wherein the transitory transceiver is disposed a casing, and wherein signaling the status is performed within the casing and/or using the casing. In some embodiments, the at least three stationary transceivers are coupled to a network, wherein at least a portion of the network is disposed in the facility. In some embodiments at least a portion of the network is disposed in an envelope of the facility. In some embodiments the network comprises a wireless or a wired network. In some embodiments the network comprises a coaxial cable, an optical cable, and/or a twisted wire. In some embodiments the network is configured for media, cellular, and local communication. In some embodiments the network if configured to facilitate at least a third generation, fourth generation, or fifth generation wireless communication. In some embodiments the network is configured to facilitate adjusting an environment of the facility. In some embodiments, adjusting the environment comprises temperature, gas content, volatile organic content, particulate content, lighting, gas speed, and/or internal atmosphere refresh rate. In some embodiments the stationary transceiver is disposed in a housing that comprises at least two sensors or a sensor and an emitter. In some embodiments the network is configured to facilitate adjusting an environment of the facility, adjust energy usage of the facility, generate safety alerts, and/or generate health alerts. In some embodiments the housing is disposed in a fixture of the facility. In some embodiments the housing is disposed in a ceiling, or in a framing portion. In some embodiments the framing portion is a window framing portion of a tintable window.

In another aspect, a non-transitory computer readable medium for locating a transitory transceiver, the non-transitory computer readable medium, when read by one or more processors operatively coupled to the transitory transceiver and to at least three stationary transceivers, is configured to execute operations comprising: (a) directing the transitory transceiver to transmit at a first time a wireless signal, which transitory transceiver is operatively coupled to a clock, which wireless signal is received by the at least three stationary transceivers at one or more second time, which at least three stationary transceivers (i) have at least three known locations in a facility and (ii) are operatively coupled to at least three clocks; (c) calculating, or directing calculation of, one or more first time differences between (iii) the one or more second times and (iv) the first time, to generate one or more first results; (d) directing the at least three stationary transceivers to transmit at one or more third times at least three wireless signals, which at least three wireless signals are received at one or more fourth times by the transitory transceiver; (e) calculating, or directing calculation of, one or more second time differences between (v) the one or more fourth times and (vi) the one or more third times, to generate one or more second results; and (f) using, or directing usage of, the one or more first results and the one or more second results to (vii) locate the transitory transceiver and/or (viii) synchronize the at least three clocks.

In some embodiments, synchronization of the at least three clocks corrects for a clock domain, a clock offset, and/or time drift for the at least three stationary transceivers. In some embodiments, synchronization of the at least three clocks corrects for a clock domain, a clock offset, and/or time drift for each of the at least three stationary transceivers. In some embodiments the synchronization further comprises synchronization of the clock of the transitory transceiver. In some embodiments the processor configured to direct the transitory transceiver to transmit the wireless signal is different from the processor configured to (A) calculate, or direct calculation of, one or more time differences and/or (B) use, or direct usage of, the one or more results to locate the transitory transceiver. In some embodiments the one or more processors is at least two processors. In some embodiments the one or more processors are included in a microcontroller and in a hierarchical control system. In some embodiments the at least three stationary transceivers each (A) has a known location of the locations in the facility and (B) is operatively coupled to a clock of the at least three clocks. In some embodiments the facility comprises a building, a floor of a building, or a room of a building. In some embodiments the facility is a private facility. In some embodiments the operations comprise directing each of the at least three stationary transceivers to transmit a wireless signal of the at least three wireless signals. In some embodiments the operations comprise using, or directing usage of, the one or more first results and the one or more second results to synchronize and/or re-synchronize each of the at least three clocks. In some embodiments the wireless signal is an electromagnetic signal that facilitates locating the transitory transceiver within at most about five, ten, or twenty centimeters. In some embodiments, the wireless signal is an electromagnetic signal comprising ultrawide radio waves. In some embodiments the transitory transceiver is a transitory radio. In some embodiments at least one of the at least three stationary transceivers is an anchor whose location is independently verified. In some embodiments the transitory transceiver is configured to be (A) carried by a person or (B) attached to an asset. In some embodiments the transitory transceiver is operatively coupled to an accelerometer. In some embodiments the one or more processors are configured to operatively coupled to the accelerometer, and wherein the operations comprise receiving input from the accelerometer indicative of movement of the transitory transceiver. In some embodiments the operations comprise directing the transitory transceiver to transmit the wireless signal when the at least one controller receives input from the accelerometer indicative of movement of the transitory transceiver. In some embodiments the transitory transceiver, the accelerometer, and/or the clock are disposed in a casing. In some embodiments the transitory transceiver is configured to utilize a rechargeable battery and/or power supply inlet. In some embodiments a controller of the at least one controller is disposed in the casing. In some embodiments the at least one controller is operatively coupled to an antenna an antenna operatively coupled to the transitory transceiver, which antenna is disposed in the casing. In some embodiments the antenna is configured for ultra high and/or ultrawide band, radio frequency. In some embodiments the transceiver is configured for ultra high and/or ultrawide band, radio frequency. In some embodiments the at least one controller is configured to control, or direct control of, transmission of the wireless signal by considering at least one characteristic of an intended carrier of the transitory transceiver. In some embodiments the intended carrier is verified as a carrier of the transitory transceiver. In some embodiments the at least one characteristic comprises animate or inanimate nature of the intended carrier. In some embodiments the at least one characteristic comprises function of the intended carrier. In some embodiments the at least one characteristic comprises average mobility speed of the intended carrier. In some embodiments the operations comprise updating, or directing update of, firmware and/or software of the transitory transceiver and/or any circuitry operatively coupled thereto, wherein the transitory transceiver and the circuitry are disposed in a casing. In some embodiments the operations comprise signaling, or directing signaling of, status of the transitory transceiver, energy status, and/or any circuitry operatively coupled to the transitory transceiver, wherein the transitory transceiver is disposed a casing, and wherein signaling the status is performed within the casing and/or using the casing. In some embodiments, the at least three stationary transceivers are coupled to a network, wherein at least a portion of the network is disposed in the facility. In some embodiments at least a portion of the network is disposed in an envelope of the facility. In some embodiments the network comprises a wireless or a wired network. In some embodiments the network comprises a coaxial cable, an optical cable, and/or a twisted wire. In some embodiments the network is configured for media, cellular, and local communication. In some embodiments the network if configured to facilitate at least a third generation, fourth generation, or fifth generation wireless communication. In some embodiments the network is configured to facilitate adjusting an environment of the facility. In some embodiments, adjusting the environment comprises temperature, gas content, volatile organic content, particulate content, lighting, gas speed, and/or internal atmosphere refresh rate. In some embodiments the stationary transceiver is disposed in a housing that comprises at least two sensors or a sensor and an emitter. In some embodiments the network is configured to facilitate adjusting an environment of the facility, adjust energy usage of the facility, generate safety alerts, and/or generate health alerts. In some embodiments the housing is disposed in a fixture of the facility. In some embodiments the housing is disposed in a ceiling, or in a framing portion. In some embodiments the framing portion is a window framing portion of a tintable window.

In another aspect, an apparatus for wireless communication, the apparatus comprises: a transceiver; and a housing configured to enclose the transceiver, which housing has a first side portion that tapers in a first direction away from the housing, and a second side portion devoid of tapering in a second direction away from the housing, which second side portion is in a direction opposite to the first side portion, and which first direction is opposite to the second direction.

In some embodiments, the transceiver is configured to be detected by a stationary network of one or more sensors and/or transceivers. In some embodiments the stationary network of one or more sensors and/or transceivers is configured to (I) located the transceiver in real time, (II) located the transceiver to an accuracy of within at least about twenty centimeters or to a higher accuracy, (III) transmit and sense ultrawide radio waves, and/or (IV) operatively couple to a control system configured to control a facility in which the stationary network of one or more sensors and/or transceivers are disposed. In some embodiments the control system is configured to use, or direct usage of, Building Information Modeling to locate the transitory transceiver. In some embodiments the control of the facility includes control of an environment of the facility, energy usage of the facility, health related devices of the facility, and/or security related devices of the facility. In some embodiments control of the facility includes control of a tintable window of the facility. In some embodiments the tintable window is an electrochromic window. In some embodiments the stationary network is configured for transmission of communication and power on a cable. In some embodiments the stationary network of one or more sensors and/or transceivers comprise cabling, and at least a portion of the cabling is disposed in an envelope of a facility in which the stationary network of one or more sensors and/or transceivers are disposed. In some embodiments the stationary network of one or more sensors and/or transceivers comprise cabling, and at least a portion of the cabling constitutes the first network installed in the facility. In some embodiments the transceiver is configured to transmit and sense cellular communication configured for at least a third (3G), further (4G) or fifth (5G) generation cellular communication. In some embodiments the taper in the first side portion is symmetric along a tapering axis. In some embodiments the tapering axis comprises a mirror symmetry axis and/or a rotational symmetry axis. In some embodiments the rotational symmetry is a C2 rotational symmetry. In some embodiments the first side portion has a first blunt end having a first width. In some embodiments the second side portion has a second blunt end having a second width. In some embodiments the second width is larger than the first width. In some embodiments the first side portion and the second side portion are symmetric along a common symmetry axis. In some embodiments the common symmetry axis is a mirror, rotational, and/or tapering symmetry axis. In some embodiments the housing comprises portions that comprise different materials. In some embodiments the different materials include metal and an organic polymer. In some embodiments the metal is elemental metal or a metal alloy. In some embodiments, the metal comprises aluminum. In some embodiments the metal is an anodized aluminum and/or paint. In some embodiments the first side portion that tapers comprises metal. In some embodiments the first side portion that tapers is part of a chassis of the apparatus. In some embodiments the apparatus further comprises external paint. In some embodiments the paint covers a metallic portion of the housing. In some embodiments a portion of the housing that tapers is a thickness of the housing. In some embodiments the housing comprises two opposing sides that taper towards toward an end side of the housing. In some embodiments the end side of the housing comprises a hole configured for carrying, hanging, and/or externally securing the component. In some embodiments the apparatus comprises a front portion and an opposing back portion. In some embodiments the front portion and/or the back portion are non-tapered portions. In some embodiments the front portion and/or the back portion have at least one section that is configured to facilitate transmission of light therethrough. In some embodiments the light is transmitted by a light emitting diode. In some embodiments the front portion and/or the back portion comprise a material that facilitates transmission of light therethrough. In some embodiments the material is an organic polymer. In some embodiments the front portion and/or the back portion are configured to include a hole that facilitates transmission of light therethrough. In some embodiments the hole is covered by a material that facilitates transmission of the light therethrough. In some embodiments the light is a visible light.

In another aspect, a method of wireless communication, the method comprises: using a transceiver disposed in a housing configured to enclose the transceiver, which housing has a first side portion that tapers in a first direction away from the housing, and a second side portion devoid of tapering in a second direction away from the housing, which second side portion is in a direction opposite to the first side portion, and which first direction is opposite to the second direction.

In some embodiments, the transceiver is configured to be detected by a stationary network of one or more sensors and/or transceivers. In some embodiments the stationary network of one or more sensors and/or transceivers is configured to (I) located the transceiver in real time, (II) locate the transceiver to an accuracy of about 20 centimeters or to a higher accuracy, (III) transmit and sense ultrawide radio waves, and/or (IV) operatively couple to a control system configured to control a facility in which the stationary network of one or more sensors and/or transceivers are disposed. In some embodiments the method further comprises using Building Information Modeling to locate the transitory transceiver. In some embodiments controlling the facility includes controlling an environment of the facility, energy usage of the facility, health related devices of the facility, and/or security related devices of the facility. In some embodiments controlling the facility includes controlling a tintable window of the facility. In some embodiments the tintable window is an electrochromic window. In some embodiments the stationary network is configured for transmission of communication and power on a cable. In some embodiments the stationary network of one or more sensors and/or transceivers comprise cabling and at least a portion of the cabling is disposed in an envelope of a facility in which the stationary network of one or more sensors and/or transceivers are disposed. In some embodiments the stationary network of one or more sensors and/or transceivers comprise cabling, and at least a portion of the cabling constitutes the first network installed in the facility. In some embodiments the transceiver is configured to transmit and sense cellular communication configured for at least a third (3G), further (4G) or fifth (5G) generation cellular communication. In some embodiments the tapered portion is symmetric along a tapering axis. In some embodiments the tapering axis comprises a mirror symmetry axis and/or a rotational symmetry axis. In some embodiments the rotational symmetry is a C2 rotational symmetry. In some embodiments the first side portion has a first blunt end having a first width. In some embodiments the second side portion has a second blunt end having a second width. In some embodiments the second width is larger than the first width. In some embodiments the first side portion and the second side portion are symmetric along a common symmetry axis. In some embodiments the common symmetry axis is a mirror, rotational, and/or tarping symmetry axis. In some embodiments the housing comprises portions that comprise different materials. In some embodiments the different materials include metal and an organic polymer. In some embodiments the metal is elemental metal or a metal alloy. In some embodiments, the metal comprises aluminum. In some embodiments the metal is an anodized aluminum and/or paint. In some embodiments the first side portion that tapers comprises metal. In some embodiments the first side portion that tapers is part of a chassis of the apparatus. In some embodiments the method further comprises external paint. In some embodiments the paint covers a metallic portion of the housing. In some embodiments a portion of the housing that tapers is a thickness of the housing. In some embodiments the housing comprises two opposing sides that taper towards toward an end side of the housing. In some embodiments an end side of the housing comprises a hole configured for carrying, hanging, and/or externally securing the component. In some embodiments the apparatus comprises a front portion and an opposing back portion. In some embodiments the front portion and/or the back portion are non-tapered portions. In some embodiments the front portion and/or the back portion have at least one section that is configured to facilitate transmission of light therethrough. In some embodiments the light is transmitted by a light emitting diode. In some embodiments the front portion and/or the back portion comprise a material that facilitates transmission of light therethrough. In some embodiments the material is an organic polymer. In some embodiments the front portion and/or the back portion are configured to include a hole that facilitates transmission of light therethrough. In some embodiments the hole is covered by a material that facilitates transmission of the light therethrough. In some embodiments the light is a visible light.

In another aspect, an apparatus for wireless communication, the apparatus comprises at least one controller comprising circuitry, which at least one controller is configured to: operatively couple to a transceiver disposed in the apparatus; and direct the transceiver to transmit and/or receive the wireless communication, which apparatus comprises a housing configured to enclose the transceiver, and, which housing has a first side portion that tapers in a first direction away from the housing, and a second side portion devoid of tapering in a second direction away from the housing, which second side portion is in a direction opposite to the first side portion, and which first direction is opposite to the second direction.

In some embodiments, the transceiver is configured to be detected by a stationary network of one or more sensors and/or transceivers. In some embodiments the stationary network of one or more sensors and/or transceivers is configured to (I) located the transceiver in real time, (II) locate the transceiver to an accuracy of about 20 centimeters or to a higher accuracy, (III) transmit and sense ultrawide radio waves, and/or (IV) operatively couple to a control system configured to control a facility in which the stationary network of one or more sensors and/or transceivers are disposed. In some embodiments the at least one controller is configured to use, or direct usage of, Building Information Modeling to locate the transitory transceiver. In some embodiments controlling the facility includes controlling an environment of the facility, energy usage of the facility, health related devices of the facility, and/or security related devices of the facility. In some embodiments controlling the facility includes controlling a tintable window of the facility. In some embodiments the tintable window is an electrochromic window. In some embodiments the stationary network is configured for transmission of communication and power on a cable. In some embodiments the stationary network of one or more sensors and/or transceivers comprise cabling and at least a portion of the cabling is disposed in an envelope of a facility in which the stationary network of one or more sensors and/or transceivers are disposed. In some embodiments the stationary network of one or more sensors and/or transceivers comprise cabling, and at least a portion of the cabling constitutes the first network installed in the facility. In some embodiments the transceiver is configured to transmit and sense cellular communication configured for at least a third (3G), further (4G) or fifth (5G) generation cellular communication. In some embodiments the tapered portion is symmetric along a tapering axis. In some embodiments the tapering axis comprises a mirror symmetry axis and/or a rotational symmetry axis. In some embodiments the rotational symmetry is a C2 rotational symmetry. In some embodiments the first side portion has a first blunt end having a first width. In some embodiments the second side portion has a second blunt end having a second width. In some embodiments the second width is larger than the first width. In some embodiments the first side portion and the second side portion are symmetric along a common symmetry axis. In some embodiments the common symmetry axis is a mirror, rotational, and/or tarping symmetry axis. In some embodiments the housing comprises portions that comprise different materials. In some embodiments the different materials include metal and an organic polymer. In some embodiments the metal is elemental metal or a metal alloy. In some embodiments, the metal comprises aluminum. In some embodiments the metal is an anodized aluminum and/or paint. In some embodiments the first side portion that tapers comprises metal. In some embodiments the first side portion that tapers is part of a chassis of the apparatus. In some embodiments the apparatus further comprises external paint. In some embodiments the paint covers a metallic portion of the housing. In some embodiments a portion of the housing that tapers is a thickness of the housing. In some embodiments the housing comprises two opposing sides that taper towards toward an end side of the housing. In some embodiments an end side of the housing comprises a hole configured for carrying, hanging, and/or externally securing the component. In some embodiments the apparatus comprises a front portion and an opposing back portion. In some embodiments the front portion and/or the back portion are non-tapered portions. In some embodiments the front portion and/or the back portion have at least one section that is configured to facilitate transmission of light therethrough. In some embodiments the light is transmitted by a light emitting diode. In some embodiments the front portion and/or the back portion comprise a material that facilitates transmission of light therethrough. In some embodiments the material is an organic polymer. In some embodiments the front portion and/or the back portion are configured to include a hole that facilitates transmission of light therethrough. In some embodiments the hole is covered by a material that facilitates transmission of the light therethrough. In some embodiments the light is a visible light.

In another aspect, a non-transitory computer readable medium for wireless communication, the non-transitory computer readable medium, when read by one or more processors operatively coupled to a transceiver disposed in an apparatus, is configured to execute one or more operations comprising: directing the transceiver to transmit and/or receive the wireless communication, which apparatus comprises a housing configured to enclose the transceiver, and, which housing has a first side portion that tapers in a first direction away from the housing, and a second side portion devoid of tapering in a second direction away from the housing, which second side portion is in a direction opposite to the first side portion, and which first direction is opposite to the second direction.

In some embodiments, the transceiver is configured to be detected by a stationary network of one or more sensors and/or transceivers. In some embodiments the stationary network of one or more sensors and/or transceivers is configured to (I) located the transceiver in real time, (II) locate the transceiver to an accuracy of about 20 centimeters or higher accuracy, (III) transmit and sense ultrawide radio waves, and/or (IV) operatively couple to a control system configured to control a facility in which the stationary network of one or more sensors and/or transceivers are disposed. In some embodiments controlling the facility includes controlling an environment of the facility, energy usage of the facility, health related devices of the facility, and/or security related devices of the facility. In some embodiments controlling the facility includes controlling a tintable window of the facility. In some embodiments the tintable window is an electrochromic window. In some embodiments the stationary network is configured for transmission of communication and power on a cable. In some embodiments the stationary network of one or more sensors and/or transceivers comprise cabling and at least a portion of the cabling is disposed in an envelope of a facility in which the stationary network of one or more sensors and/or transceivers are disposed. In some embodiments the stationary network of one or more sensors and/or transceivers comprise cabling, and at least a portion of the cabling constitutes the first network installed in the facility. In some embodiments the transceiver is configured to transmit and sense cellular communication configured for at least a third (3G), further (4G) or fifth (5G) generation cellular communication. In some embodiments the tapering axis comprises a mirror symmetry axis and/or a rotational symmetry axis. In some embodiments the tapering axis comprises a mirror symmetry axis and/or a rotational symmetry axis. In some embodiments the rotational symmetry is a C2 rotational symmetry. In some embodiments the first side portion has a first blunt end having a first width. In some embodiments the second side portion has a second blunt end having a second width. In some embodiments, the second side portion has a second blunt end having a second width. In some embodiments, the second width is larger than the first width. In some embodiments the common symmetry axis is a mirror, rotational, and/or tarping symmetry axis. In some embodiments the housing comprises portions that comprise different materials. In some embodiments the different materials include metal and an organic polymer. In some embodiments the metal is elemental metal or a metal alloy. In some embodiments, the metal comprises aluminum. In some embodiments the metal is an anodized aluminum and/or paint. In some embodiments the first side portion that tapers comprises metal. In some embodiments the first side portion that tapers is part of a chassis of the apparatus. In some embodiments, the non-transitory computer readable medium, further comprises external paint. In some embodiments the paint covers a metallic portion of the housing. In some embodiments a portion of the housing that tapers is a thickness of the housing. In some embodiments the housing comprises two opposing sides that taper towards toward an end side of the housing. In some embodiments an end side of the housing comprises a hole configured for carrying, hanging, and/or externally securing the component. In some embodiments the apparatus comprises a front portion and an opposing back portion. In some embodiments the front portion and/or the back portion are non-tapered portions. In some embodiments the front portion and/or the back portion have at least one section that is configured to facilitate transmission of light therethrough. In some embodiments the light is transmitted by a light emitting diode. In some embodiments the front portion and/or the back portion comprise a material that facilitates transmission of light therethrough. In some embodiments the material is an organic polymer. In some embodiments the front portion and/or the back portion are configured to include a hole that facilitates transmission of light therethrough. In some embodiments the hole is covered by a material that facilitates transmission of the light therethrough. In some embodiments the light is a visible light.

In another aspect, the present disclosure provides systems, apparatuses (e.g., controllers), and/or non-transitory computer-readable medium (e.g., software) that implement any of the methods disclosed herein.

In another aspect, the present disclosure provides methods that use any of the systems, computer readable media, and/or apparatuses disclosed herein, e.g., for their intended purpose.

In another aspect, an apparatus comprises at least one controller that is programmed to direct a mechanism used to implement (e.g., effectuate) any of the method disclosed herein, which at least one controller is configured to operatively couple to the mechanism. In some embodiments, at least two operations (e.g., of the method) are directed/executed by the same controller. In some embodiments, at less at two operations are directed/executed by different controllers.

In another aspect, an apparatus comprises at least one controller that is configured (e.g., programmed) to implement (e.g., effectuate) any of the methods disclosed herein. The at least one controller may implement any of the methods disclosed herein. In some embodiments, at least two operations (e.g., of the method) are directed/executed by the same controller. In some embodiments, at less at two operations are directed/executed by different controllers.

In another aspect, a system comprises at least one controller that is programmed to direct operation of at least one another apparatus (or component thereof), and the apparatus (or component thereof), wherein the at least one controller is operatively coupled to the apparatus (or to the component thereof). The apparatus (or component thereof) may include any apparatus (or component thereof) disclosed herein. The at least one controller may be configured to direct any apparatus (or component thereof) disclosed herein. The at least one controller may be configured to operatively couple to any apparatus (or component thereof) disclosed herein. In some embodiments, at least two operations (e.g., of the apparatus) are directed by the same controller. In some embodiments, at less at two operations are directed by different controllers.

In another aspect, a computer software product, comprising a non-transitory computer-readable medium in which program instructions are stored, which instructions, when read by at least one processor (e.g., computer), cause the at least one processor to direct a mechanism disclosed herein to implement (e.g., effectuate) any of the method disclosed herein, wherein the at least one processor is configured to operatively couple to the mechanism. The mechanism can comprise any apparatus (or any component thereof) disclosed herein. In some embodiments, at least two operations (e.g., of the apparatus) are directed/executed by the same processor. In some embodiments, at less at two operations are directed/executed by different processors.

In another aspect, the present disclosure provides a non-transitory computer-readable medium comprising machine-executable code that, upon execution by one or more processors, implements any of the methods disclosed herein. In some embodiments, at least two operations (e.g., of the method) are directed/executed by the same processor. In some embodiments, at less at two operations are directed/executed by different processors.

In another aspect, the present disclosure provides a non-transitory computer-readable medium comprising machine-executable code that, upon execution by one or more processors, effectuates directions of the controller(s) (e.g., as disclosed herein). In some embodiments, at least two operations (e.g., of the controller) are directed/executed by the same processor. In some embodiments, at less at two operations are directed/executed by different processors.

In another aspect, the present disclosure provides a computer system comprising one or more computer processors and a non-transitory computer-readable medium coupled thereto. The non-transitory computer-readable medium comprises machine-executable code that, upon execution by the one or more processors, implements any of the methods disclosed herein and/or effectuates directions of the controller(s) disclosed herein.

The content of this summary section is provided as a simplified introduction to the disclosure and is not intended to be used to limit the scope of any invention disclosed herein or the scope of the appended claims.

The disclosure provided herein regarding device(s) can be applicable to respective component(s). The disclosure provided herein regarding firmware can be applicable to software.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

These and other features and embodiments will be described in more detail with reference to the drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

Novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “Fig.” and “Figs.” herein), of which:

FIG. 1 schematically depicts a control system architecture and perspective view of an enclosure;

FIG. 2 delineates examples of components and possible uses thereof;

FIG. 3 schematically depicts a perspective view of an enclosure;

FIG. 4 schematically depicts a network coupled to components in various enclosures;

FIG. 5 schematically depicts component communities;

FIG. 6 schematically depicts a community of components;

FIG. 7 schematically depicts a community of components;

FIG. 8 schematically depicts a community of components;

FIG. 9 schematically depicts a community of components;

FIG. 10 schematically depicts a community of components;

FIG. 11 schematically depicts a community of components;

FIG. 12 depicts a flowchart;

FIG. 13 depicts a flowchart;

FIG. 14 depicts a flow chart and component communities;

FIGS. 15A-15B schematically depicts signal related time lapse diagrams;

FIG. 16 schematically depicts signal related time lapse diagram;

FIGS. 17A-17B schematically depicts signal related time lapse diagrams;

FIG. 18 schematically depicts signal related time lapse diagram;

FIG. 19 schematically depicts signal related time lapse diagrams;

FIG. 20 schematically depicts a community of components;

FIG. 21A schematically depicts signal related time lapse diagrams, and FIG. 21B schematically depicts various components;

FIG. 22A schematically depicts signal related time lapse diagrams, and FIG. 22B schematically depicts a community of components;

FIGS. 23A-23B schematically depicts component communities;

FIG. 24 schematically depicts component communities;

FIG. 25 schematically depicts component communities;

FIGS. 26A-26B schematically depicts component communities;

FIG. 27 schematically depicts a processing system;

FIG. 28 schematically depicts an electrochromic construct;

FIGS. 29A-29B schematically depicts integrated glass units;

FIG. 30A schematically depicts a perspective view of a portion of a transitory component, with an enlarged portion of area A shown, and FIG. 30B schematically depicts a perspective view of a portion of a transitory component from the opposite side to that shown in FIG. 30A, with an enlarged portion of area B shown;

FIG. 31 schematically depicts a partially exploded perspective view of a transitory component;

FIG. 32 schematically depicts various views of a transitory component;

FIG. 33 schematically depicts electronic circuitry for a stationary component (e.g., an anchor);

FIG. 34 schematically depicts electronic circuitry for a transitory component;

FIG. 35A schematically depicts components in relation to a time of flight diagram, and FIG. 35B schematically depicts components in relation to a time difference of arrival diagram;

FIG. 36 schematically depicts a signal and its portions;

FIG. 37 schematically depicts operations and apparatuses relating to control;

FIG. 38 depicts a flow chart relating to tag localization;

FIG. 39 depicts electronic circuitry for a transitory component; and

FIG. 40 schematically depicts various views of a transitory component and portions thereof.

The figures and components therein may not be drawn to scale. Various components of the figures described herein may not be drawn to scale.

### DETAILED DESCRIPTION

While various embodiments of the invention are shown, and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

Terms such as “a”, “an” and “the” are not intended to refer to only a singular entity but include the general class of which a specific example may be used for illustration. The terminology herein is used to describe specific embodiments of the invention(s), but their usage does not delimit the invention(s).

When ranges are mentioned, the ranges are meant to be inclusive, unless otherwise specified. For example, a range between value 1 and value 2 is meant to be inclusive and include value 1 and value 2. The inclusive range will span any value from about value 1 to about value 2. The term “adjacent” or “adjacent to,” as used herein, includes ‘next to’, ‘adjoining’, ‘in contact with’, and ‘in proximity to.’

The term “operatively coupled” or “operatively connected” refers to a first mechanism that is coupled (or connected) to a second mechanism to allow the intended operation of the second and/or first mechanism. The coupling may comprise physical or non-physical coupling. The non-physical coupling may comprise signal induced coupling (e.g., wireless coupling).

An element (e.g., mechanism) that is “configured to” perform a function includes a structural feature that causes the element to perform this function. A structural feature may include an electrical feature, such as a circuitry or a circuit element. A structural feature may include an actuator. A structural feature may include a circuitry (e.g., comprising electrical or optical circuitry). Electrical circuitry may comprise one or more wires. Optical circuitry may comprise at least one optical element (e.g., beam splitter, mirror, lens and/or optical fiber). A structural feature may include a mechanical feature. A mechanical feature may comprise a latch, a spring, a closure, a hinge, a chassis, a support, a fastener, or a cantilever, and so forth. Performing the function may comprise utilizing a logical feature. A logical feature may include programming instructions. Programming instructions may be executable by at least one processor. Programming instructions may be stored or encoded on a medium accessible by one or more processors. Additionally, in the following description, the phrases “operable to,” “adapted to,” “configured to,” “designed to,” “programmed to,” or “capable of” may be used interchangeably where appropriate.

In some embodiments, an enclosure comprises an area defined by at least one structure. The at least one structure may comprise at least one wall. An enclosure may comprise and/or enclose one or more sub-enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure about 30%, 20%, 10%, 5%, or 1% of the walls(s). The wall(s) may comprise a floor, a ceiling or a side wall. The closable opening may be closed by at least one window or door. The enclosure may be at least a portion of a facility. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct. In some embodiments, an enclosure may be stationary and/or movable (e.g., a train, a plane, a ship, a vehicle, or a rocket).

In some embodiments, the enclosure encloses an atmosphere. The atmosphere may comprise one or more gases. The gases may include inert gases (e.g., argon or nitrogen) and/or non-inert gases (e.g., oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Certain disclosed embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring. One or more sensors can be deployed (e.g., installed) in an environment as part of installing the network and/or after installing the network. One or more transceivers can be deployed (e.g., installed) in an environment as part of installing the network and/or after installing the network.

In various embodiments, a network infrastructure supports a control system for one or more windows such as tintable (e.g., electrochromic) windows. The control system may comprise one or more controllers operatively coupled (e.g., directly or indirectly) to one or more windows. While the disclosed embodiments describe tintable windows (also referred to herein as “optically switchable windows,” or “smart windows”) such as electrochromic windows, the concepts disclosed herein may apply to other types of switchable optical devices comprising a liquid crystal device, an electrochromic device, suspended particle device (SPD), NanoChromics display (NCD), Organic electroluminescent display (OELD), suspended particle device (SPD), NanoChromics display (NCD), or an Organic electroluminescent display (OELD). The display element may be attached to a part of a transparent body (such as the windows).

The tintable window may be disposed in a (non-transitory) facility such as a building, and/or in a transitory facility (e.g., vehicle) such as a car, RV, buss, train, airplane, helicopter, ship, or boat.

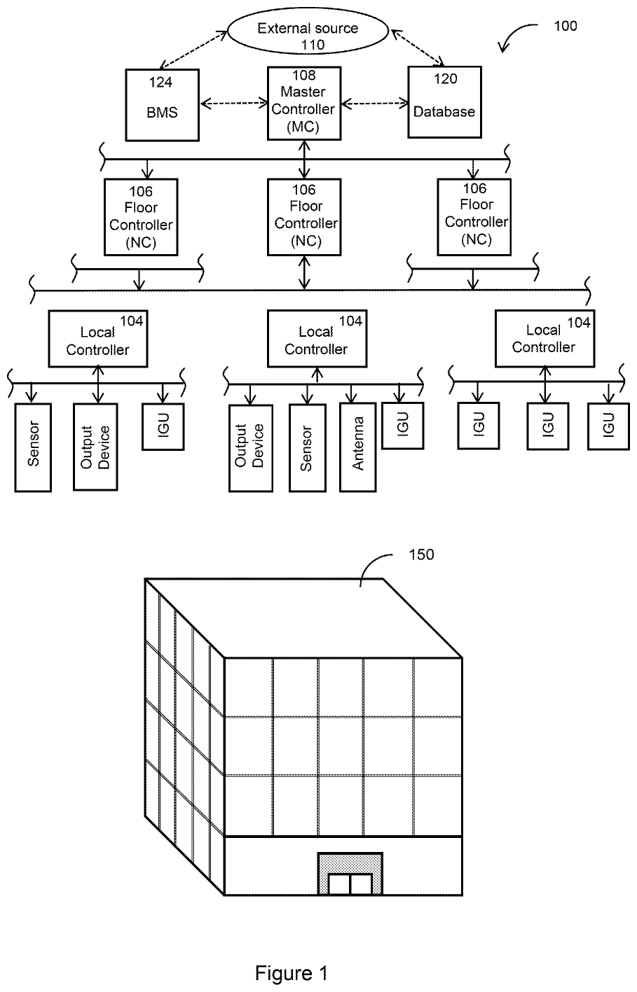

In some embodiments, one or more components may be disposed in or on a fixed in space enclosure. In some embodiments, one or more components may be mobile. An enclosure may comprise a portion of a building (e.g., having a geographical location, e.g., having a municipal address). A building may be a residential building and/or a commercial building. An enclosure may comprise and/or enclose one or more sub-enclosures. An enclosure may include a room, a lobby, hall, a duct, a foyer, an attic, a basement, a balcony (e.g., inner or outer balcony), a stairwell, a corridor, an elevator shaft, a mezzanine, a penthouse, a garage, a porch (e.g., enclosed porch), a terrace (e.g., enclosed terrace), and/or a cafeteria. An enclosure may include a floor and/or a level. An enclosure may include one or more elements. An element may comprise interior facing wall, exterior facing wall, ceiling, floor, window, entrance, door, opening, beam, stair, facade, molding, mullion, or transom. The enclosure may be stationary or movable. In some embodiments, one or more components are disposed in or on a moveable enclosure (e.g., a train, a plane, a ship, a vehicle, or a rocket). FIG. 1 shows an example of a stationary enclosure that is a schematic representation of a building 101.

In some embodiments, an enclosure comprises one or more sensors (e.g., as part of one or more transceivers, e.g., respectively). An enclosure can comprise at least one wall that defines the enclosure. The at least one wall may comprise metal (e.g., steel), clay, stone, plastic, glass, plaster (e.g., gypsum), polymer (e.g., polyurethane, styrene, or vinyl), asbestos, fiber-glass, concrete (e.g., reinforced concrete), wood, paper, or a ceramic. The at least one wall may comprise wire, bricks, blocks (e.g., cinder blocks), tile, drywall, or frame (e.g., steel frame).

In some embodiments, the enclosure comprises one or more openings. The one or more openings may be reversibly closable. The one or more openings may be permanently open. A fundamental length scale (FLS) of the one or more openings may be smaller relative to the fundamental length scale of the wall(s) that define the enclosure. A fundamental length scale may comprise a diameter of a bounding circle, a length, a width, or a height. A surface of the one or more openings may be smaller relative to the surface the wall(s) that define the enclosure. The opening surface may be a percentage of the total surface of the wall(s). For example, the opening surface can measure about 30%, 20%, 10%, 5%, or 1% of the walls(s). The wall(s) may comprise a floor, a ceiling or a side wall. The closable opening may be closed by at least one window or door. The enclosure may be at least a portion of a facility. The enclosure may comprise at least a portion of a building. The building may be a private building and/or a commercial building. The building may comprise one or more floors. The building (e.g., floor thereof) may include at least one of: a room, hall, foyer, attic, basement, balcony (e.g., inner or outer balcony), stairwell, corridor, elevator shaft, façade, mezzanine, penthouse, garage, porch (e.g., enclosed porch), terrace (e.g., enclosed terrace), cafeteria, and/or Duct.

In some embodiments, the enclosure encloses an atmosphere. The atmosphere may comprise one or more gases. The gases may include inert gases (e.g., argon or nitrogen) and/or non-inert gases (e.g., oxygen or carbon dioxide). The enclosure atmosphere may resemble an atmosphere external to the enclosure (e.g., ambient atmosphere) in at least one external atmosphere characteristic that includes: temperature, relative gas content, gas type (e.g., humidity, and/or oxygen level), debris (e.g., dust and/or pollen), and/or gas velocity. The enclosure atmosphere may be different from the atmosphere external to the enclosure in at least one external atmosphere characteristic that includes: temperature, relative gas content, gas type (e.g., humidity, and/or oxygen level), debris (e.g., dust and/or pollen), and/or gas velocity. For example, the enclosure atmosphere may be less humid (e.g., drier) than the external (e.g., ambient) atmosphere. For example, the enclosure atmosphere may contain the same (e.g., or a substantially similar) oxygen-to-nitrogen ratio as the atmosphere external to the enclosure. The velocity of the gas in the enclosure may be (e.g., substantially) similar throughout the enclosure. The velocity of the gas in the enclosure may be different in different portions of the enclosure (e.g., by flowing gas through to a vent that is coupled with the enclosure).

Some embodiments provide a network infrastructure in the enclosure (e.g., a facility such as a building). The network infrastructure is available for various purposes such as for providing communication and/or power services. The communication services may comprise high bandwidth (e.g., wireless and/or wired) communications services. The communication services can be to occupants of a facility and/or users outside the facility (e.g., building). The network infrastructure may work in concert with, or as a partial replacement of, the infrastructure of one or more cellular carriers. The network infrastructure can be provided in a facility that includes electrically switchable windows. Examples of components of the network infrastructure include a high speed backhaul. The network infrastructure may include at least one cable, switch, physical antenna, transceivers, sensor, transmitter, receiver, radio, processor and/or controller (that may comprise a processor). The network infrastructure may be operatively coupled to, and/or include, a wireless network. The network infrastructure may comprise wiring.

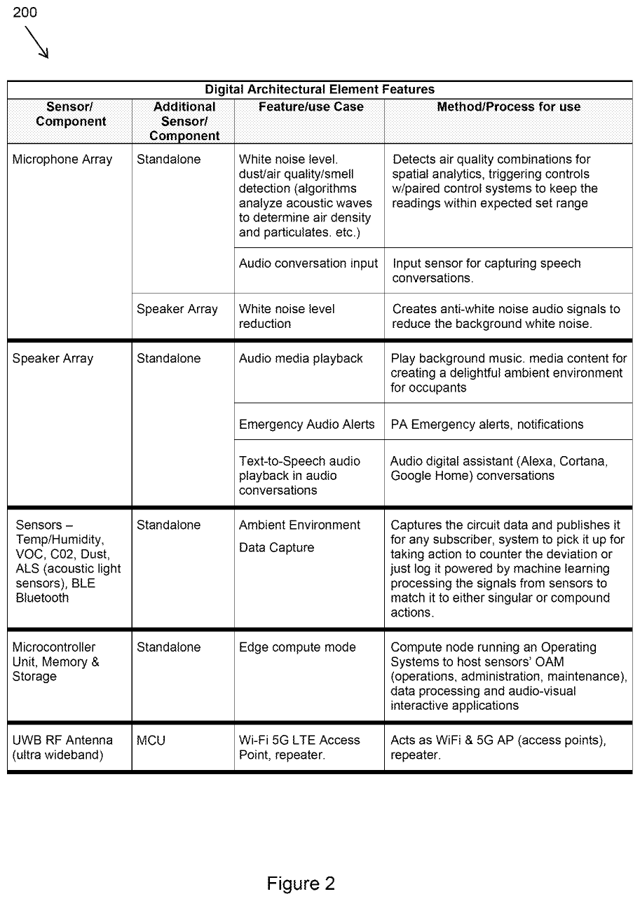

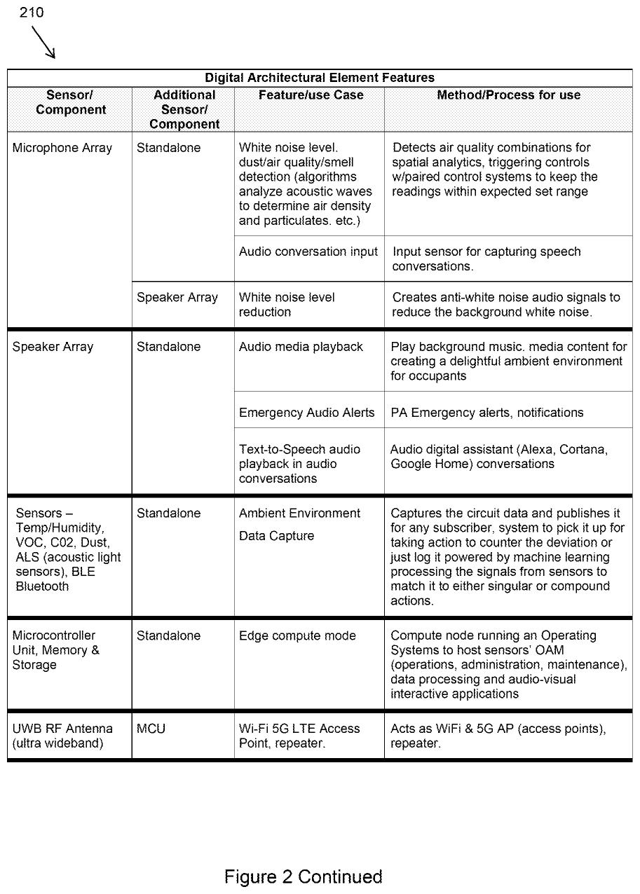

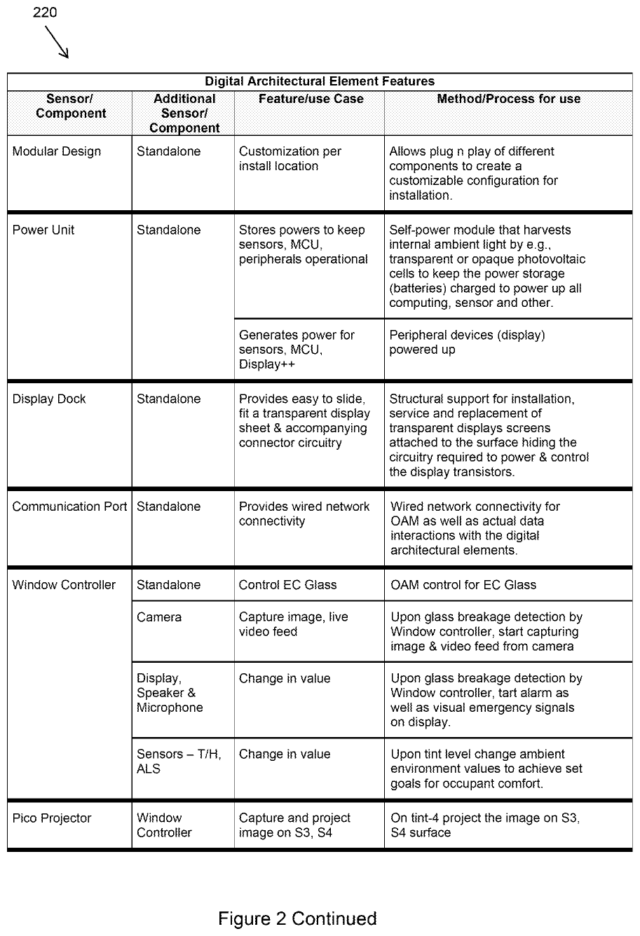

In some embodiments, the community of components includes specialized and/or non-specialized components. The specialized components may include anchor components, and/or coordinator components. The anchor component and the coordinator may be the same component or may be different components. The components may include sensors, actuators, transmitters, receivers, transceivers, processors, and/or controllers. The non-specialized components may be stationary or mobile. The coordinator component may be stationary or mobile. The coordinator component may be a virtual component (e.g., reside in a cloud), for example, when the coordinator component is pre-assigned to a community (e.g., network) of components. FIG. 2 delineates in tables 200, 210 and 220 examples of various types of components and some possible uses in an enclosure. Components may be configured to process, measure, analyze, detect and/or react to one or more of: data, temperature, humidity, sound, force, electromagnetic waves, position, distance, movement, acceleration, speed, vibration, volatile compounds (e.g., Volatile Organic Compounds abbreviated herein as “VOCs”), dust, light, glare, color, gas(es), and/or other aspects (e.g., characteristics) of the enclosure. Gases may be one or more of: carbon monoxide, carbon dioxide, water vapor (e.g., humidity), oxygen, radon, and hydrogen sulfide. The gas(es) may be present in an ambient environment. The gas(es) may comprise an inert gas. The VOCs and/or gasses may include compound(s) such as Nitric oxide (NO), nitrogen dioxide (NO₂), and/or formaldehyde).

One or more component may be coupled to (e.g., installed on, or in) an enclosure. For example, the one or more components may be coupled to elements of the enclosure. The element of the enclosure may include a wall, a door, a window, a door frame, a window frame, and/or a duct (e.g., air duct and/or an electrical duct). A component may be included in the element of the enclosure. A component may be coupled to an element directly or indirectly. Coupled to may include fastened to, glued to, contacted with, electronically connected to, wired to, and/or tied to. A component may be easy to remove from an element (e.g., removable), or it may be permanently coupled to the element (e.g., hard to remove from an element without causing damage to the element). Easy to remove may include reversibly removable. For example, the component may be attached and detached to the element reversibly, e.g., with no aesthetic and/or detectable damage to the element and/or to the component. A component may be configured to attach (e.g., reversibly) to one or more element of an enclosure. The component may be reversibly or irreversibly attached to the element of the enclosure. A component may be configured to fit into and/or snap onto an element (e.g., fit into and/or attached on to a mullion). At least two components may be coupled to the same circuit board. At least two components may be coupled to separate circuit boards. A component ensemble may comprise two or more components (e.g., one or more sensor and one or more processor). In some embodiments, a component ensemble is coupled (e.g., disposed in) to a single circuit board. Two or more components may be part of a larger system (e.g., a module). Examples of components and modules are provided in U.S. patent application Ser. No. 16/447,169, titled “SENSING AND COMMUNICATIONS UNIT FOR OPTICALLY SWITCHABLE WINDOW SYSTEMS,” filed Jun. 20, 2019, which is incorporated herein by reference in its entirety. A component may communicate with, or be operatively (e.g., functionally) coupled, to other components wirelessly or via one or more wires (e.g., one or more wireless camera may communicate with one or more processor via radio waves).

In some embodiments, a tintable window exhibits a (e.g., controllable and/or reversible) change in at least one optical property of the window, e.g., when a stimulus is applied. The optical property may comprise hue, or transmissivity. The hue may comprise color. The transmissivity may be of one or more wavelengths. The wavelengths may comprise ultraviolet, visible, or infrared wavelengths. The stimulus can include an optical, electrical and/or magnetic stimulus. For example, the stimulus can include an applied voltage and/or current. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through the window. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC). In some cases, tintable windows may be responsive to (e.g., and communicatively coupled to) one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows (e.g., with MEMS devices for tinting) are described in U.S. Pat. No. 10,359,681 B2, issued Jul. 23, 2019, filed May 15, 2015, titled “MULTI-PANE WINDOWS INCLUDING ELECTROCHROMIC DEVICES AND ELECTROMECHANICAL SYSTEMS DEVICES,” and incorporated herein by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

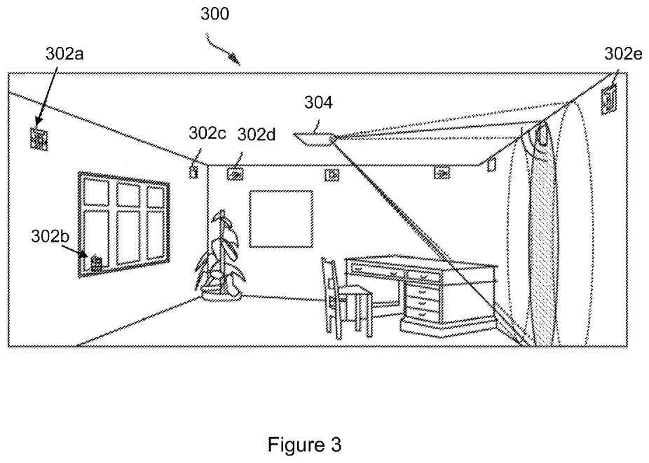

FIG. 3 shows an example of a community of components coupled to elements of an enclosure. In the example shown in FIG. 3, a community of components 302a-302e is coupled to elements of an enclosure 300 comprised of interior facing walls, a ceiling and a window. Component 302a can represent one or more gas sensor configured to measure, analyze, and/or provide indications of ambient CO₂ levels within an enclosure. Component 302b can represent one or more controller configured to control functions of one or more window. A window may comprise an optically switchable window, e.g., an electrochromic window. Examples of optically switchable windows, controllers, and methods of use of are provided in U.S. patent application Ser. No. 16/462,916, filed May 21, 2019, titled “AUTOMATED COMMISSIONING OF CONTROLLERS IN A WINDOW NETWORK,” which is incorporated herein by reference in its entirety. Component 302c can represent one or more sound sensor configured to measure, analyze, and/or provide indications of sound levels, present within the enclosure. Component 302d can represent one or more light sensor configured to measure, analyze, and/or provide indications of light and/or glare present within the enclosure. Component 302e can represent one or more transceiver configured to receive and transmit radio waves within the enclosure. Component 302f can represent one or more processor configured to process signals transmitted by one or more of components 302a-302e. Some community of components may have at least two components of the same type (e.g., two temperature sensors). For example, all members of the community of components may be of the same type. Some community of components may have at least two components of different type (e.g., a temperature sensor and a pressure sensor). For example, all members of the community of components may be of different types. In some embodiments, a single component may provide the functionality of two or more components (e.g., a force sensor that is used to detect vibration and movement). In some embodiments, components with functionalities other than disclosed herein may be used. In some embodiments, components may be provided on, or in, elements other than disclosed herein.

In some embodiments, a plurality of components (e.g., devices) may be operatively (e.g., communicatively) coupled to the control system. The plurality of components may be disposed in a facility (e.g., including a building and/or room). The control system may comprise the hierarchy of controllers. The components may comprise an emitter, a sensor, a transceiver, or a window (e.g., IGU). The component may be any component as disclosed herein. At least two of the plurality of components may be of the same type. For example, two or more IGUs may be coupled to the control system. At least two of the plurality of components may be of different types. For example, a sensor and an emitter may be coupled to the control system. At times the plurality of components may comprise at least 20, 50, 100, 500, 1000, 2500, 5000, 7500, 10000, 50000, 100000, or 500000 components. The plurality of components may be of any number between the aforementioned numbers (e.g., from 20 components to 500000 components, from 20 components to 50 components, from 50 components to 500 components, from 500 components to 2500 components, from 1000 components to 5000 components, from 5000 components to 10000 components, from 10000 components to 100000 components, or from 100000 components to 500000 components). For example, the number of windows in a floor may be at least 5, 10, 15, 20, 25, 30, 40, or 50. The number of windows in a floor can be any number between the aforementioned numbers (e.g., from 5 to 50, from 5 to 25, or from 25 to 50). At times the components may be in a multi-story building. At least a portion of the floors of the multi-story building may have components controlled by the control system (e.g., at least a portion of the floors of the multi-story building may be controlled by the control system). For example, the multi-story building may have at least 2, 8, 10, 25, 50, 80, 100, 120, 140, or 160 floors that are controlled by the control system. The number of floors (e.g., components therein) controlled by the control system may be any number between the aforementioned numbers (e.g., from 2 to 50, from 25 to 100, or from 80 to 160). The floor may be of an area of at least about 150 m², 250 m², 500 m², 1000 m², 1500 m², or 2000 square meters (m²). The floor may have an area between any of the aforementioned floor area values (e.g., from about 150 m² to about 2000 m², from about 150 m² to about 500 m², from about 250 m² to about 1000 m², or from about 1000 m² to about 2000 m²). The facility may be a residential building (e.g., a single family house).

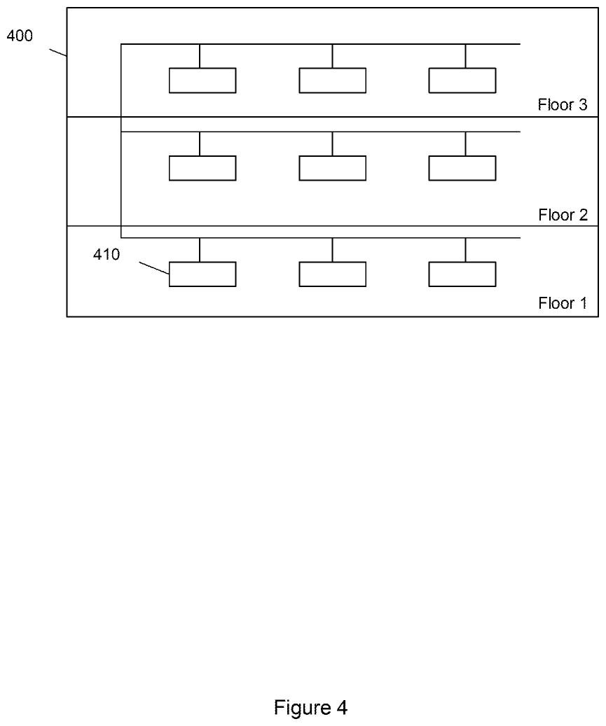

FIG. 4 shows a schematic example of a network within an enclosure. In the example of FIG. 4, the enclosure 400 is a building having floor 1, floor 2, and floor 3. The enclosure 400 includes a network 420 (e.g., wired network) that is provided to communicatively couple a community of components 410. In the example shown in FIG. 4, the three floors are sub enclosures within the enclosure 400.

Communication within a community of components that are coupled to a network may be coordinated by at least one component. The component may be part of the community. The component may comprise a controller. A controller may be located within an enclosure that houses the components being controlled by the controller, or the controller may be disposed outside of the enclosure that houses the components. For example, the controller may be located remotely relative to the enclosure housing the controller. The remote location may be physical or virtual (e.g., in the cloud). A controller may communicate with a community of components wirelessly of via one or more wires. A controller may include, but is not limited to, a processor, a local or distributed server, a building management system, a sensor management system, an environmental management system, a component controller, and/or a window controller. Examples of window controllers, and methods of use of are provided in U.S. patent application Ser. No. 16/096,557, titled “CONTROLLING OPTICALLY-SWITCHABLE DEVICES,” filed Oct. 25, 2018, which is incorporated herein by reference in its entirety. In some embodiments, the component comprises a controller. In some embodiments, the component may function as a controller. the controller may be temporarily assigned to the community of components. The controller may be permanently assigned to the community of the components (e.g., during the operative life of the community and of the controller).

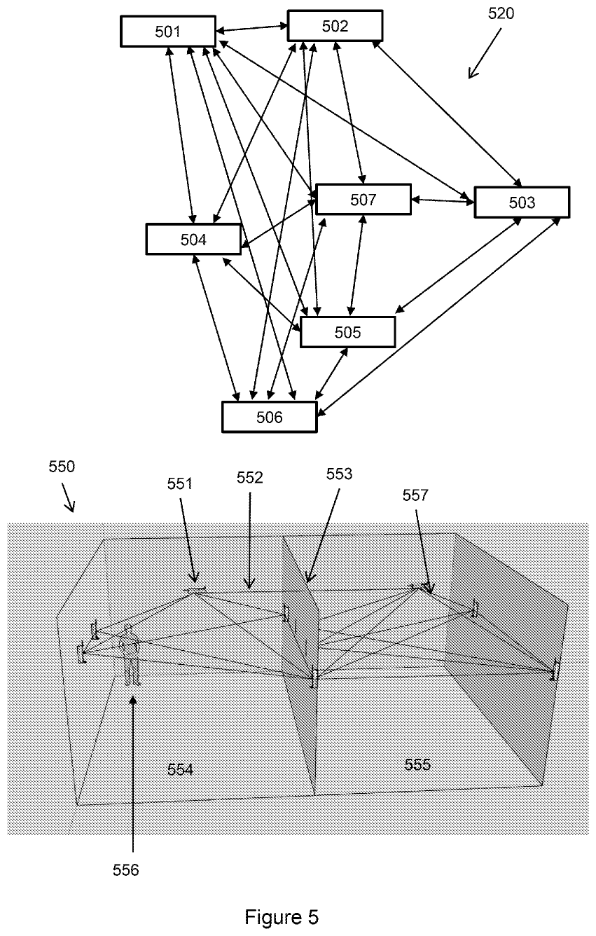

FIG. 5 shows an example of a topology of a community of components connected by a network. FIG. 5 shown an example of components 501-507 that are communicative coupled to form a communication network of components 520. The community of components can be configured to communicate via a network, and/or form a communication network. The arrows of the network shown in the example of FIG. 5, depict a possible (e.g., allowed) direction of communication (e.g., a direction of signal propagation). A network may be a wired and/or a wireless network. One or more component of a community of components may be powered by an onboard power source and/or powered by a remote power source. Power to one or more component of a community of components may be provided wirelessly (e.g., harvested energy) and/or via wires. The power may be from a renewable energy source (e.g., from a solar panel). The power may be from a non-renewable energy source (e.g., from a power plant using non-renewable energy).

FIG. 5 shows in 550 an example of a community of network disposed in an enclosure comprising two sub enclosures 554 and 555 (e.g., two rooms). Component 551 is part of the community of components disposed in a first sub-enclosure 554 (e.g., room) in which a person 556 is in, and Component 557 is part of the community of components disposed in a second sub-enclosure 555 (e.g., room) that is no occupied by any person. A wall 553 separates the two sub-enclosures in the example shown in FIG. 5., that also shows possible (e.g., allowed) communication routes between the components, schematically depicted as lines (e.g., 552). At times, the community of components may span more than one enclosure or sub-enclosures. For example, at least part of (e.g., all of) the components from the two sub-enclosures 554 and 555 constitute one community of components. At times, the community of components may span one enclosure or sub-enclosures. For example, at least part of (e.g., all of) the components from sub-enclosure 554 constitute one community of components, that excludes the components in enclosure 555. The physical fundamental length scale of the community of components may depend on the range of signal transmission and/or receipt by a coordinator of the community of components.

In some embodiments, a topology of a community of components is determined. The topology may be determined, at least in part, by a moving or stationary person and/or a machine. A traveler may be a moving person or machine. The topology may be absolutely determined or relatively determined. An absolute determination of the topology may require a traveler or a third party (e.g., third party accessory) to verify an absolute coordination of at least one of the community members. The absolute coordination may be determined based at least in part on global positioning system (GPS) coordinates. A relative determination of coordinates may include relative position of the components in relation to one another. A topology of a community of components may be determined from distances and/or angles measured between the community of components. A topology of a community of components may be determined by one or more processor configured to perform (or direct performance of) (I) measurements and/or analysis of: (I) time of flight of one or more signals propagating between the components (e.g., signal between component 502 and 507 of FIG. 5), (II) response times of components, (III) distances and/or angles between components. The one or more processors may be of a component or of two or more components. Measurements and/or analysis may be stored as data in one or more memory associated with, or operatively coupled to, one or more processor. The memory may be disposed in the enclosure, or outside of the enclosure. The memory may be disposed in the cloud, or in another facility (e.g., in another building). Measurements between a community of components may define constraints. The constraints may be utilized by at least one processor to determine a relative distance between the community members. The processor may utilize data stored in at least one memory. The processor may utilize one or more calculations (e.g., triangulation) to determine the relative position of the components. In one embodiment, once distances between at least three (3) components (e.g., anchor components) disposed in a common plane are determined, the positions of the other components of the community may be determined relative to the three components. Each of the three components may have associated Cartesian coordinates (e.g., X, Y, and Z). The three components may have at least two of their Cartesian coordinates different from each other (e.g., the three components are different in at least two dimensions). For example, the three components may have all three of their Cartesian coordinates different (e.g., the three components are different in three dimensions). As the number of components is increased, a topology's (e.g., relative) positional accuracy may improve. The topology may be displayed (e.g., on a user interface communicatively coupled to the community of components).

In some embodiments, one or more component of a community of components comprises a transceiver. In some embodiments, a transceiver may be configured transmit and receive one or more signals using a personal area network (PAN) standard, for example such as IEEE 802.15.4. In some embodiments, signals may comprise Bluetooth, Wi-Fi, or EnOcean signals (e.g., wide bandwidth). The one or more signals may comprise ultra-wide bandwidth (UWB) signals (e.g., having a frequency in the range from about 2.4 to about 10.6 Giga Hertz (GHz), or from about 7.5 GHz to about 10.6 GHz). An Ultra-wideband signal can be one having a fractional bandwidth greater than about 20%. An ultra-wideband signal can have a bandwidth greater than about 500 Mega Hertz (MHz). The one or more signals may use a very low energy level for short-range. Signals (e.g., having radio frequency) may employ a spectrum capable of penetrating solid structures (e.g., wall, door, and/or window). Low power may be of at most 25 milli Watts (mW), 50 mW, 75 mW, or 100 mW. Low power may be any value between the aforementioned values (e.g., from 25 mW to 100 mW, from 25 mW to 50 mW, or from 75 mW to 100 mW).

Signals may be transmitted at predetermined times and/or intervals. The predetermined time may be fixed or changing. The time may be predetermined, e.g., by a controller. FIG. 5 shows an example of signal transmission between components. In the example of FIG. 5, signals are sent over network 520 by a transmitter of a component 501 and are received by receivers of components 502-507. In the example of FIG. 5, signals are sent by transmitters of components 502-507 and are received by a receiver of component 501. In the example of FIG. 5, signals are sent over network 520 by transmitter and receivers of the other components 502-507. Time of flight of signals between transmitters of components and receivers of components may be (i) stored as distance data in at least one memory and/or (ii) may be retrieved to determine a relative distance between the components. The relative distance may be utilized to create a map or topology of the community of components. The retrieval from memory may utilize data processing, e.g., by at least one processor. Other data types may include, but are not limited to: angle data, position data, location data, control data, sensor data, and/or component identification information data. The data may be stored in at least one memory. The data may be communicated over the network.

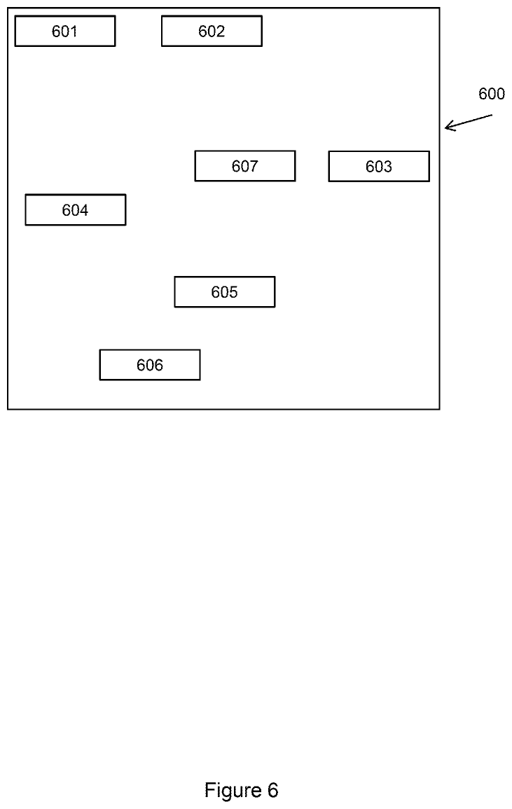

FIG. 6 shows an example of a topology of the community of components (e.g., such as the one represented in FIG. 5) in an enclosure. A community of components may be disposed in one or more enclosures during initial construction of the enclosure or after construction of the enclosure. After placement in an enclosure, one or more signals sent between the components may be analyzed and/or used to determine a topology of the community of components. Determination of a topology of a community of components by itself may not determine an absolute position of the components in a topology of an enclosure. A lack of knowledge of the position of the component, may make its data interpretation, data usage, calibration, replacement, maintenance, and/or repair difficult. For example, it may hinder forming an accurate distribution mapping of a sensed environmental characteristic (e.g., heat, pressure, or humidity) in the enclosure. For example, is may skew determination of a position of the sensed environmental characteristic. For example, it may direct maintenance personnel to a wrong location within the enclosure.

A topology of components in an enclosure may be determined (and/or displayed) using data embodied in the form of determined distances and/or angles between elements of the enclosure (e.g., distances and/or angles between wall, floors, and/or ceilings). A topology may comprise a two dimensional topology and/or a three dimensional topology. In the example shown in FIG. 6, a topology of an enclosure 600 and a community of components 601-607 comprises a two dimensional d topology. A topology of an enclosure and/or a topology of a community of components may be embodied in the form of a physical and/or virtual representation of the topology (e.g., a blueprint, architectural drawing, floorplan, and/or three dimensional software representation). A topology of a community of components and/or a topology of an enclosure may be stored as data in at least one memory associated with one or more processors that are in turn associated with one or more components. A topology may comprise a printed or printable topology, a displayed or displayable topology, and/or a topology comprised of data read or readable by a processor.

In some embodiments, at least one component of a community of components is (e.g., designated as) a reference component (e.g., at least one of components 601-607 in the example of FIG. 6). The reference component may be associated and/or assigned to a known location within an enclosure. The reference component may be disposed in the enclosure, and its location may be measured and/or verified, e.g., by a traveler and/or third party. The traveler may be a field service engineer. The traveler may be a robot (e.g., using a camera, or another optical sensor). The robot may be mobile. The traveler may be a drone. The traveler may establish a ground truth of the location of at least one component of the community of components (e.g., community of sensors). The one or more reference components in the enclosure may be at most 1, 2, 3, 4, 5, or 10 components. The one or more reference components in the enclosure may be any number between the aforementioned numbers (e.g., from 1 to 10, from 1 to 5, or from 5 to 10 components). A reference component may be associated with a location within an enclosure before or after placement of a community of components within an enclosure. Assignment of a reference component may be via physical placement of the component at a known location of an enclosure (e.g., by a field service engineer). In one embodiment, assignment of a reference component may be performed via software (e.g., using the network and/or a controller). Assignment of a reference component may include virtual placement onto a location of a software generated representation of an enclosure. Assignment of a reference component may include its physical placement in an enclosure and/or its virtual placement onto a location of a software generated representation of an enclosure. A software generated representation of an enclosure may comprise a two dimensional and/or a three dimensional representation. A software generated representation of an enclosure may be digitally represented, and/or displayed, e.g., on an electronic display. A user may interact with the digital representation. For example, a user may interact with an electronic display via a graphical user interface (abbreviated herein as “GUI”) that may be configured to enable assignment (and/or reassignment) of a reference component via user interaction (e.g., via data entry, dragging and/or dropping).

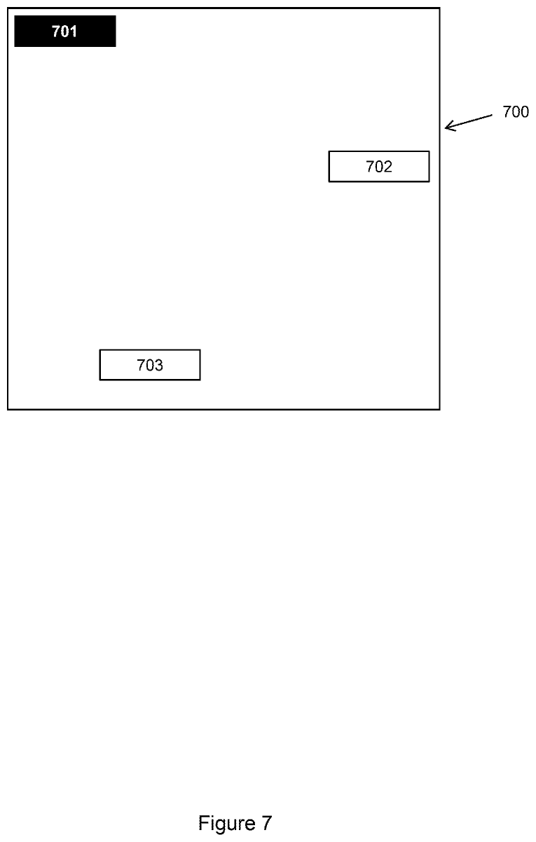

FIG. 7 shows an example of an orientation of a topology of a community of components comprised of a reference component. In FIG. 7, a community of components 701-703 is physically placed within an enclosure 700, wherein 701 a reference component. After a reference component is assigned to and/or verified in a location within an enclosure, constraints imposed by topology of the enclosure and the topology community of components limit the absolute position of the other components to (e.g., only) one possible location within the enclosure. The reference component may also be termed herein as “anchor component.” A topology of the components in an enclosure may be printed and/or displayed as a blueprint, architectural drawing and/or floorplan of the enclosure to find locations of components within the enclosure. If one or more components move, are moved, added to, or removed from a community of components, a new topology of the components may be determined. The topology may be of the components relative to each other and/or relative to the enclosure. When an absolute topology (e.g., in relation to absolute coordinates, e.g., GPS) is requested, then the absolute coordinates of at least one of the components is required. In order to determine an absolute location of a components in three dimensions, then three components having all three Cartesian coordinates different from each other may be required (e.g., using a triangulation mapping method). A calibrated and/or localized component may be utilized as a standard for calibrating and/or localizing other components. Such component may be referred to as the “golden component.” The golden component be utilized as a reference component. Such component may be the one most calibrated and/or accurately localized in the facility.

In some embodiments, locations of all components of the community are determined. In order to form a two dimensional topological mapping in an environment, a component is required to determine its relative position to at least two adjacent components that differ from each other in two of their cartesian coordinates. In order to form a three dimensional topological mapping in an environment, a component is required to determine its relative position to at least three adjacent components that differ from each other in three of their cartesian coordinates. In order to determine an absolute position of the components in the enclosure, anchor component(s) are required (e.g., whose position is verified by a traveler). For example, using one or more anchor component having a known location, and determining a relative location of the other components to the anchor component(s). Once the absolute position of all components is known, failure or is removal of an anchor component (e.g., reference component) may be immaterial (e.g., as the absolute position of all components will be known by virtue of their relation to the anchor components before its removal and/or failure).

In one embodiment, where one or more components of a community of sensors comprise sensors (e.g., as part of transceivers), once a sensor(s) location is determined within the topology of an enclosure, data sensed by the sensor may be monitored in view of the location. Data (e.g., signal) from any component (e.g., sensor) may be time stamped. Data from a sensor may be collated and/or analyzed. The collation and/or analysis may be performed by one or more processors. The processors may be operatively coupled to (e.g., and residing on) one or more components in the community of components. Collation and/or analysis may be performed, or directed to be performed, by and/or on one or more component comprised of a sensor and/or one or more component not comprised of a sensor (e.g., a buzzer or a light (e.g., a light emitting diode). Collation and/or analysis may be performed or directed to be performed at a location within which sensors are located and/or at a location different from that of the sensors (e.g., a remote location and/or the cloud). Analysis may utilize machine learning and/or artificial intelligence techniques (e.g., reactive, limited memory, theory of mind, and/or self-aware techniques). Monitoring data of one or more enclosure (e.g., building or room of a building) using one or more sensors (e.g., temperature, noise, power, voltage, current, radio waves, and/or gas sensors) may provide a time dependent evolution of an environment of the enclosure pertaining to the data (e.g., time dependent temperature, noise, power, voltage, current, frequency, wavelength, amplitude, and/or gas sensors) as a function of time. Evolution data may be utilized for analysis, control, maintenance, and/or prediction of the environment of an enclosure. For example, an elevated noise level at location coupled with an atypical temperature variation may indicate a malfunctioning ventilation at that location. Evolution data may be used to predict and/or prepare for future events in an enclosure (e.g., prepare an enclosure for a meeting, predict failure of a component, and/or recognize failure of a component).

In some embodiments, sensor data analysis utilizes artificial intelligence (abbreviated herein as “AI”). In some embodiments, processing sensor data comprises performing sensor data analysis. In some embodiments, the sensor data analysis comprises linear regression, least squares fit, Gaussian process regression, kernel regression, nonparametric multiplicative regression (NPMR), regression trees, local regression, semiparametric regression, isotonic regression, multivariate adaptive regression splines (MARS), logistic regression, robust regression, polynomial regression, stepwise regression, ridge regression, lasso regression, elasticnet regression, principal component analysis (PCA), singular value decomposition, fuzzy measure theory, Borel measure, Han measure, risk-neutral measure, Lebesgue measure, group method of data handling (GMDH), Naive Bayes classifiers, k-nearest neighbors algorithm (k-NN), support vector machines (SVMs), neural networks, support vector machines, classification and regression trees (CART), random forest, gradient boosting, or generalized linear model (GLM) technique.

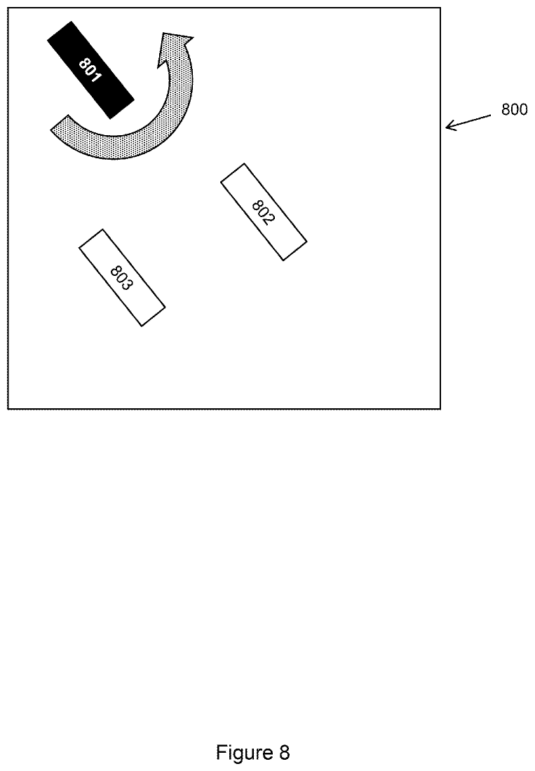

FIG. 8 shows an example of different enclosure and orientation of the topology of community of components represented in FIG. 7. In FIG. 8, a community of components 801-803 is physically placed within an enclosure, a topology (e.g., relative location) of the components is determined. A reference component 801 has a known location in the enclosure 800. As represented in FIG. 8, even though reference component 801 is has a known location in the enclosure, and a topology of a community of components is determined, the topology of the enclosure may not act to constrain the topology of the community of components to (e.g., only) one orientation. For example, in FIG. 8, the topology of the community of components 801-803 may be rotated about reference component 801 (e.g., as indicated by rotational arrow) such that components 802 and 803 may be positioned within the enclosure in more than one location. Therefore, more than one anchor component is required to constrain an absolute location of the community of sensors. A sensor can be part of (e.g., included in) a transceiver.

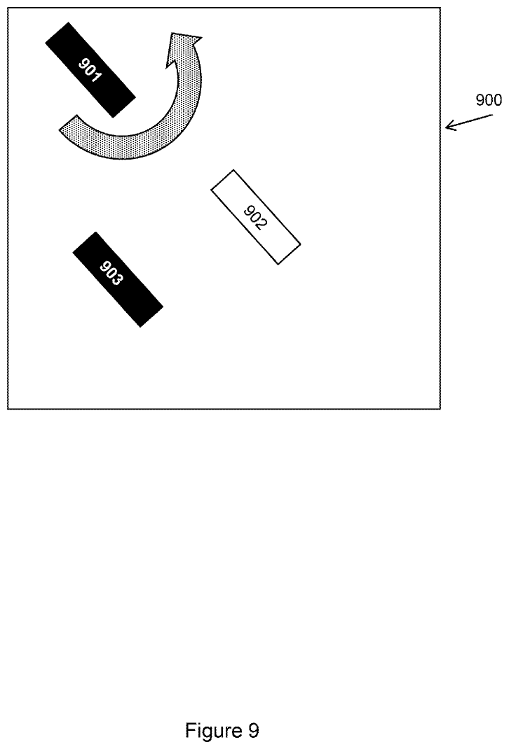

FIG. 9 shows an example of a community of components comprised of two reference components (e.g., anchor components). In one embodiment, if a user determines that a topology of a community of components may be fitted within an enclosure, the user may install and/or assign two or more components as reference components (e.g., having known locations). In one embodiment, if (e.g., an algorithm determines that) a topology of a community of components may be fitted within an enclosure in more than one orientation, installation and/or assignment of one or more additional reference (e.g., anchor) components may be advised. In the example shown in FIG. 9, a community of components 901-903 is physically placed within an enclosure and two reference components 901 and 903 have known locations in the enclosure 900. In the example of FIG. 9, additional constraints are imposed (as compared to the community shown in FIG. 8) by an additional reference component in a manner that limits the number of orientations that the topology of the community of components 901-903 may be fit within an enclosure.

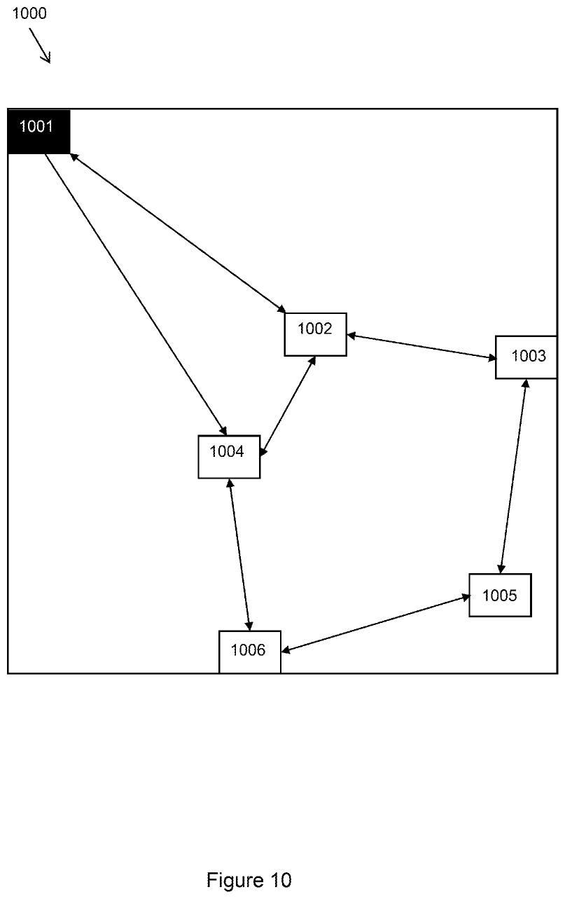

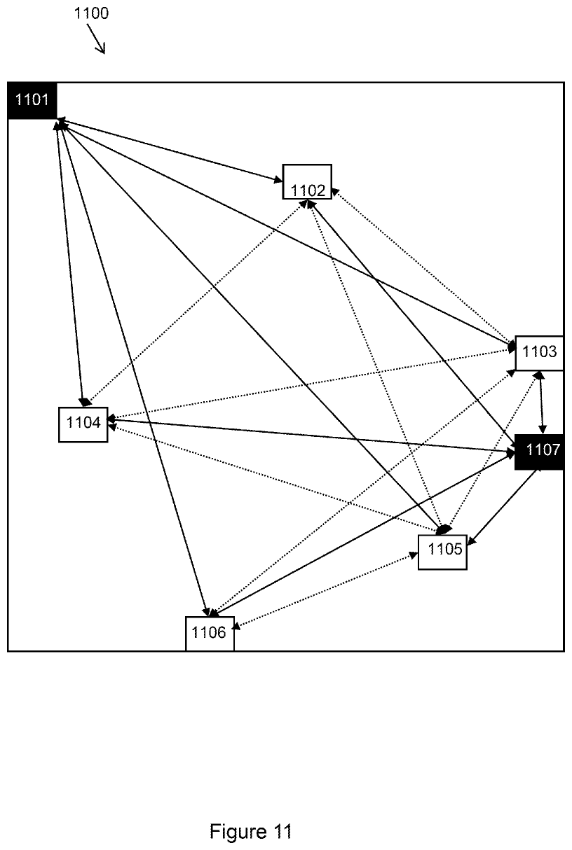

The topology of the community may be determined with varied degrees of accuracy and/or robustness. In some embodiments, minimal number of signals are required to form a topology (e.g., without verification). In some embodiments, the number of signals forming the topology exceeds the minimum number of signals. In increase in verification signal may form a more robust topology, with greater positional accuracy of the components. FIG. 10 shows an example of a topology of a sensor community in an enclosure formed by a minimum number of signals, in which component 1001 is an anchor component that has a known location. The location of components 1002-1006 is determined relative to one another and to the anchor component, with each component located with respect to two components in the community. The arrows in FIG. 10 designate signal communication between components (e.g., communicating signal(s) relating to a distance between the components which the arrow connects). FIG. 11 shows an example of a topology of a sensor community in an enclosure formed by number of signals greater than the minimum required to form the topology, in which components 1101 and 1107 are anchor components that have a known location (e.g., verified location). The location of components 1102-1106 is determined relative to one another and to the anchor component, with each component located with respect of more than two components within the community. The arrows in FIG. 11 designate signal communication between components (e.g., communicating signal(s) relating to a distance between the components which the arrow connects). The solid line arrows in FIG. 11 designate signal communication between a non-anchor component and an anchor component, which components are disposed at the ends of an arrow (e.g., anchoring communication). The dotted line arrows in FIG. 11 designate signal communication between a non-anchor component disposed at the ends of an arrow (e.g., non-anchoring communication for assessing a relative location of the components).

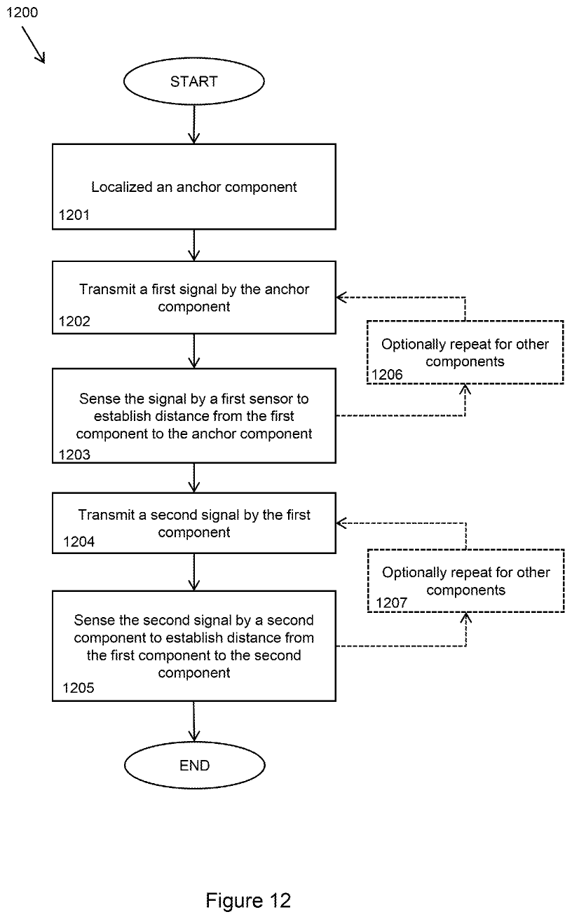

The community of components can establish the location of its members relative to each other and/or relative to an anchor component. In some embodiments, a physical topology of the community of component is determined with respect to an anchor component. At least a portion of the community of components may have a relative location established prior to its relation to the anchor components. In some embodiments, the relation of the community is established after establishing a known location of the anchor component. FIG. 12 shows an example of a flowchart 1200 in which a location of the anchor component is known and/or localized 1201, and other community member(s) (e.g., a first component) are located relative to the anchor component 1202-1203, by using signal transmission and receipt. Other components can be located in a similar manner 1206. In the example of the flowchart shown in FIG. 12, location of some of the community member(s) is determined relative to other community member(s) that are not the anchor components. For example, the location of the second component is determined (via signal transmission and receipt) relative to the first component in 1204-1205. Other components can be located in a similar manner 1207.

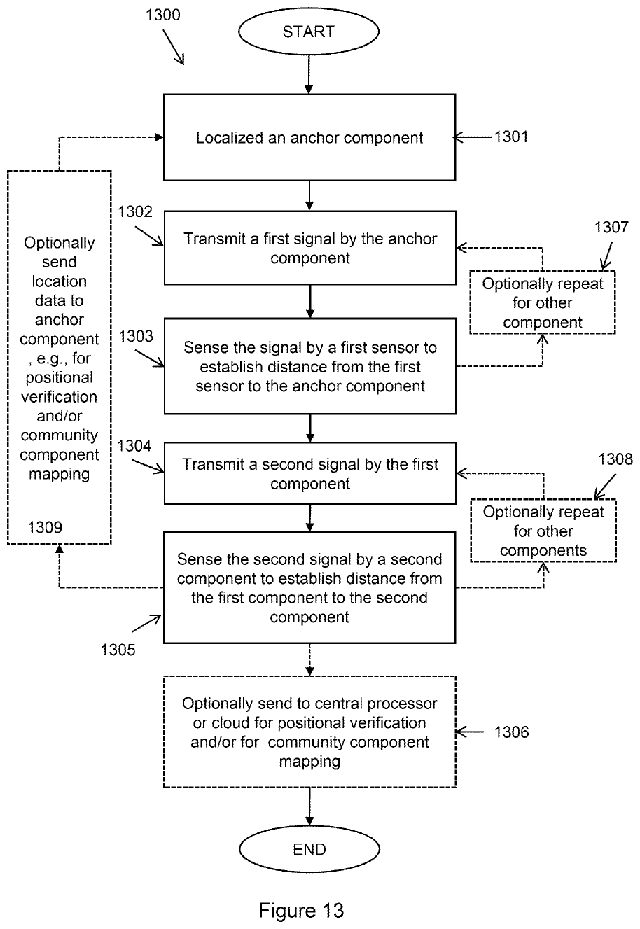

FIG. 13 shows an example of a flowchart 1300 in which a location of the anchor component is known and/or localized 1301, and other community member(s) (e.g., a first component) are located relative to the anchor component 1302-1303, by using signal transmission and receipt. Other components can be located in a similar manner 1307. In the example of the flowchart shown in FIG. 13, location of some of the community member(s) is determined relative to other community member(s) that are not the anchor components. For example, the location of the second component is determined (via signal transmission and receipt) relative to the first component in 1304-1305. Other components can be located in a similar manner 1308. The topological mapping, location establishment, and/or location verification may be performed locally and/or via the cloud (e.g., 1309). Locally may be using a processor in the enclosure, as part of the component assembly (e.g., on the electrical board of the component), in the facility (e.g., building), external to the enclosure and/or facility, in a remote location, and/or in the cloud.

In some embodiments, the community of components determines its own topology (e.g., topology of its members). For example, the community of components (e.g., sensors) can determine a relative location of its members (e.g., using signal transmission and receipt by the components). For example, the components may utilize signal transmission and receipt to determine their relative distance from each other. A timing of the signal transmission and/or receipt may be coordinated. For example, each component may have a designated time window to transmit its signal. The designated time windows of members of the community may not overlap. The assignment of time windows to the various community members may be by a coordinator. The coordinator may be a community member (e.g., a component). The coordinator may be an anchor component. The coordinator may be different from a community member (e.g., may reside outside of the enclosure, e.g., in a cloud. The coordinator may be a controller. The identity of the coordinator may be pre-determined. The identity of the coordinator may be determined in situ in the enclosure (e.g., once the components are disposed in the enclosure). The community of components may comprise stationary components. The assignment of the coordinator may be performed during a designated time. The assignment of the coordinator (e.g., that is done in situ), may be performed during a designated time. The community members may participate in assignment of the coordinator. The assignment of the coordinator may precede designation of time windows for signal transmission by the community members, e.g., to determine their relative location from each other.

In some embodiments, the component is configured to generate one or more signal types. The component may be configured to generate a first signal utilized for measuring relative location of the components (e.g., to form a topological mapping of the components in the enclosure). The component may be configured to generate a second signal utilized for searching and/or assigning a coordinator (e.g., that is a member of the community of sensors). This second signal may be referred to herein as “coordinator assignment signal,” or “beacon.” The first signal and the second signal may be the same signal (e.g., the same signal type having the same signal characteristics). The first and second signal may be different signals. The first and second signal may be of different type. The first and second signal may have at least one signal characteristic that is different (e.g., a plurality of different signal characteristics). The at least one signal characteristic comprises a signal signature, signal time span (e.g., signal length), signal wavelengths (e.g., wavelength span), signal amplitude, or any combination thereof. The signal may comprise an electromagnetic signal (e.g., optical signal). The signal may comprise an acoustic signal. The first and second signals may differ in their signal signature, signal length, signal wavelengths (e.g., wavelength span), signal amplitude, or any combination thereof.

In some embodiments, the components of the community are configured to generate time-based data. In some embodiments, the components of the community are configured to generate a random number. The random number may be generated in relation to the time-based data (e.g., the component may generate a random time to transmit its signal). The time-based data may relate to the signal transmission. The time-based data may relate to a time window (e.g., comprising start time, and end time of the time window). The random time may be chosen within a time window (e.g., that is predetermined and/or prescribed to all components in the community). The component may be configured to generate a signal comprising an identification number (abbreviated herein as “ID”). The ID may uniquely identify the component in the community. The identification number may be transmitted in radio frequency, or any other frequency disclosed herein. For example, a component may be configured to generate a start time, an end time, and/or a random time therebetween (e.g., 2.350000 s selected randomly from the time range of from 2.000000 s to 3.000000 s). When a component is disposed in an enclosure it may be turned on. Turning on the component may be manual or automatic. For example, turning on of the component may be when connecting it to the network.

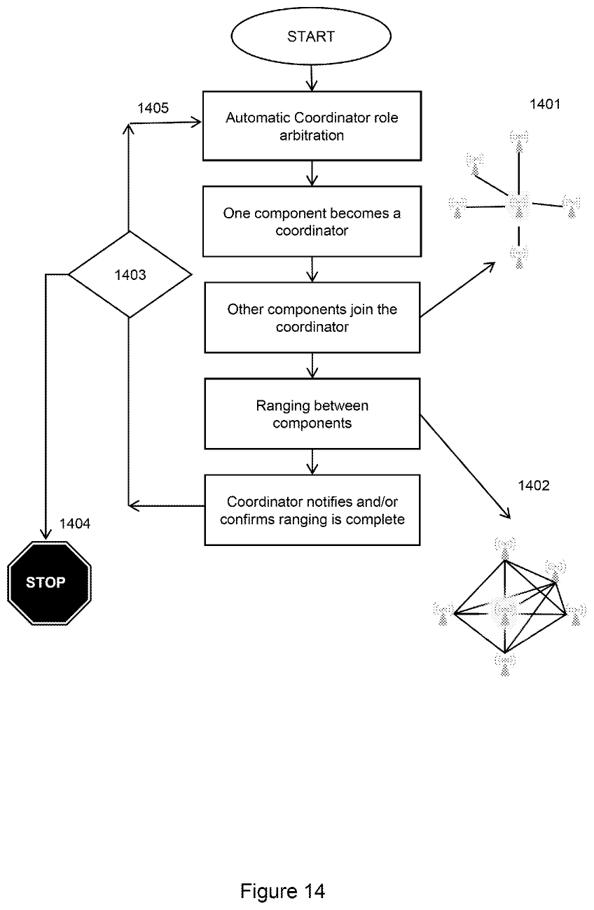

In some embodiments, the community of components determines its own topology using signal transmission and detection. The community of members may designate its own coordinator using a coordinator assignment process. Once a coordinator is assigned, the community members may transmit signals and may detect signals of other community members. to determine their relative location from each other. The coordinator assignment process may initiate once the community members are connected to the network. The community members may be connected to the network simultaneously (e.g., once the power is turned on to the enclosure). The community members may be connected to the network sequentially (e.g., once the each is connected to the power). FIG. 14 shows an example of a flowchart depicting a coordinator assignment process, including assignment of a coordinator by the community (e.g., as delineated herein), and establishing a (e.g., relative and/or absolute) physical location of the community components. This assignment may be an automatic assignment. For example, the members of the community may be programmed to perform the automatic assignment process. Following assignment of the coordinator component, as shown in the example of FIG. 4, other components (that are within signal sensing range of the coordinator) will join the coordinator and expand the number of community members. Once all members have joined the coordinator to form the community 1401 (e.g., having a “star” configuration), the community will self-generate its topology 1402 (e.g., as orchestrated by the coordinator), e.g., by ranging measurement between the components of the community. If (e.g., once) the topology mapping is complete, the coordinator will notify the community members and/or a controller or other processor operatively coupled to the coordinator, and the coordinator may go into a standby mode 1403. From that standby mode, the coordinator may entirely cease (e.g., stop 1404) its function. From the standby mode (e.g., 1403), the process of coordinator assignment may be initiated (e.g., 1405), for example, on (i) a new installation of the stationary members of the community of components, and/or (ii) any removal and/or malfunction of a component (e.g., a coordinator). The process of topology mapping of the community members (e.g., entitled “Ranging between components,” in FIG. 14) may be initiated (e.g., directly from the standby mode) on entrance of a new community member (e.g., weather stationary or transitory) into the range of the coordinator (e.g., entitled “Other components join the coordinator,” in FIG. 14).

In some embodiments, the coordinator assignment process includes random time generation within a (e.g., predetermined) time slot, and transmission of signal during that time slot. The first community member to transmit a signal received by another community member, may be designated as the coordinator for that community. Once a coordinator is assigned, the coordinator assigns time windows for signal transmission for each of the community members, which time windows are a repeating interval. The coordinator may change the time window and/or repetition rate of the intervals, e.g., upon joining of additional (e.g., mobile) community member into the enclosure.

In some embodiments, the component may be turned on and transmit a signal at the random time within the prescribed time window. A component may generate a random number and/or a random time designation upon being turned on or upon occurrence of a particular event. The event may comprise a detected change in a topology, e.g., entrance of a mobile component into the enclosure. The event may comprise a manual or automatic system reset).

After being turned on or upon the occurrence of the event, a component may be attentive (e.g., listen) for one or more coordinator assignment signals (e.g., one or more beacons) from other component(s). The coordinator assignment signal may be a regular component signal (e.g., such as the one utilized for relative distance measurements). The coordinator assignment signal may have a specific characteristic (e.g., signal signature). The characteristic of the coordinator assignment signal may designate (e.g., be associated with) a search for a coordinator component. A signal having a signature indicating that it is searching for a coordinator is designated herein as “beacon” signal. The coordinator assignment signal may be transmitted at the random time (within the prescribed time slot). The time slot for the coordinator assignment signal may be embedded in the component (e.g., programmed in the processor operatively coupled to the component, e.g., the component processor). The time slot may be provided to the component upon its coupling to the network. All the components in the community transmit their coordinator assignment signal (e.g., first signal) and listen to any received coordinator assignment signal (e.g., from other community members). The listening can be during a listening time window. If a component does not detect a valid coordinator assignment signal from another component during the listening time window, it may generate another initial (e.g., beacon) signal. In one embodiment, a length of the listening window is longer that the initial (e.g., beacon) signal length. In some embodiments, the listening window is at least 2*, 3*, 4*, 5*, 10*, or 20 times (*) longer than its beacon signal. The listening window can be longer than its beacon signal by any value between the aforementioned values (e.g., from at least 2* to at least 20*, from at least 2* to at least 10*, or from at least 10* to at least 20*). FIG. 15A shows a time dependent signal related behavior of a component, in which the component generates a random time point for sending a signal (e.g., beacon) between zero seconds (s) and three seconds (e.g., by using a random generation function Rnd(0 s, 3 s)). In the example shown in FIG. 15A, the random time generated is 2.35 s, and the beaconing signal 1503, which beaconing 1503 is initiated at time 2.35 s. The time window (e.g., of 3 s in FIG. 15A, 1505) reserved for transmission of the signal is the sum of the time periods 1501, 1503, and 1502. During the time 1501 and 1502 in which the component is not sending the 1503 signal (e.g., the coordinator assignment signal, or beacon), it is receptive to any coordinator assignment signal transited by other (e.g., adjacent) component(s) within its range. This time can be referred to as “listening period” (e.g., 1501 and 1502). The beacon signal has a fixed (short) time and is designated in FIG. 15A as 1503. The beacon signal duration (i) may be smaller than the listening time window and/or (ii) may be smaller than the time window during which the random signal transmission time is chosen (e.g., using a random number generator). In some embodiments, smaller is by at least 2*, 5*, 10*, 50*, 100*, or 1000* wherein the symbol “*” designates a mathematical operation of multiplication also known as “times.” Smaller may be by any value between the aforementioned values (e.g., from 2*to 1000* smaller, from 2* to 500* smaller, or from 500* to 1000* smaller). The listening window and/or random signal transmission time can be at least about 0.01 s, 0.1 s, 1.0 s, 1.5 s, 2 s, 2.5 s, 3 s, 2.5 s, 4 s, or 5 seconds (abbreviated herein as “5”) long. The listening window and/or random signal transmission time can be at least about 10 milliseconds (ms), 25 ms, 50 ms 100 ms, 200 ms, 500 ms 1 s, 1.5 s, 2 s, 2.5 s, 3 s, 2.5 s, 4 s, or 5 seconds (abbreviated herein as “5”) long. The listening window can of any time value between the aforementioned time values (e.g., from about 10 ms to about 5 s, from about 10 ms to about 1 s, from about 1 s to about 2.5 s, or from about 2.5 s to about 5 s, long). In some embodiments, the listening window can be less than about 0.01 s, or 0.1 s.

In some embodiments, a first components generates a first coordination assignment signal and a second component generates a second coordination assignment signal. The first coordination signal may have a signal signature of the first component (e.g., first component ID), and is generated at a first random time (within an allocated time window). The second coordination signal may have a signal signature of the second component (e.g., second component ID), and is generated at a second random time (within the allocated time window). The components in the community may have the same allocated time window to each send their coordination assignment signals. During the allocated time window, the community components may send coordination assignment signal, expect to receive (e.g., listen for) a coordination assignment signal from another component in the community, and/or receive the coordination assignment signal from another component in the community. The length of the coordination assignment signal may be shorter than the allocated time window for transmitting the coordination assignment signal. Smaller may be by at least 5*, 10*, 50*, 100*, or 1000* wherein the symbol “*” designates a mathematical operation of multiplication also known as “times.” Smaller may be by any value between the aforementioned values (e.g., from 5* to 1000* smaller, from 5* to 500* smaller, or from 500* to 1000* smaller). When the first component detects the second coordinator assignment signal (e.g., a second beacon signal) from the second component within its listening window, the first component may generate a random time window, after which it stops generating its coordinator assignment signal, which time window is referred to herein as an “intermission.” In some embodiments, the intermission is longer than the length of the coordinator assignment signal. longer may be by at least about 5*, 10*, 50*, 100*, or 1000* wherein the symbol “*” designates a mathematical operation of multiplication also known as “times.” Longer may be by any value between the aforementioned values (e.g., from about 5* to about 1000* longer, from about 5* to about 500* longer, or from about 500* to about 1000* longer). While the first component is in the listening mode (e.g., expecting to receive a coordination assignment signal from another component in the community), the first component may detect a third coordinator assignment signal from the second component. The second coordination assignment signal and the third coordination assignment signals may have the same ID signature (e.g., of the second component). Once the first component receives a minimum of two coordination assignment signals from the same component (e.g., which two coordination signals may have the same ID signature), the first component may assume a role as a coordinator component. Once a component assumes the role of a coordinator component, it may start an association process during which a detected component (e.g., the second component) is associated to the community of components that includes the first component that now became coordinator component. FIG. 15B shows time lapse example of a first component including three time windows. The first time window 1551 is from zero to three seconds, and the second time window 1552 is from three seconds to six seconds. The third time window 1540 is utilized for coordinator designation. The first component generates a random time point during the first time window 1551 in which it generates a beacon 1512, which time point is randomly chose to be 0.35 seconds. Except for the beaconing period 1512, the first component is receptive to any incoming signal during time window 1551, and it receives a signal 1531 that started at time 1.65 s. In the example shown in FIG. 15B, the first component receives a beacon signal 1531 from a second component starting at time 1.65 s. Once a component receives a coordinator association signal from another component, it can start a coordinator assignment routine. Alternatively, it can wait a second time period to confirm a request from the other component. FIG. 15B shows an example in which the first component is receptive to any signal received from a second component to during a second time period 1552, which second component beacon 1532 is received at time 5.52 s. Once a component received two beacons from the same component (e.g., the second component), it designates that component as the coordinator, and the coordinator assignment process initiates. FIG. 15B shows an example of a coordinator assignment process 1540 that initiates after the first component received a second beacon 1532 from the second component. The coordinator association process can take place immediately after receipt of the second beacon from the second component, or after the second time window closes (e.g., 1541). Once the first component detects an incoming signal from the same second component in each of the time windows (e.g., 1551 and 1552), the second component becomes a coordinator of the community (e.g., that includes the first component and the second component). The community may initiate the coordination assignment process after a first component receives at most one, two, three, four, or five signals from a second component, which signals are coordination assignment signals (e.g., beacons).

In some embodiments, locating components in the community includes a plurality of operations. The plurality of operations may include (i) a first component being receptive to any incoming beacon from a second component during a (e.g., pre-assigned) time duration, (ii) a first component transmitting a beacon at a random time within the time duration, and a second component transmitting a beacon at a (e.g., another) random time within the time duration, (iii) repeating operations (i) and (ii) N times, (iv) the first component to receive (e.g., sense) a beacon N time becomes a coordinator, (v) the coordinator optionally transmit coordinator role confirmation signal(s), (vi) the coordinator senses other components in the network (e.g., by sensing their beacons) and assigns their range signaling window, (vii) at least one first component in the network transmits its ranging signals that are received by at least one second component in the network, (vii) the ranging signals are analyzed, (v) a relative and/or absolute location of the components in the community is formed, (vi) the localized components of the community are receptive to any incoming component to the community, (vii) the coordinator may optionally transmit a signal comprising its identity signal signature in (e.g., preassigned) time intervals and the non-coordinator components in the community expect to receive those signals (viii) once a new community member is sensed, operations (vi) to (vi) are repeated, and/or (ix) once an absent of a coordinator is sensed (e.g., the coordinator ID signal is not received by one or more active community members), operations (i) to (vi) are repeated. The ranging signals can be analyzed by one or more components of the community. For example, the ranging signals can be analyzed by the component receiving the ranging signal, by the coordinator, by one or more stationary components, by one or more non-stationary components, by one or more anchor components, by another processor operatively coupled to at least one member of the community. The other processor can be in the cloud, in the facility in which the components are disposed, or in another facility. If the coordinator transmits a plurality of coordinator role signals, they may be transited at fixed intervals. N may be an integer greater than zero. N can have any integer value disclosed herein. Even when a component received an opportunity transmit a beacon in the process of becoming a coordinator, the component will continue to follow random time assigned to transmit its beacon for next N cycles to verify that no other components (e.g., devices) are transmitting a beacon.

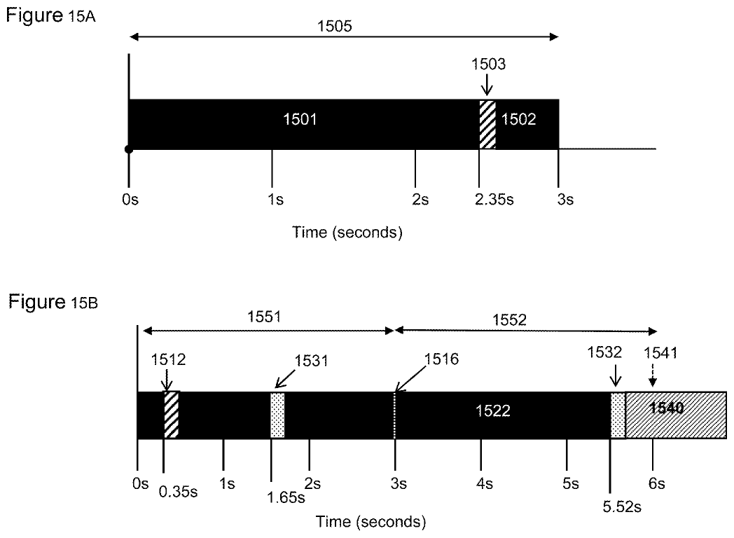

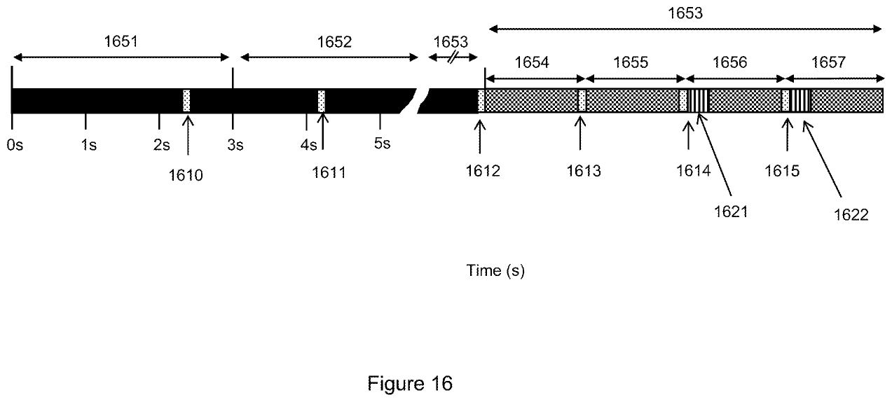

In some embodiments, a coordinator is designated to a community of components. Once designated, the coordinator assigns repetitive time slots for the associated component (e.g., the second component) to transmit a topography signal, which topography signal is utilized to determine the topography of the community of components (e.g., in the enclosure). The topography signal may have at least one characteristic different than the coordinator assignment signal. The topography signal may have the same characteristics as the coordinator assignment signal. When a component receives an opportunity to transmit a beacon during a process of assuming the role of a coordinator, it may continue to generate new time windows for signal reception (referred to herein as “listening time windows”) for a number of cycles (e.g., ‘N’ cycles). The number of “N” is an integer having value of at least one. The number of cycles is preferably sufficiently large to ensure with a high probability that all components (e.g., within a range of the coordinator) component have been associated to the coordinator. In one embodiment, “N” is equal or greater than 1, 2, 3, 4, 5, 10, 50, 100, or 1000. The number N can be any integer number between the aforementioned numbers (e.g., from 1 to 1000, from 1 to 500, or from 500 to 1000). If a beacon signal is received by the component from another component at least twice during the “N” cycles, the component may assume the role of a coordinator. After the component assumes the role of a coordinator component, it may begin to transmit its beacon signals at fixed intervals. A component that assumes a role of a coordinator may transmit a unique signal signature depicting its role as a coordinator (e.g., in addition to, or instead of, its ID signal). A component that assumes a role of stationary subordinate component (which subordinate is with reference to a coordinator) it may transmit a unique signal signature depicting its role as a subordinate component (e.g., in addition to, or instead of, its ID signal). A component that is not a coordinator in a network may be referred to herein as a “subordinate” component, or a “non-coordinator” component. A component that is stationary may transmit a unique signal signature depicting its stationary positioning (e.g., in addition to, or instead of, its ID signal and/or being a coordinator or subordinate). A component that is mobile may transmit a unique signal signature depicting its mobility (e.g., in addition to, or instead of, its ID signal and/or being a coordinator or subordinate). Mobility may be with respect to the enclosure and/or stationary component(s). The coordinator signal may comprise a signature of a coordinator role. A mobile component may be referred to herein as a “Tag” component. A coordinator component may be referred to herein as a “coordinator.” A component which has a known position is termed herein “anchor.” Once a component becomes a coordinator, it transmits signal at fixed intervals. The coordinator transmitted signal may notify components(s) within range of (i) the role of the coordinator, and/or (ii) assigned time window in which the non-coordinator components should transmit their topological signal. The topological signal may be utilized to form the topology of the community of components, e.g., that are within range of the coordinator. After a coordinator component begins to transmit its signals at fixed intervals, it may initiate a process of associating in range components into its community of components. FIG. 16 shows a time lapse example of a first component including several time windows. A first time window 1651 has a three second duration (e.g., between zero and three seconds) during which a beacon 1610 is received by the first component at a random time in the 1651 time window. A second time window 1652 has a three second duration (e.g., between three and six seconds) during which a beacon 1611 is received (e.g., sensed) by the first component at a random time in the 1652 time window. A Nth time window 1653 has a three second duration which a beacon 1612 is received by the first component at a random time in the 1653 time window. The time windows 1651-1653 incorporate duration in which the first component is receptive to any incoming beacon signal, and during which the first component beacons (not shown in FIG. 16). N can be any integer greater than 0. For example, N can have an integer value of at least 0, 1, 2, 3, 4, 5, 10, or 20. N can have any integer value between the aforementioned values (e.g., from 0 to 10, from 0 to 10, or from 10 to 20). In the example of FIG. 16, when N is 0, the number of listening windows includes two time windows. In some embodiments, the listening window is a single listening window. When a plurality of beacons received by the first component originate from a second component, the second component becomes a coordinator. The second component may transmit one or more confirmation signals confirming its role as a coordinator. FIG. 16 shows an example of two coordinator confirmation signals 1613 and 1614. The one or more confirmation signals may be transmitted at non-random times and/or at constant intervals (e.g., 1654 and 1655). The coordinator confirmation signal may comprise a signal signature for an ID of the component, the role of the component (e.g., as a coordinator), the transitory or stationary nature of the component, and/or the component being an anchor component or non-anchor component. Once the coordinator role is confirmed, the coordinator may recognize the components within its community (e.g., network). The number of community members may depend on, e.g., a range at which a component may receive the coordinator signal and/or a range at which a coordinator may sense a non-coordinator component signal. Once a component is sensed by the coordinator, the coordinator may assign a range signaling window to that sensed component. FIG. 16 shows an example of a range signaling windows 1621 and 1622 that are allocated to a non-coordinator component in the community of components that are coordinated by the coordinator, which range signaling windows are in ranging periods (e.g., range determination time windows) 1656 and 1657 respectively. The coordinator may optionally transmit signals (e.g., 1614 and 1615), for example, to designate a beginning of a ranging period. A ranging period (e.g., 1656) may include a number of range signaling windows respective to the number of components in the network. In the example shown in FIG. 16, one non-coordinator sensor is in the community, and is assigned a range signaling window 1621 during ranging period 1656. The ranging signaling window designation can be repeated in any subsequent ranging period. FIG. 16 shows an example in which a ranging period 1657 is repeated subsequent to ranging period 1656, in which a non-coordinator component is designated a range signaling time window 1622 that is at the same relative timing to the ranging period 1657 as ranging signaling window 1621 is in ranging period 1656. During the range signaling period 1656. One or more subsequent ranging periods are repeated until the relative and/or absolute location of all components in the community is complete.

In some embodiments, the first component received signals from two different components during the “N” cycles. In that case, the component may refrain from assuming a role of a coordinator for an intermission that is “P” times longer than the time of any other previous listening windows. In one embodiment P is any number greater than one. P times longer may be by at least about 5*, 10*, 50*, 100*, or 1000* wherein the symbol “*” designates a mathematical operation of multiplication also known as “times.” P times linger may be by any value between the aforementioned values (e.g., from about 5*to about 1000* longer, from about 5* to about 500* longer, or from about 500* to about 1000* longer). For example, P*25. In one embodiment, “P” is at least two. If during the “P” length back off time no beacon signal is received from another component, the component is assigned as a coordinator component.

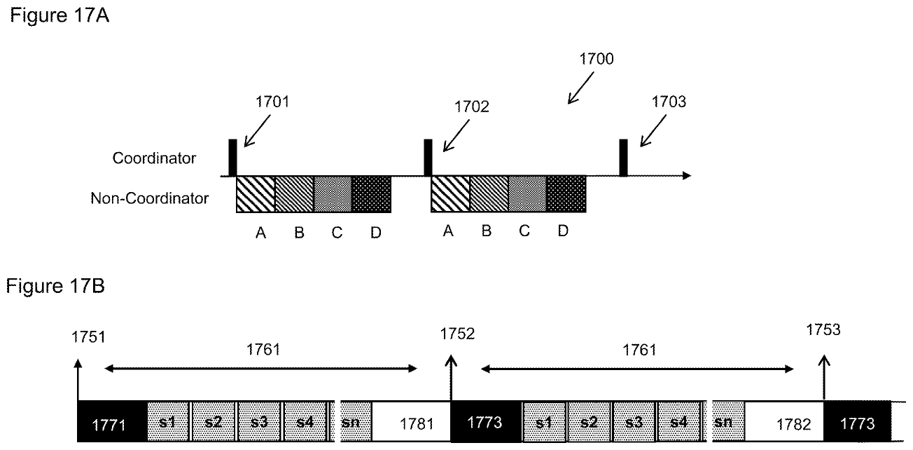

FIG. 17A shows an example of a signal related time laps 1700 depicting respective coordinator signals 1701, 1702, and 1703 emitted at fixed intervals. The coordinator emitted signals may signal a beginning and/or end of a location signaling process. The location signaling process may comprise signal emission by other components of the community. One or more members of the community (e.g., each member of the community) may be assigned a time slot in which it emits the location related signal. FIG. 17A shows an example in which the coordinator assigns time slots A, B, C, and D to non-coordinator components of the community. The time interval between the coordinator signals (e.g., 1701-1703) may be larger than the sum of the time windows allocated to the community members, e.g., for emitting their location related signals.

FIG. 17B shows an example of a signal related time laps depicting respective coordinator signals 1751, 1752, and 1753 emitted at fixed intervals 1761, the coordinator assigns time slots S1, S2, S3, S4 . . . and Sn to non-coordinator components of the community, wherein n is an integer equal or greater than one. The time interval between the coordinator signals (e.g., 1751-1753) may include (i) than the sum of the first type of time windows allocated to the community members (e.g., S1 to Sn in FIG. 17B)) for emitting their location related signals, (ii) a second type of time window allocated for any other sensor to joining the community (e.g., 1771, 1772, and 1773), and/or (iii) a third type of time window allocated for detection and joining of transitory (e.g., TAG) community members (e.g., 1781 and 1782). The time interval between the coordinator signals may be referred herein as “super time frame.” The order of the first types of time windows, second type of time window, and third type of time window can be any order. For example, the first type may be followed by the second type, that may be followed by the third type. For example, the second type may be followed by the first type, that may be followed by the third type (e.g., as depicted in FIG. 17B). For example, the second type and/or the third type may be embedded in the first type, e.g., such that (a) the second type may follow at least one time windows allocated to the community members for emitting their location related signals, and/or (b) the third type may follow at least one time windows allocated to the community members for emitting their location related signals. The first time window may be time-spaced by at least one time windows allocated to the community members for emitting their location related signals. The super time frame may include (e.g., designated) time frame(s) that do not allow any community member to transmit a signal (referred to herein as “quiet time”). The transitory community member (e.g., tag) can be referred to herein as a “transitory component.” The tag may comprise a mobile circuitry. The mobile circuitry can be implemented in a mobile (e.g., cellular) phone, a pad, a laptop, or in an identification tag. The tag may comprise a transceiver (e.g., a radio) and/or a controller (e.g., a microcontroller). The tag may comprise circuitry enabling geo-location technology (e.g., global positioning system (GPS), Bluetooth (BLE), ultrawide band (UWB) and/or dead-reckoning). The circuitry may include a micro-location chip. The geo-location technology may facilitate determination of a position of signal source (e.g., location of the tag) to an accuracy of at least 100 centimeters (cm), 75 cm, 50 cm, 25 cm, 20 cm, 10 cm, or 5 cm. In some embodiments, the electromagnetic radiation of the signal comprises ultra-wideband (UWB) radio waves, ultra-high frequency (UHF) radio waves, or radio waves utilized in global positioning system (GPS). In some embodiments, the electromagnetic radiation comprises electromagnetic waves of a frequency of at least about 300 MHz, 500 MHz, or 1200 MHz. In some embodiments, the signal comprises location and/or time data. In some embodiments, the tag utilizes Bluetooth, UWB, UHF, and/or global positioning system (GPS) technology. In some embodiments, the signal has a spatial capacity of at least about 1013 bits per second per meter squared (bit/s/m²).

In some embodiments, pulse-based ultra-wideband (UWB) technology (e.g., ECMA-368, or ECMA-369) is a wireless technology for transmitting large amounts of data at low power (e.g., less than about 1 millivolt (mW), 0.75 mW, 0.5 mW, or 0.25 mW) over short distances (e.g., of at most about 300 feet 0, 250′, 230′, 200′, or 150′). A UWB signal can occupy at least about 750 MHz, 500 MHz, or 250 MHz of bandwidth spectrum, and/or at least about 30%, 20%, or 10% of its center frequency. The UWB signal can be transmitted by one or more pulses. A component broadcasts digital signal pulses may be timed (e.g., precisely) on a carrier signal across a number of frequency channels at the same time. Information may be transmitted, e.g., by modulating the timing and/or positioning of the signal (e.g., the pulses). Signal information may be transmitted by encoding the polarity of the signal (e.g., pulse), its amplitude and/or by using orthogonal signals (e.g., pulses). The UWB signal may be a low power information transfer protocol. The UWB technology may be utilized for (e.g., indoor) location applications. The broad range of the UWB spectrum comprises low frequencies having long wavelengths, which allows UWB signals to penetrate a variety of materials, including various building fixtures (e.g., walls). The wide range of frequencies, e.g., including the low penetrating frequencies, may decrease the chance of multipath propagation errors (without wishing to be bound to theory, as some wavelengths may have a line-of-sight trajectory). UWB communication signals (e.g., pulses) may be short (e.g., of at most about 70 cm, 60 cm, or 50 cm for a pulse that is about 600 MHz, 500 MHz, or 400 MHz wide; or of at most about 20 cm, 23 cm, 25 cm, or 30 cm for a pulse that is has a bandwidth of about 1 GHz, 1.2 GHz, 1.3 GHz, or 1.5 GHz). The short communication signals (e.g., pulses) may reduce the chance that reflecting signals (e.g., pulses) will overlap with the original signal (e.g., pulse).

In some embodiments, a transitory component (e.g., an ID tag of an occupant) can include a micro-chip. The micro-chip can be a micro-location chip. The micro-chip can incorporate auto-location technology (referred to herein also as “micro-location chip”). The micro-chip may incorporate technology for automatically reporting high-resolution and/or high accuracy location information. The auto-location technology can comprise GPS, Bluetooth, or radio-wave technology. The auto-location technology can comprise electromagnetic wave (e.g., radio wave) emission and/or detection. The radio-wave technology may be any RF technology disclosed herein (e.g., high frequency, ultra-high frequency, super high frequency. The radio-wave technology may comprise UWB technology. The micro-chip may facilitate determination of its location within an accuracy of at most about 25 centimeters, 20 cm, 15 cm, 10 cm, or 5 cm. In various embodiments, the control system, sensors, transceivers, and/or antennas are configured to communicate with the micro-location chip. In some embodiments, the tag may comprise the micro-location chip. The micro-location chip may be configured to broadcast one or more signals. The signals may be omnidirectional signals. One or more component operatively coupled to the network may (e.g., each) comprise the micro-location chip. The micro-location chips (e.g., that are disposed in stationary and/or known locations) may facilitate determination of stationary components (e.g., anchors). By analyzing the time taken for a broadcast signal to reach the anchors within the transmittable distance of the tag, the location of the tag may be determined. One or more processors (e.g., of the control system) may perform an analysis of the location related signals. For example, the relative distance between the micro-chip and one or more anchors and/or other micro-chip(s) (e.g., within the transmission range limits) may be determined. The relative distance, know location, and/or stationary component localization information may be aggregated. At least one of the stationary component may be disposed in a floor, ceiling, wall, and/or mullion of a building. There may be at least 1, 2, 3, 4, 5, 8, or 10 stationary component disposed in the enclosure (e.g., in the room, in the building, and/or in the facility). At least two of the stationary component may have at least of (e.g., substantially) the same X coordinate, Y coordinate, and Z coordinate (of a Cartesian coordinate system).

In some embodiments, a control system enables locating and/or tracking one or more components (e.g., comprising auto-location technology such as the micro location chip) and/or at least one user carrying such (e.g., transitory) component. The relative location between two or more such components can be determined from information relating to received transmissions, e.g., at one or more stationary components (e.g., transceivers, antennas and/or sensors). The location of the (e.g., transitory) component may comprise geo-positioning and/or geolocation. The location of the component may an analysis of electromagnetic signals emitted from the component and/or the micro-location chip. Information that can be used to determine location includes, e.g., the received signal strength, the time of arrival, the signal frequency, and/or the angle of arrival. When determining a location of the one or more components from these metrics, a localization (e.g., using trilaterations such as triangulation) module may be implemented. The localization module may comprise a calculation and/or algorithm. The localization module may account for and/or utilize the physical layout of a building. The auto-location may comprise geolocation and/or geo-positioning. Examples of location methods may be found herein and in International Patent Application Serial No. PCT/US17/31106, filed on May 4, 2017, titled, “WINDOW ANTENNAS,” which is incorporated herein by reference in its entirety.

In some embodiments, the position of the tag may be located using one or more stationary components comprising positional sensors. A sensor can be part of (e.g., included in) a transceiver. The positional sensor(s) may be disposed in the facility (e.g., enclosure as a building, or room). The positional sensor may be part of a device ensemble or separated from a device ensemble (e.g., standalone positional sensor). The positional sensor may be operatively (e.g., communicatively) coupled to a network. The network may be a network of the facility (e.g., of the building). The network may be configured to transmit communication and power. The network may be any network disclosed herein. The network may extend to a room, a floor, several rooms, several floors, the building, or several buildings of the facility. The network may operatively (e.g., to facilitate power and/or communication) couple to one or more components. For example, the network may operatively (e.g., to facilitate power and/or communication) couple to a control system (e.g., as disclosed herein), sensor(s), emitter(s), transceiver(s), antenna, radar(s), router(s), power supply, and/or to building management system (and/or its various constituents). The network may be coupled to personal computers of users (e.g., occupants) associated with the facility (e.g., employees and/or tenants). At least part of the network may be installed as the initial network of the facility, and/or disposed in an envelope structure of the facility. The network may be operatively coupled to other devices in the facility that perform operations for, or associated with, the facility (e.g., production machinery, communication machinery, and/or service machinery). The production machinery may include computers, factory related machinery, and/or any other machinery configured to produce product(s) (e.g., printers and/or dispensers). The service machinery may include food and/or beverage related machinery, hygiene related machinery (e.g., mask dispenser, and/or disinfectant dispensers). The communication machinery may include media projectors, media display, touch screens, speakers, and/or lighting (e.g., entry, exit, and/or security lighting).

In some embodiments, at least one stationary component (e.g., ensemble) includes at least one processor and/or memory. The processor may perform computing tasks (e.g., including machine learning and/or artificial intelligence related tasks). In this manner the network can allow low latency (e.g., as disclosed herein) and faster response time for applications and/or commands. In some embodiments, the network and circuitry coupled thereto may form a distributed computing environment (e.g., comprising CPU, GPU, memory, and/or storage) for application and/or service hosting to store and/or process content close to the user's mobile circuitry (e.g., cellular device, pad, or laptop).

In some embodiments, after a component assumes the role of a coordinator, it may begin transmitting signals at fixed intervals. Each interval may comprise a contention window during which component whose signal have been detected at least twice may be joined by the coordinator into its community of components. Each time slot comprises a time interval during which a joining component may be assigned to transmit and/or receive signals. After a component is joined by a coordinator, it may begin transmitting and receiving signals to determine its distance from other joined components (e.g., topological signals).

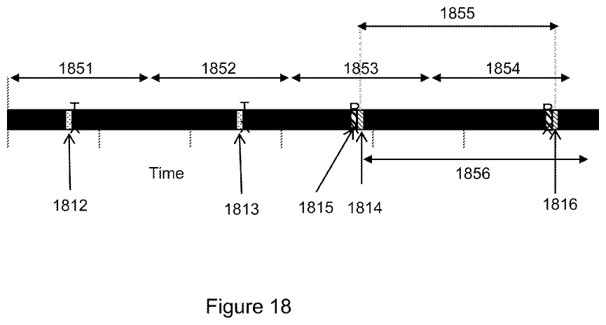

In some embodiments, during the coordination assignment process, a first components receives a bacon generated by a second component. The community may undergo a coordinator verification process. The received second component signal may be before or after the first components transmits any beacon during that time interval. The first component, sensing the beacon of the second component, can cease (e.g., back off) from transmitting any (e.g., additional) beacon, and/or remain in a listening mode (e.g., signal receiving mode). FIG. 18. shows an example of two signal intervals 1851 and 1852 during which the first component transmits beacons (e.g., coordinator assignment signals) 1812 and 1813 during a coordinator assignment process. Beacon 1812 is generated at a random time during time interval 1851, and beacon 1813 is generated at a random time during time interval 1852. The black portions of the time interval shown in FIG. 18 designates a time span at which the first component is in a listening mode (e.g., signal receiving mode). During a third time interval 1852, the first component senses a beacon 1815 of a second component. The first component may transmit one or more association signals (e.g., 1814 and 1816) to signal to any other community member different from the second component and/or to the second component that it is associated with the second components, designating the second component as the coordinator. Such association signal may direct and/or cause the other community members different from the second component to cease beaconing (e.g., stop transmitting their coordinator assignment signals), and/or transition into listening mode. When another beacon is transmitted by the second component, e.g., and received by the first component, during the “back off” period (e.g., 1855), this signal may serve as a coordinator verification signal. The coordinator verification signal may trigger assignment of the second component as a community coordinator.

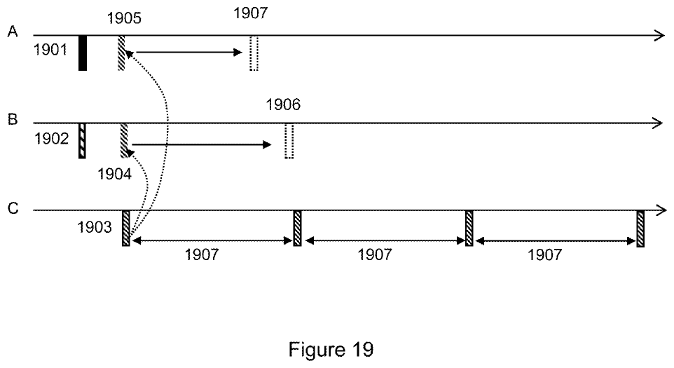

In some embodiments, a first component and a second component each send a coordinator assignment signal (e.g., beacon) at the same time (e.g., simultaneously). The selected time for sending the beacon by the first component can be randomly assigned. The selected time for sending the beacon by the second component can be randomly assigned. When such simultaneous beaconing occurs, none of the first component and the second component will become a coordinator, even these are the first signals received by other community members. Rather, a generator of a subsequent single beacon has a better chance to becoming (e.g., or will become) the coordinator. FIG. 19 shows an example of time dependent signals transmission (e.g., emission) of three components in a community of components, which components are designated as A B and C. In the example shown in FIG. 19, component A transmits a beacon 1901 at the same time as component B transits a beacon 1902, and component C transmits a beacon 1903 shortly thereafter, which signal is detected by component B as 1904 and by component A as 1905. Detection of the beacon 1903 by component A and B causes component A and B to cease emitting any otherwise emitted randomly timed beacons (e.g., 1907 and 1906 respectively), whereas component C initiates generating the coordinator signals, e.g., at fixed intervals 1907.

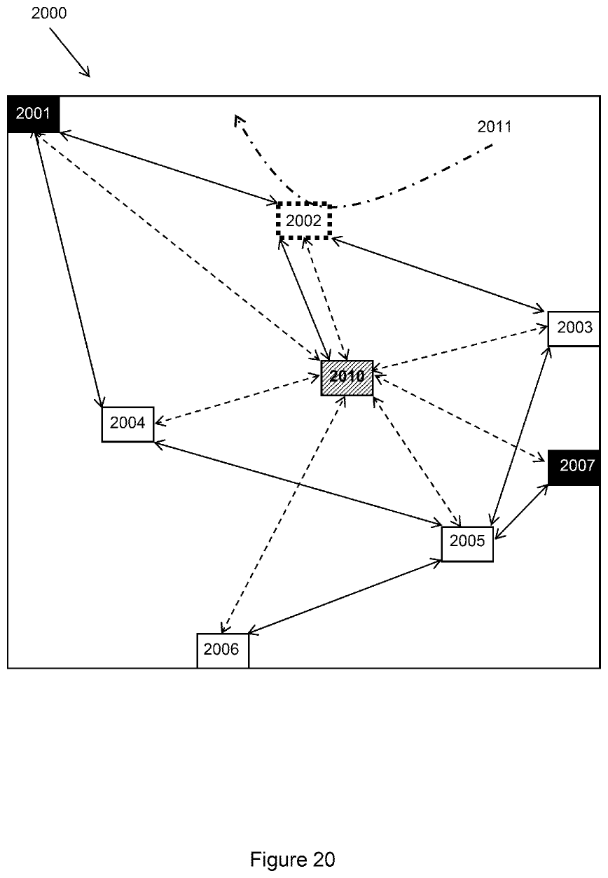

In some embodiments, coordinator components do not retain their coordinator role indefinitely, e.g., during the functioning life of the community. In some embodiments, if the topology of a community of components changes (e.g., via malfunction, addition, and/or removal of one or more component), a new topology may be determined. When a new topology is to be determined, the coordinator will provide time window for topology signaling for each of its non-coordinator community members. For example, when a mobile (e.g., Tag) components enters into the range of the community, enclosure, and/or range of the coordinator. If no coordinator is present in the community (e.g., due to removal of the old coordinator and/or its malfunctioning) a new coordinator component may be assigned. Changes in a topology of a community of components may be communicated via detection of one or more changes in signal(s) communicated by component(s) to the community. The changes in signals may include (I) a loss of signal (e.g., when a community member exits the community range and/or malfunctions), and/or (II) an introduction of a new a signal (e.g., when a mobile component enters the community range). FIG. 20 shows an example of a community of components 2000 that includes anchor components 2001 and 2007, coordinator component 2010, transitory component 2002, and other stationary components of the community 2003, 2004, 2005, and 2006. The arrows other than arrow 2011 designate signal directionality, while the arrow 2011 designates the route of translating component 2002. Dotted arrows other than 2011 designate coordination related signals (e.g., commands). Solid arrows designate distance related signals for topological mapping of the components in the community.

In some embodiments, one or more changes in signal(s) comprise changes in signals generated by a motion sensor (e.g., an accelerometer) operatively coupled to the component. Operatively coupled may include associated with, or made part of, the component of a community of components. In one embodiment, each of the components of a community of components comprises its own operatively coupled motion sensor. In one embodiment, motion sensors comprise accelerometers. In one embodiment, one or more changes in a topology may be detected (e.g., and actions initiated) by one or more components of a community of components. In one embodiment, changes in a topology of components are detected (e.g., and actions initiated) by components that are not part of a community of components (e.g., by a controller disposed outside the range of the community). In one embodiment, one or more changes to a topology of components may be communicated wirelessly and/or over one or more wires. In some embodiments, (I) if after a predetermined period of time no new component associations have been made, or expected to be made (e.g., after at least about 0.01, 0.05, 0.1, 0.5, 1, 2, 5, 10, 30, or 60 seconds) and/or (II) if after a topology of all components of a community of components is determined; a coordinator component may relinquish its role, or may receive directions to relinquish its role (e.g., directed by a controller and/or communicated through the network).

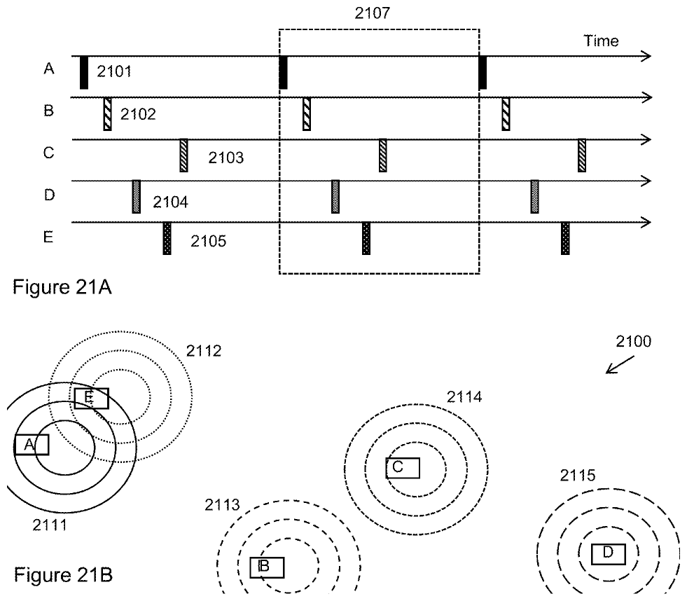

FIG. 21A schematically shows examples of time lapse diagrams of a community of components including components A, B, C, D, and E, that emit signals (e.g., location related signals) in fixed intervals such as 2107. The fixed intervals may be designated by a coordinator. The fixed interval may be a super time frame. Each of the components A-E has a designated time window within the super time frame, in which it emits its signal (e.g., 2101, 2102, 2103, 2104 and 2105 respectively). FIG. 21B schematically shows examples of horizontal cross section of signal emission by a community of components 2100 including components A, B, C, D, and E, which emitted signals 2111, 2113, 2114, 2115 and 2112 respectively, propagate in space.

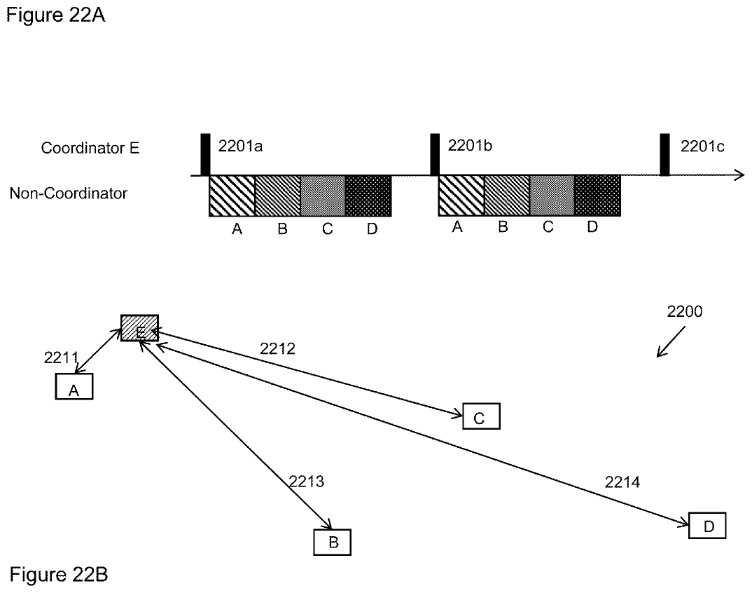

FIG. 22A shows an example of a signal related time laps 2200 depicting respective coordinator signals 2201a, 2201b, and 2201c emitted at fixed intervals by component E. One or more members of the community (e.g., each member of the community) may be assigned a time slot in which it emits the location related signal. FIG. 22A shows an example in which the coordinator assigns time slots A, B, C, and D to non-coordinator components of the community. The time interval between the coordinator signals (e.g., 2201a-2201c) may be longer than the sum of the time windows allocated to the community members, e.g., for emitting their location related signals. FIG. 22B shows an example of respective spatial arrangement of the components A-E, with component E being the coordinator. The arrows between the components A-D to the coordinator E designate communication between the coordinator and the non-coordinator components in the community.

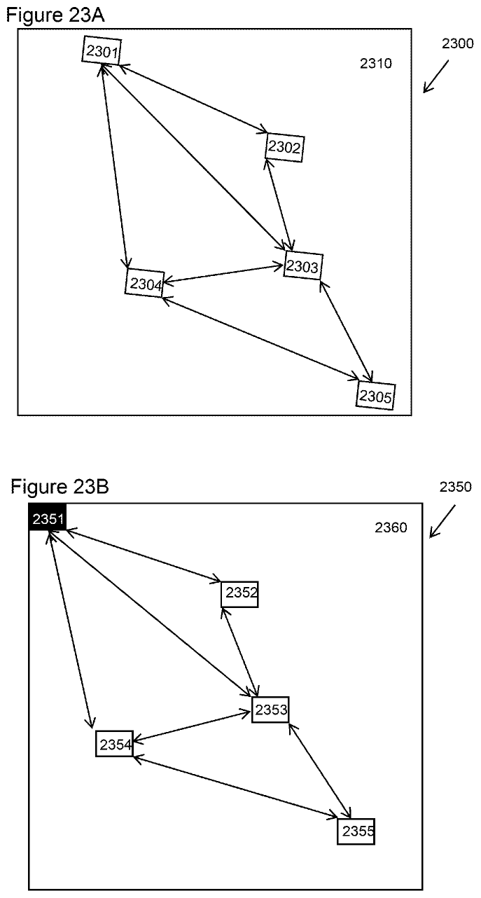

FIG. 23A shows an example 2300 of a relative spatial placement of a community of components 2301-2305 in an enclosure 2310, which community does not have an anchor component. FIG. 23B shows an example 2350 of an absolute spatial placement of a community of components 2351-2355 in an enclosure 2360, which community does have an anchor component 2351. Arrows in FIGS. 23A-23B designate signal communication between the components.

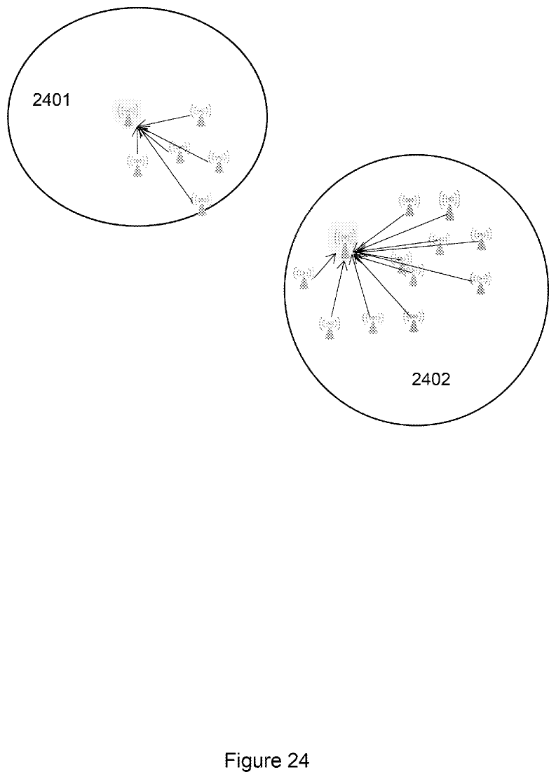

In some embodiments, a plurality of components is within range of the coordinator and form the community of components. The range may span one or more enclosures. The range may translate barriers. The barrier may comprise glass, concrete, wood, clay, stone, metal, or chalk. The barrier may comprise a wall, a floor, a door or a window. For example, more than one community of components may be installed in one or more enclosure. Not all (e.g., installed) components in an enclosure may be able to communicate with each other. In some embodiments, distances and/or structures between components may hinder (e.g., prevent) effective communication between the components. FIG. 24 shown an example of a group of components 2401 and another group of components 2402 joined forming two separate communities of components. In the example shown in FIG. 24, the two communities of components are unable to communicate (e.g., wirelessly) with each other (e.g., effectively), e.g., because of their spatial separation. Components of community 2402 may be out of range of (e.g., at least) the coordinator of community 2401. For example, the components of community 2402 may be out of range of the community member of community 2401.

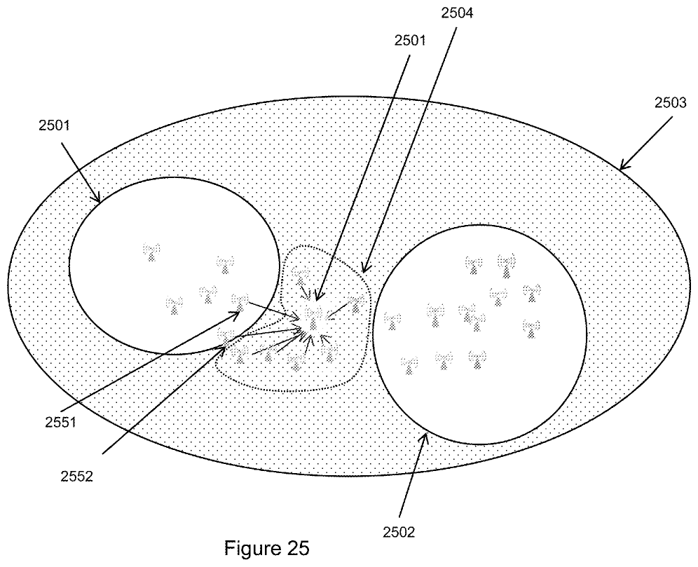

In one embodiment, two or more communities of components (e.g., during and/or after installation) that are not within communication range of each other, may be bridged by another community. Such situation may occur during formation of one or more of these communities. FIG. 25 shows an example of a plurality of components in area 2504 disposed between a first community of components 2501 and a second community of components 2502. In one embodiment, when components in the area 2504 may detect that they have been placed within (e.g., wireless) communication range of communities 2501 and/or 2502. Components in area 2504 may cease transmissions of signals until a determination of the topologies of the forming communities (e.g., 2501 and/or 2502) are completed. The detection of other forming communities may be via detection of any signal transmitted during the community and/or topology determinate process (e.g., any signal that follows assignment of a coordinator of a community). Such signal may comprise association signals of community member to a coordinator, coordinator confirmation signals, and/or ranging signals broadcast by one or more components of the communities (e.g., 2501 and/or 2502). Once a topology of adjacent coordinator component is determined and/or assigned, all the components of in the intermediate area (e.g., 2504) may be joined into a community of components, and a topology of the adjacent communities (e.g., communities 2501 and 2502) has been determined, components in the intermediate area (e.g., 2504) may initiate their coordinator assignment process, proceed identifying their community members, and finalize the topology of all community members. The community members of the newly formed intermediate community may include community members from adjacent communities. FIG. 25 shows an example of an intermediate community having a coordinator 2501 that includes community members in the area 2504 as well as some community members that belong to community 2501 (e.g., components 2551 and 2552). In this manner, accurate (e.g., relative and/or absolute) localization of large overlapping communities of components may be determined, which overall spatial arrangement of the communities exceeds the range of a single coordinator component. Known topologies of the communities of components in area 2503, may be communicated between at least two communities by at least one component of the two communities (e.g., by 2551 and/or 2552) to determine positions of all the components of the two or more communities with respect to one another. In the example shown in FIG. 25, the community forming around coordinator 2501 overlaps community 2501 (with overlap components 2551 and 2552 within range of coordinator 2501 and the coordinator of group 2501), wherein community 2502 has no overlapping members.

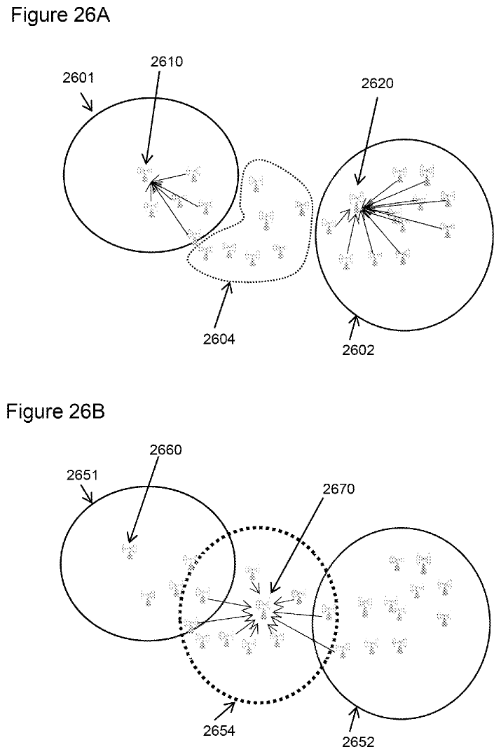

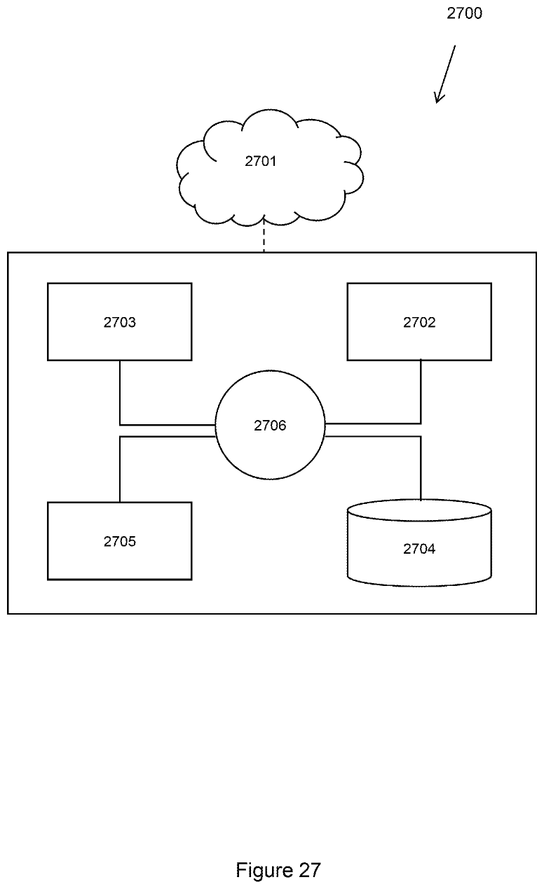

FIG. 26A shows an example in which a community of components in area 2601 is formed or forming around coordinator 2610, and a community of components in area 2602 is formed or forming around coordinator 2620. Two separated community of components may be formed simultaneously, or sequentially. Two separated community of components may be formed non-simultaneously with or without a time overlap. FIG. 26 shows an example of components in area 2604 that are out of range of both coordinator 2610 and coordinator 2620, and thus do not below to communities 2602 or 2601, and do not join their community formation operation.

FIG. 26B shows an example in which a community of components in area 2604 is formed or forming around coordinator 2670, after communities in areas 2501 and 2552 have been formed and their members have been (e.g., relatively or absolutely) determined. Formation of the component community in area 2654 includes community members that have been assigned an (absolute or relative) location, as they also belong to the communities in areas 2651 and 2652. Those components are disposed in the overlapping regions of area 2651 with 2654 and overlapping regions of area 2654 with 2652. After the community in area 2654 is assigned a coordinator 2670, the (e.g., relative or absolute) location of its component can be determined. In this manner the location of all components in regions 2651, 2654, and 2652 can be determined, even if not all components are within range of a single coordinator (e.g., 2670). If location of at least one component is absolutely determined, the location of all other components can be absolutely determined (e.g., in at least one Cartesian direction).

In some embodiments, one or more controllers discussed herein monitor and/or direct (e.g., physical) alteration of the operating conditions of components, software, algorithms and/or methods described herein. Control may comprise regulate, manipulate, restrict, direct, monitor, adjust, modulate, vary, alter, restrain, check, guide, or manage. Control may comprise controlling a control variable (e.g., temperature, power, voltage, and/or current). Control can comprise real time or off-line control. A calculation utilized by the controller can be done in real time, and/or off line. A controller may be a manual or a non-manual controller. The control may be manual or automatic. A controller may be an automatic controller. A controller may operate upon request. A controller may be a programmable controller. The controller may operate according to a feedback and/or feed forward control scheme. The controller may operate according to a closed loop and/or open loop control scheme. The feed forward and/or open loop control may comprise a calculation (e.g., of a simulation). The controller may be programed. A controller may comprise a processing unit (e.g., CPU or GPU). A controller may receive an input (e.g., from at least one sensor). The controller may comprise circuitry, electrical wiring, optical wiring, socket, and/or outlet. A controller may deliver an output. A controller may comprise multiple (e.g., sub-) controllers. The controller may be a part of a control system. A control system may comprise a master controller, network controller, local controller. The local controller may be a window controller (e.g., controlling an optically switchable window), enclosure controller, or component controller. For example, a controller may be a part of a hierarchal control system (e.g., comprising a main controller that directs one or more controllers, e.g., network controllers, local (e.g., window) controllers, enclosure controllers, and/or component controllers). The local controller may control one or more devices (e.g., and be directly coupled to the devices). The local controller may be disposed proximal to the one or more devices it is controlling. For example, the local controller may control one or more components including an optically switchable device (e.g., IGU), an antenna, a sensor, a transceiver, and/or an output device (e.g., a light source, sounds source, smell source, gas source, HVAC outlet, or heater). The network controller may direct one or more window controllers, one or more enclosure controllers, one or more component controllers, or any combination thereof. For example, the network controller may be control a plurality of window controllers. The plurality of window controllers may be disposed in a portion of a facility (e.g., in a portion of a building). The portion of the facility may be a floor of a facility. For example, a network controller may be assigned to a floor. For example, a network controller may be assigned to a portion of a floor. For example, a network controller may be assigned to a portion of the window controllers disposed in the facility. For example, a network controller may be assigned to a portion of the floors of a facility. A master controller may be coupled to one or more network controllers. The network controller may be disposed in the facility. The master controller may be disposed in the facility, or external to the facility. The master controller may be disposed in the cloud. The controller may be a part of, or be operatively coupled to, a building management system. A controller may receive one or more inputs. A controller may generate one or more outputs. The controller may be a single input single output controller (SISO) or a multiple input multiple output controller (MIMO). A controller may interpret an input signal received. A controller may acquire data from the one or more components (e.g., sensors). Acquire may comprise receive or extract. The data may comprise measurement, estimation, determination, generation, or any combination thereof. A controller may comprise feedback control. A controller may comprise feed-forward control. Control may comprise on-off control, proportional control, proportional-integral (PI) control, or proportional-integral-derivative (PID) control. Control may comprise open loop control, or closed loop control. A controller may comprise closed loop control. A controller may comprise open loop control. A controller may comprise a user interface. A user interface may comprise (or operatively coupled to) a keyboard, keypad, mouse, touch screen, microphone, speech recognition package, camera, imaging system, or any combination thereof. Outputs may include a display (e.g., screen), speaker, or printer. FIG. 1 shows an example of a control system architecture 110 comprising a master controller that controls network controllers, that in turn control local controllers. The local controllers in FIG. 1 can control one or more: IGUs, output devices, and sensors. In some embodiments, a local controller controls one or more IGUs, one or more sensors, one or more output devices, or any combination thereof. FIG. 1 shows an example of a configuration in which the master controller is operatively coupled (e.g., wirelessly and/or wired) to a building management system (BMS) and to a database. Arrows in FIG. 1 represent communication pathways. The master controller may be operatively coupled (e.g., wired and/wirelessly) to an external source. The external source may comprise a network. The external source may comprise one or more sensors or output device. The external source may comprise a cloud based application and/or database. The communication may be wired and/or wireless. The external source may be disposed external to the facility. For example, the external source may comprise one or more sensors and/or antennas disposed, e.g., on a wall or on a ceiling of the facility. The communication may be monodirectional or bidirectional. In the example shorn in FIG. 1, the communication all communication arrows are meant to be bidirectional.

The methods, systems and/or the components described herein may comprise a control system. A control system can be in communication with any of the apparatuses (e.g., components comprising actuators, signal emitting devices, or sensors) described herein. Components may be of the same type or of different types (e.g., as described herein). For example, the control system may be in communication with a first component and/or with a second component. A control system may control one or more component. A control system may control one or more components of a building management system (e.g., lightening, security, and/or air conditioning system). A controller may regulate at least one (e.g., environmental) characteristic of an enclosure. A control system may regulate the enclosure environment using any component, e.g., component(s) of the building management system. For example, a control system may regulate energy supplied by a heating element and/or by a cooling element. For example, a control system may regulate velocity of an air flowing through a vent to and/or from the enclosure.

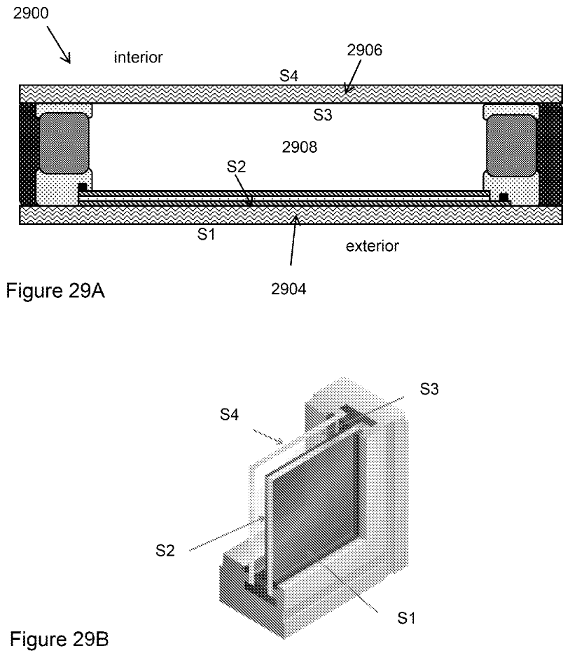

A control system may comprise a processor. A processor may be a processing unit. A controller may comprise a processing unit. A processing unit may be central. A processing unit may comprise a central processing unit (abbreviated herein as “CPU”). A processing unit may be a graphic processing unit (abbreviated herein as “GPU”). A controller(s) or control mechanisms (e.g., comprising a computer system) may be programmed to implement one or more methods of the disclosure. A processor may be programmed to implement methods of the disclosure. A controller may control at least one component of the forming systems and/or components disclosed herein. FIG. 29 is a schematic representation of a computer system 2900 that is programmed or otherwise configured to one or more operations of any of the methods provided herein. A computer system can control (e.g., direct, monitor, and/or regulate) various features of the methods, components and systems, such as, for example, control heating, cooling, lightening, and/or venting of an enclosure, or any combination thereof. A computer system can be part of, or be in communication with, any component or combination of components disclosed herein. A computer may be coupled to one or more mechanisms disclosed herein, and/or any parts thereof. For example, a computer may be coupled to one or more sensors, transceivers, valves, switches, lights, windows (e.g., IGUs), motors, pumps, optical components, or any combination thereof.

A computer system can include a processing unit (e.g., 2706) (also “processor,” “computer” and “computer processor” used herein). A computer system may include memory or memory location (e.g., 2702) (e.g., random-access memory, read-only memory, flash memory), electronic storage unit (e.g., 1104) (e.g., hard disk), communication interface (e.g., 2703) (e.g., network adapter) for communicating with one or more other systems, and peripheral devices (e.g., 2705), such as cache, other memory, data storage and/or electronic display adapters. In an exemplary embodiment, the memory 2702, storage unit 2704, interface 2703, and peripheral devices 2705 are in communication with the processing unit 2706. The communication may comprise (e.g., be through) a communication bus (solid lines), such as a motherboard. The communication comprises wireless communication. The wires may comprise coaxial wires or twisted pair. The communication network may comprise an antenna. The storage unit can be a data storage unit (or data repository) for storing data. A computer system can be operatively coupled to a computer network (“network”) (e.g., 2701) with the aid of the communication interface. The communication through the network may comprise wired or wireless communication. The network can be the Internet, an internet and/or extranet, or an intranet and/or extranet that is in communication with the Internet. The communication may be through ethernet. In some cases, the network comprises a telecommunication and/or data network. The network can include one or more computer servers, which can enable distributed computing, such as cloud computing. The one or more servers may be operatively coupled to the network. The one or more servers may be disposed in the enclosure or out of the enclosure. The one or more servers may be disposed in the facility (e.g., building) in which the enclosure is disposed or out of the facility. The one or more servers may be disposed in the facility of a company manufacturing at least a portion (e.g., component) of the enclosure (e.g., that manufactures the optically switchable window(s)). A network, in some cases with the aid of the computer system, can implement a peer-to-peer network, which may enable devices coupled to the computer system to behave as a client or a server.

A processing unit can execute a sequence of machine readable instructions, which can be embodied in a code, program and/or software. Instructions may be stored in a memory location, such as the memory 2702. Instructions can be directed to the processing unit, which can program or otherwise configure the processing unit to implement methods of the present disclosure. Examples of operations performed by the processing unit can include fetch, decode, execute, calculate, and write back. A processing unit may interpret and/or execute instructions. A processor may include a microprocessor, a data processor, a central processing unit (CPU), a graphical processing unit (GPU), a system-on-chip (SOC), a co-processor, a network processor, an application specific integrated circuit (ASIC), an application specific instruction-set processor (ASIPs), a controller, a programmable logic device (PLD), a chipset, a field programmable gate array (FPGA), or any combination thereof. A processing unit can be part of a circuit, such as an integrated circuit. One or more other components of the system 2700 can be included in the circuitry.

A storage unit can store files, such as drivers, libraries and saved programs. A storage unit can store user data (e.g., user preferences and user programs). In some cases, a computer system can include one or more additional data storage units that are external to the computer system, such as located on a remote server that is in communication with the computer system, e.g., through an intranet or the Internet.

A computer system can communicate with one or more remote computer systems through a network. For instance, a computer system can communicate with a remote computer system of a user (e.g., operator). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. A user (e.g., client) can access a computer system via the network.

Methods as described herein can be implemented by way of machine (e.g., computer processor) executable code stored on an electronic storage location of the computer system, such as, for example, on the memory or electronic storage unit. Machine executable or machine-readable code can be provided in the form of software. During use, a processor can execute the code. In some cases, code can be retrieved from the storage unit and stored on the memory for ready access by the processor. In some situations, the electronic storage unit can be precluded, and machine-executable instructions are stored on memory.

The code can be pre-compiled and/or configured for use with a machine having a processer adapted to execute the code or can be compiled during runtime. Code can be supplied in a programming language that can be selected to enable the code to execute in a pre-compiled or as-compiled fashion.

In some embodiments, a processor comprises a code. The code can be program instructions. The program instructions may cause the at least one processor (e.g., computer) to direct a control scheme (e.g., feed forward and/or feedback control loop). In some embodiments, program instructions cause the at least one processor to direct a closed loop and/or open loop control scheme. Control may be based at least in part on one or more sensor readings (e.g., sensor data). One controller may direct a plurality of operations. At least two operations may be directed by different controllers. In some embodiments, a different controller may direct at least two operations of a plurality of operations (e.g., of operations (a), (b) and (c)). In some embodiments, different controllers may direct at least two of operations of a plurality of operations (e.g., of operations (a), (b) and (c)). In some embodiments, a non-transitory computer-readable medium cause each a different computer to direct at least two operations of a plurality of operations (e.g., of operations (a), (b) and (c)). In some embodiments, different non-transitory computer-readable mediums cause each a different computer to direct at least two of operations of a plurality of operations (e.g., of operations (a), (b) and (c)). A controller and/or computer readable media may direct any of the apparatuses or components disclosed herein. A controller and/or computer readable media may direct any operations of the methods disclosed herein.

In some embodiments, the tintable window comprises an electrochromic device (referred to herein as an “EC device” (abbreviated herein as ECD), or “EC”). An EC device may comprise at least one coating that includes at least one layer. The at least one layer can comprise an electrochromic material. In some embodiments, the electrochromic material exhibits a change from one optical state to another, e.g., when an electric potential is applied across the EC device. The transition of the electrochromic layer from one optical state to another optical state can be caused, e.g., by reversible, semi-reversible, or irreversible ion insertion into the electrochromic material (e.g., by way of intercalation) and a corresponding injection of charge-balancing electrons. For example, the transition of the electrochromic layer from one optical state to another optical state can be caused, e.g., by a reversible ion insertion into the electrochromic material (e.g., by way of intercalation) and a corresponding injection of charge-balancing electrons. Reversible may be for the expected lifetime of the ECD. Semi-reversible refers to a measurable (e.g., noticeable) degradation in the reversibility of the tint of the window over one or more tinting cycles. In some instances, a fraction of the ions responsible for the optical transition is irreversibly bound up in the electrochromic material (e.g., and thus the induced (altered) tint state of the window is not reversible to its original tinting state). In various EC devices, at least some (e.g., all) of the irreversibly bound ions can be used to compensate for “blind charge” in the material (e.g., ECD).

In some implementations, suitable ions include cations. The cations may include lithium ions (Li+) and/or hydrogen ions (H+) (i.e., protons). In some implementations, other ions can be suitable. Intercalation of the cations may be into an (e.g., metal) oxide. A change in the intercalation state of the ions (e.g., cations) into the oxide may induce a visible change in a tint (e.g., color) of the oxide. For example, the oxide may transition from a colorless to a colored state. For example, intercalation of lithium ions into tungsten oxide (WO3-y (0<y≤˜0.3)) may cause the tungsten oxide to change from a transparent state to a colored (e.g., blue) state. EC device coatings as described herein are located within the viewable portion of the tintable window such that the tinting of the EC device coating can be used to control the optical state of the tintable window.

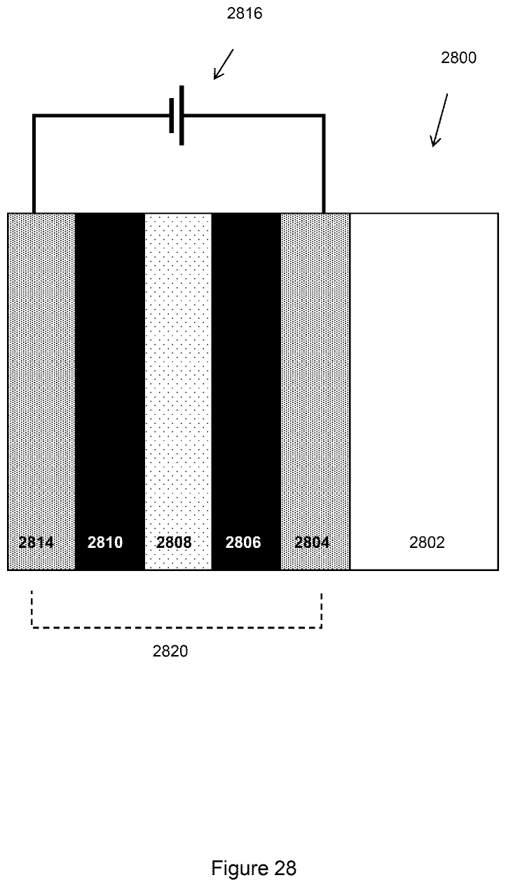

FIG. 28 shows an example of a schematic cross-section of an electrochromic device 2800 in accordance with some embodiments is shown in FIG. 28. The EC device coating is attached to a substrate 2802, a transparent conductive layer (TCL) 2804, an electrochromic layer (EC) 2806 (sometimes also referred to as a cathodically coloring layer or a cathodically tinting layer), an ion conducting layer or region (IC) 2808, a counter electrode layer (CE) 2830 (sometimes also referred to as an anodically coloring layer or anodically tinting layer), and a second TCL 2814. Elements 2804, 2806, 2808, 2810, and 2814 are collectively referred to as an electrochromic stack 2820. A voltage source 2816 operable to apply an electric potential across the electrochromic stack 2820 effects the transition of the electrochromic coating from, e.g., a clear state to a tinted state. In other embodiments, the order of layers is reversed with respect to the substrate. That is, the layers are in the following order: substrate, TCL, counter electrode layer, ion conducting layer, electrochromic material layer, TCL.

In various embodiments, the ion conductor region (e.g., 2808) may form from a portion of the EC layer (e.g., 2806) and/or from a portion of the CE layer (e.g., 2810). In such embodiments, the electrochromic stack (e.g., 2820) may be deposited to include cathodically coloring electrochromic material (the EC layer) in direct physical contact with an anodically coloring counter electrode material (the CE layer). The ion conductor region (sometimes referred to as an interfacial region, or as an ion conducting substantially electronically insulating layer or region) may form where the EC layer and the CE layer meet, for example through heating and/or other processing steps. Examples of electrochromic devices fabricated without depositing a distinct ion conductor material can be found in U.S. patent application Ser. No. 13/462,725, filed May 2, 2012, titled “ELECTROCHROMIC DEVICES,” which is herein incorporated by reference in its entirety. In some embodiments, an EC device coating may include one or more additional layers such as one or more passive layers. Passive layers can be used to improve certain optical properties, to provide moisture, and/or to provide scratch resistance. These and/or other passive layers can serve to hermetically seal the EC stack 2820. Various layers, including transparent conducting layers (such as 2804 and 2814), can be treated with anti-reflective and/or protective layers (e.g., oxide and/or nitride layers).

In certain embodiments, the electrochromic device is configured to (e.g., substantially) reversibly cycle between a clear state and a tinted state. Reversible may be within an expected lifetime of the ECD. The expected lifetime can be at least about 5, 10, 15, 25, 50, 75, or 100 years. The expected lifetime can be any value between the aforementioned values (e.g., from about 5 years to about 100 years, from about 5 years to about 50 years, or from about 50 years to about 100 years). A potential can be applied to the electrochromic stack (e.g., 2820) such that available ions in the stack that can cause the electrochromic material (e.g., 2806) to be in the tinted state reside primarily in the counter electrode (e.g., 2810) when the window is in a first tint state (e.g., clear). When the potential applied to the electrochromic stack is reversed, the ions can be transported across the ion conducting layer (e.g., 2808) to the electrochromic material and cause the material to enter the second tint state (e.g., tinted state).

It should be understood that the reference to a transition between a clear state and tinted state is non-limiting and suggests only one example, among many, of an electrochromic transition that may be implemented. Unless otherwise specified herein, whenever reference is made to a clear-tinted transition, the corresponding device or process encompasses other optical state transitions such as non-reflective-reflective, and/or transparent-opaque. In some embodiments, the terms “clear” and “bleached” refer to an optically neutral state, e.g., untinted, transparent and/or translucent. In some embodiments, the “color” or “tint” of an electrochromic transition is not limited to any wavelength or range of wavelengths. The choice of appropriate electrochromic material and counter electrode materials may govern the relevant optical transition (e.g., from tinted to untinted state).

In certain embodiments, at least a portion (e.g., all of) the materials making up electrochromic stack are inorganic, solid (i.e., in the solid state), or both inorganic and solid. Because various organic materials tend to degrade over time, particularly when exposed to heat and UV light as tinted building windows are, inorganic materials offer an advantage of a reliable electrochromic stack that can function for extended periods of time. In some embodiments, materials in the solid state can offer the advantage of being minimally contaminated and minimizing leakage issues, as materials in the liquid state sometimes do. One or more of the layers in the stack may contain some amount of organic material (e.g., that is measurable). The ECD or any portion thereof (e.g., one or more of the layers) may contain little or no measurable organic matter. The ECD or any portion thereof (e.g., one or more of the layers) may contain one or more liquids that may be present in little amounts. Little may be of at most about 100 ppm, 10 ppm, or 1 ppm of the ECD. Solid state material may be deposited (or otherwise formed) using one or more processes employing liquid components, such as certain processes employing sol-gels, physical vapor deposition, and/or chemical vapor deposition.

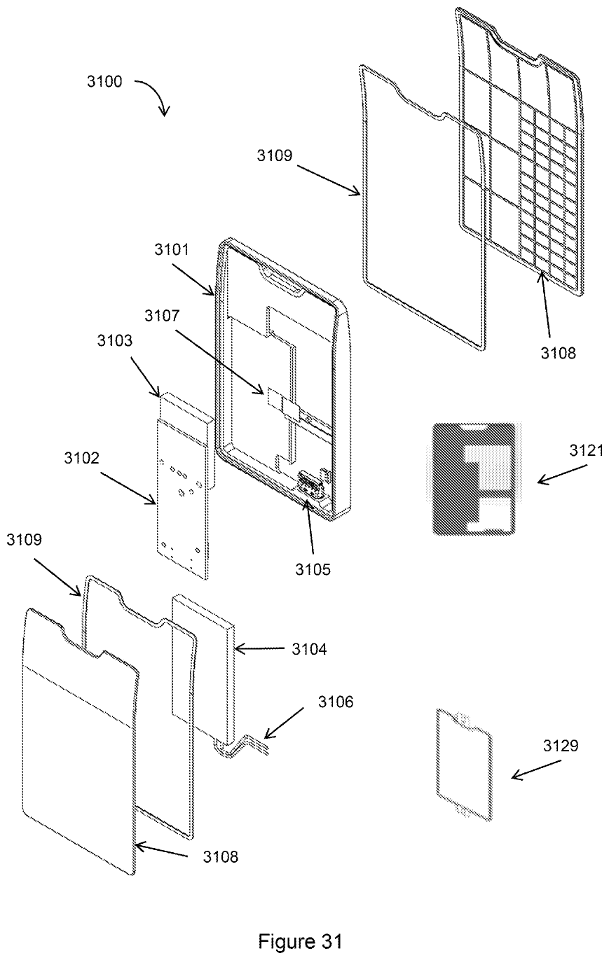

FIGS. 31A and 31B show an example of a cross-sectional view of a tintable window embodied in an insulated glass unit (“IGU”) 3200, in accordance with some implementations. The terms “IGU,” “tintable window,” and “optically switchable window” can be used interchangeably herein. It can be desirable to have IGUs serve as the fundamental constructs for holding electrochromic panes (also referred to herein as “lites”) when provided for installation in a building. An IGU lite may be a single substrate or a multi-substrate construct. The lite may comprise a laminate, e.g., of two substrates. IGUs (e.g., having double- or triple-pane configurations) can provide a number of advantages over single pane configurations. For example, multi-pane configurations can provide enhanced thermal insulation, noise insulation, environmental protection and/or durability, when compared with single-pane configurations. A multi-pane configuration can provide increased protection for an ECD. For example, the electrochromic films (e.g., as well as associated layers and conductive interconnects) can be formed on an interior surface of the multi-pane IGU and be protected by an inert gas fill in the interior volume (e.g., 3208) of the IGU. The inert gas fill may provide at least some (heat) insulating function for an IGU. Electrochromic IGUs may have heat blocking capability, e.g., by virtue of a tintable coating that absorbs (and/or reflects) heat and light.

In some embodiments, an “IGU” includes two (or more) substantially transparent substrates. For example, the IGU may include two panes of glass. At least one substrate of the IGU can include an electrochromic device disposed thereon. The one or more panes of the IGU may have a separator disposed between them. An IGU can be a hermetically sealed construct, e.g., having an interior region that is isolated from the ambient environment. A “window assembly” may include an IGU. A “window assembly” may include a (e.g., stand-alone) laminate. A “window assembly” may include one or more electrical leads, e.g., for connecting the IGUs and/or laminates. The electrical leads may operatively couple (e.g., connect) one or more electrochromic devices to a voltage source, switches and the like, and may include a frame that supports the IGU or laminate. A window assembly may include a window controller, and/or components of a window controller (e.g., a dock).

FIG. 29A shows an example implementation of an IGU 2900 that includes a first pane 2904 having a first surface S1 and a second surface S2. In some implementations, the first surface S1 of the first pane 2904 faces an environment exterior to the enclosure, such as an outdoors or outside environment. The IGU 2900 also includes a second pane 2906 having a first surface S3 and a second surface S4. In some implementations, the second surface (e.g., S4) of the second pane (e.g., 2906) faces an interior environment of an enclosure, such as an inside environment of a home, building, vehicle, or compartment thereof (e.g., an enclosure therein such as a room).

In some implementations, the first and the second panes (e.g., 2904 and 2906) are transparent or translucent, e.g., at least to light in the visible spectrum. For example, each of the panes (e.g., 2904 and 2906) can be formed of a glass material. The glass material may include architectural glass, and/or shatter-resistant glass. The glass may comprise a silicon oxide (SOx). The glass may comprise a soda-lime glass or float glass. The glass may comprise at least about 75% silica (SiO₂). The glass may comprise oxides such as Na₂O, or CaO. The glass may comprise alkali or alkali-earth oxides. The glass may comprise one or more additives. The first and/or the second panes can include any material having suitable optical, electrical, thermal, and/or mechanical properties. Other materials (e.g., substrates) that can be included in the first and/or the second panes are plastic, semi-plastic and/or thermoplastic materials, for example, poly(methyl methacrylate), polystyrene, polycarbonate, allyl diglycol carbonate, SAN (styrene acrylonitrile copolymer), poly(4-methyl-1-pentene), polyester, and/or polyamide. The first and/or second pane may include mirror material (e.g., silver). In some implementations, the first and/or the second panes can be strengthened. The strengthening may include tempering, heating, and/or chemically strengthening.

In various embodiments, a network infrastructure supports a control system for one or more windows such as electrochromic (e.g., tintable) windows. The control system may comprise one or more controllers operatively coupled (e.g., directly or indirectly) to one or more windows. The enclosure comprises optically switchable devices. The optically switchable devices may include tintable windows, smart windows, and/or electrochromic windows. Optically switchable devices may comprise a liquid crystal device, or a suspended particle device. For example, a liquid crystal device and/or a suspended particle device may be implemented instead of, or in addition to, an electrochromic device.

In some embodiments, a tintable exhibits a (e.g., controllable and/or reversible) change in at least one optical property of the window, e.g., when a stimulus is applied. The stimulus can include an optical, electrical and/or magnetic stimulus. For example, the stimulus can include an applied voltage. One or more tintable windows can be used to control lighting and/or glare conditions, e.g., by regulating the transmission of solar energy propagating through them. One or more tintable windows can be used to control a temperature within a building, e.g., by regulating the transmission of solar energy propagating through them. Control of the solar energy may control heat load imposed on the interior of the facility (e.g., building). The control may be manual and/or automatic. The control may be used for maintaining one or more requested (e.g., environmental) conditions, e.g., occupant comfort. The control may include reducing energy consumption of a heating, ventilation, air conditioning and/or lighting systems. At least two of heating, ventilation, and air conditioning may be induced by separate systems. At least two of heating, ventilation, and air conditioning may be induced by one system. The heating, ventilation, and air conditioning may be induced by a single system (abbreviated herein as “HVAC). In some cases, tintable windows may be responsive to one or more environmental sensors and/or user control. Tintable windows may comprise (e.g., may be) electrochromic windows. The windows may be located in the range from the interior to the exterior of a structure (e.g., facility, e.g., building). However, this need not be the case. Tintable windows may operate using liquid crystal devices, suspended particle devices, microelectromechanical systems (MEMS) devices (such as microshutters), or any technology known now, or later developed, that is configured to control light transmission through a window. Windows with MEMS devices for tinting are described in U.S. patent application Ser. No. 14/443,353, filed May 15, 2015, titled “MULTI-PANE WINDOWS INCLUDING ELECTROCHROMIC DEVICES AND ELECTROMECHANICAL SYSTEMS DEVICES,” which is herein incorporated by reference in its entirety. In some cases, one or more tintable windows can be located within the interior of a building, e.g., between a conference room and a hallway. In some cases, one or more tintable windows can be used in automobiles, trains, aircraft, and other vehicles, e.g., in lieu of a passive and/or non-tinting window.

In some embodiments, a transitory component includes a housing. The transitory component may be a badge or tag that is carried by a person or is coupled (e.g., attached or affixed) to an object (e.g., an asset). The housing may comprise at least one material suitable for supporting internal electronics and/or covers for enclosing the electronics. The material may comprise a metal, an allotrope of elemental carbon, a ceramic, a polymer, or a resin. The metal may be an elemental metal or a metal alloy. The material may comprise a composite material. The material may be a stiff material. The material may comprise carbon fibers or glass fibers. The material may comprise an organic polymer (e.g., carbon based polymer). The material may comprise Bakelite (polyoxybenzylmethylenglycolanhydride). The material may comprise plastic. The material may be resistant to heat, scratches, and/or organic solvents (e.g., acetone, alkanes, benzene, toluene, hydrofuran, and/or alcohols). The material may or may not be an insulator (e.g., have low electrical conductivity). The material may or may not be flammable. The material may have a tensile strength of at least about 80 mega Pascals (MPa), 85 MPa, 90 MPa, 100 MPa, 110 MPa, or 120 MPa (e.g., at ambient temperature and pressure such as at 25° C. and at 1 Atmosphere). The material may have a hardness of at least about 60 N/mm2, 80 N/mm2, 90 N/mm2, 100 N/mm2, or 110 N/mm2 (e.g., at ambient temperature and pressure such as at 25° C. and at 1 Atmosphere). The hardness may be Rockwell B, or Vickers hardness. The material may have an impact resistance of at least about 60 Kilojoule per meter (KJ/m), 65 KJ/m, 70 KJ/m, or 75 KJ/m (e.g., at ambient temperature and pressure such as at 25° C. and at 1 Atmosphere). The material may have a maximum working temperature of at least about 100° C., 150° C., 180° C., 200° C., 500° C., or 600° C. The material may have a surface resistivity of at most about 106 or, 109 ohm (e.g., at ambient temperature and pressure such as at 25° C. and at 1 Atmosphere). The material may have an electrical resistivity of at least about 2 ohm/cm, 2.5 ohm/cm, 3 ohm/cm, 3.5 ohm/cm or 4.0 ohm/cm (e.g., at ambient temperature and pressure such as at 25° C. and at 1 Atmosphere). The material may have a modulus of elasticity of at least about 60 Giga Pascals (GPa), 65 GPa, 68 GPa, 70 GPa, 75 GPa, or 80 GPa (e.g., at ambient temperature and pressure such as at 25° C. and at 1 Atmosphere). The material may or may not be transparent to electrogenic radiation. The electromagnetic radiation may comprise radiation in the ultraviolet, visible light, infrared light, or radio wave wavelength regimes.

In some embodiments, the housing includes a plurality of materials or a plurality of material classes. For example, the front and back of the housing can comprise a first material of a first class (e.g., polymer), and the rim of the housing may comprise a second material of a second (e.g., metals). The first material may be different by at least one material characteristic, from the second class of material. The material characteristic may comprise material composition, material type, electrical resistance, tensile strength, hardness, impact resistance, maximum working temperature, surface resistivity, electrical resistivity, modules of elasticity, flammability, resistance to scratches, or resistance to organic solvents. The at least one material characteristic may comprise any material characteristic disclosed herein. In some embodiments, at least a portion of the cover may comprise an external coating. The coating may comprise a visible color. The coating may comprise a powdered color.

In some embodiments, the circuitry is separated from the ambient environment by a cover. The cover may be at least partially transparent to electromagnetic waves. The covers may be formed of a material that transmits radio signal therethrough. The housing may support a port that is configured to transmit data and/or power to the internal electronic circuitry. The internal electronic circuitry may include at least one circuit board, at least one antenna, and at least one (e.g., rechargeable) battery. The battery may have a current of at least about 200 milliamperes (ma), 240 ma, 360 ma, 370 ma, 420 ma, or 500 ma. The battery may be charged multiple times, e.g., upon its (e.g., substantial) depletion. For example, the battery may be charged at least about 100 times, 250 times, 500 times, 750 times, or 1000 times. The battery may be charged a number of times between the aforementioned number of times. The antenna may be integrated with and/or separate from the circuit board(s). The battery may be charged via a battery charging circuit connected to the port and/or charged wirelessly. The port may transmit data for updating firmware on the at least one circuit board. The firmware updates may be perform at least partially wirelessly. The battery may provide power to the at least one circuit board and/or to various other internal electronic component(s). The circuit board(s) may include at least an ultra-wide band radio and/or a programmable microcontroller. The antenna(s) may include an ultra-wide band antenna and/or a Bluetooth (BLE) Low energy antenna. The BLE antenna may be connected to a Bluetooth low energy radio. The BLE antenna and/or BLE radio may be connected to the circuit board(s). The internal electronics may include an accelerometer connected to the circuit board(s). The transitory component (e.g., the identification tag) may be three dimensional. The three-dimensional transitory component may be sized (e.g. height, width, thickness) to minimize its overall dimensions. The overall dimensions (e.g., fundamental length scale) may be the minimum required to contain and support the internal components. The overall dimensions may be configured to allow for external access to the port (e.g., to form electrical connection). The transitory component may have surfaces that taper on one of its sides, e.g., to minimize the overall dimensions, ease usage, ease storage, and/or increase aesthetic appeal, of the transitory component.

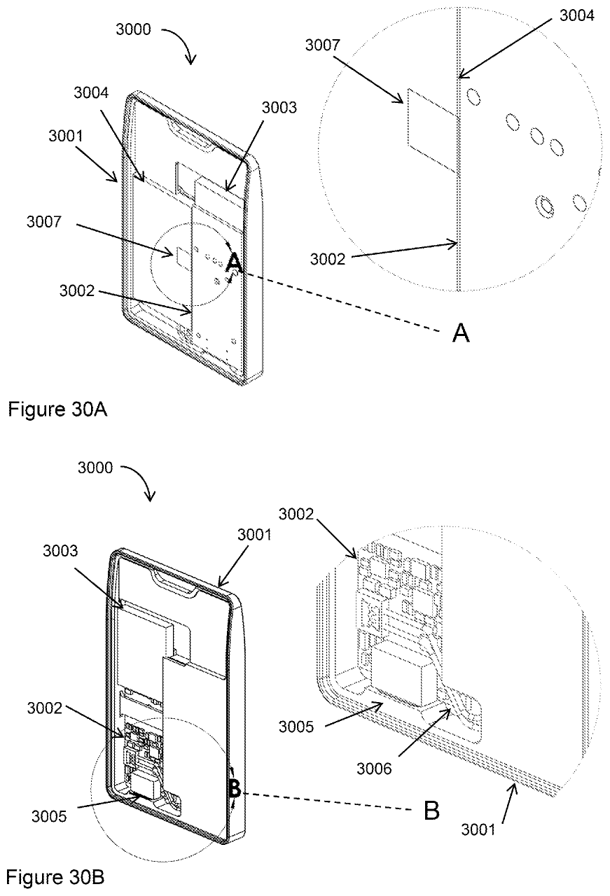

FIGS. 30A and 30B show an example of a portion of a transitory component 3000, which may be a badge or tag that is carried by a person and/or an object (e.g., an ID tag). The tag 3000 includes a housing 3001 that supports internal electronics and covers (not shown in these Figures). The housing 3001 may be made from any material suitable for supporting the internal electronics (e.g. aluminum and/or other metals or plastics), and may be formed to create a luxurious look and feel (e.g. anodized aluminum, stainless steel, etc.). The cover may have at least one external matt or glossy (e.g., shiny) surface. The electronics mounted in the housing 3001 may include a printed circuit board 3002, an antenna 3003 (e.g. ultra-wide band and/or other types of wireless communication standards), which may be part of or separate from the printed circuit board 3002, a battery 3004 (e.g. a lithium ion, lithium polymer and/or other type of battery such as a rechargeable battery), and/or a port 3005 (e.g. a USB, USB-C or other type of port for transferring data and/or electric power, e.g., as disclosed herein). The port 3005 is connected to the printed circuit board 3002 and the battery 3004 connects to the printed circuit board 3002 via a battery cable 3006. The port 3005 may be employed to charge the battery 3004 (e.g., wired charging) and/or the battery 3004 may be charged wirelessly. The port 3005 may be employed to upload and/or update firmware on the printed circuit board 3002. A thermal transfer tape 3007 (e.g. copper, lead, aluminum, or kapton thermal transfer tape, and/or any other type of thermal transfer tape) may attach between the printed circuit board 3002, the battery 3004 and the housing 3001.

FIG. 31 shows an example of a transitory component 3100 shown as an exploded perspective view, which transitory component may be a badge or tag that is carried by a person and/or an object. A housing and internal electronics may be similar to those discussed relative to FIGS. 30A-30B. The tag 3100 includes a housing having a framing portion 3101 that also supports a printed circuit board 3102 (e.g., the framing portion 3101 is a chassis, shown also in 3121), an antenna 3103, a battery 3104, and/or a port 3105. The port 3105 is connected to the printed circuit board 3102 and the battery 3104 connects to the printed circuit board 3102 via cabling 3106. The port 3105 may be employed to charge the battery 3104 and/or the battery 3104 may be charged wirelessly. The port 3105 may be employed to upload and/or update firmware on the printed circuit board 3102. A thermal transfer tape 3107 (e.g. any thermal transfer tape such as disclosed herein) may attach between the printed circuit board 3102, the battery 3104 and the framing 3101. The tag 3100 includes back and front covers 3108 that are secured (e.g. with adhesive 3109 and/or by other securement mechanisms) to the framing 3101, covering and protecting the internal electronics adjacent to the framing 3101. The adhesive is also shown in 3129. The covers 3108 may be made of a material that minimizes (e.g., does not inhibit) interference with wireless signals transmitted by and received by the antenna 3103 (e.g. plastic and/or any other material(s) that readily allows for passage of wireless signals). Such setup may maximize the range of the antenna 3101 as it communicates with various anchors (see FIG. 20).

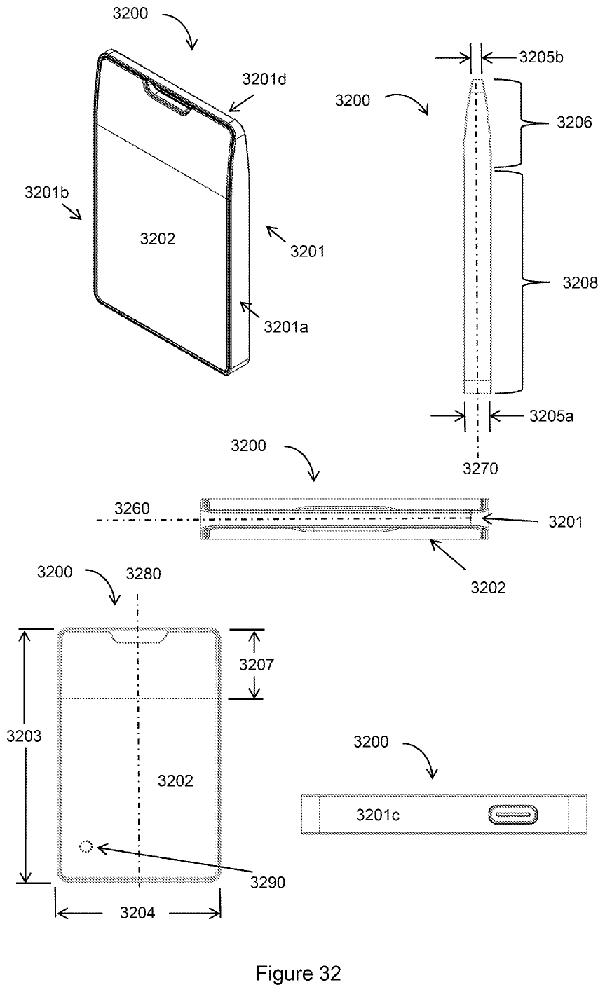

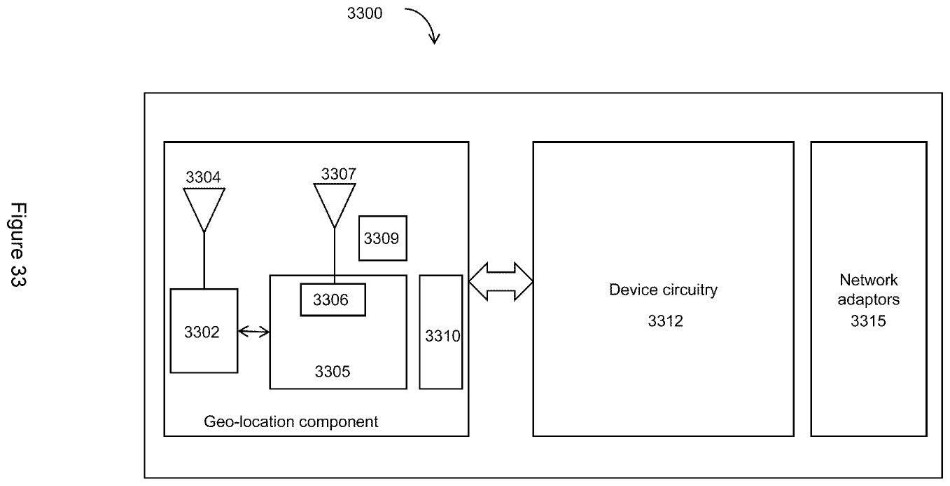

The transitory component (e.g., tag) is three dimensional. The transitory component may have a height, width, and length (e.g., as depicted in FIG. 32). The transitory component (e.g., tag) may a height (e.g., 3203) of at most about 150 mm, 100 mm, 90 mm, 86 mm, 80 mm, 75 mm, 70 mm, or 50 mm. The height may be between any of the aforementioned values, e.g., from about 150 mm to about 50 mm. The transitory circuitry may have a width (e.g., 3204) of at most about 60 mm, 55 mm, 50 mm, 45 mm, 40 mm, 30 mm, or 20 mm. The width may be between any of the aforementioned values, e.g., from about 60 mm to about 20 mm. The transitory circuitry may have a constant or a varying thickness. The transitory circuitry may have a first thickness (e.g., 3205a) of at most about 8 mm, 7.7 mm, 7.5 m, 7.0 mm, 6.5 mm, 6.0 mm, 5.5 mm, or 5.0 mm. The first thickness may be between any of the aforementioned values, e.g., from about 8 mm to about 5 mm. The transitory circuitry may have a second thickness (e.g., 3205b) of at most about 5.0 mm, 4.5 mm, 4.0 mm, 3.5 mm, 3.0 mm, 2.5 mm, 2.0 mm, or 1.5 mm. The first thickness may be between any of the aforementioned values, e.g., from about 5 mm to about 1.4 mm. The thickness of the transitory component may be the first thickness or the second thickness. The thickness of the transitory component may vary from the first thickness to the second thickness. Varying between the first thickness to the second thickness may be gradual. The gradual variation may be linear or curved. The gradual variation may be exponential. The gradual variation may form a curved shape (e.g., having a curved cross section). The gradual variation may form a concave or a convex shape. The gradual variation may be non-symmetric or symmetric along a symmetry line or plane extending through the thickness of the tag (e.g., 3270). The thickness may be constant along a first portion (e.g., 3207) of the tag (e.g., 3208), and gradual (e.g., tarped) along a second portion of the tag (e.g., 3206) that contacts the first portion. The length of the first portion may the same or different than the length of the second portion. The length of the first portion may at least about 1.5 times (*), 2*, 2.5*, 3*, 3.5*, 4*, 4.5*, 5*, 5.5*, or 6* larger than the second portion. An aspect ratio of the width (e.g., 3204) to the height (e.g., 3203) of the tag may be at least about 3:10, 4:10, 5:10, 6:10, 7:10, or 8:10. An aspect ratio of the width (e.g., 3204) to the first thickness of the tag (e.g., 3205a) of the tag may be at least about 4:1, 5:1, 6:1, 7:1 or 8:1. A relationship between the first thickness of the tag (e.g., 3205a) and the second thickness of the tag may be at least about 1.25:1, 1.5:1, 1.75:1, 2:1, 2.25:1, 2.5:1, 2.75:1, or 3:1.

In some embodiments, the tag is configured to signal its operational status. For example, the tag is configured to signal its energetic capabilities (e.g., battery status). The signaling may comprise visual (e.g., using light), tactile (e.g., using vibrations), and/or audial (e.g., using sound such as beeping) signaling. The light may be in the visible spectrum. The visible light may be emitted by an LED light. The visible light may be a signaling light. The signaling light may signal operational states of the tag including: normal operation (e.g., indicated by green or blue light), insufficient power (e.g., depletion of battery power. E.g., indicated by yellow or orange light), and/or malfunction of the tag (e.g., indicated by red light). An intensity of the visible light may fluctuate. The fluctuation may or may not depend on operational states. The light intensity fluctuations may be (e.g., substantially) the same for at least two of the operational states. The light intensity fluctuations may be different for at least two of the operational states. The fluctuations may be between light and no-light, intense and less intense light, or any combination thereof. The frequency of the fluctuation may depend on the operational state. The signal intensity (e.g., light intensity, vibrational intensity, or sound intensity) may fluctuate between high intensity and low intensity. The low intensity may include no intensity. The fluctuation may resemble a top hat function. Transition between the low intensity to high intensity (e.g., ramp up) may be gradual (e.g., linear, logarithmic, or exponential). Transition between the high intensity to low intensity (e.g., ramp down) may be gradual (e.g., linear, logarithmic, or exponential). The ramp up and down curves may follow the same trend (e.g., may be of opposing trends, and have the same absolute value). The ramp up and down curves may follow different trends (e.g., may be of opposing trends, and have different absolute values). For example, the ramp up and down may vary in time and/or in function. At least one of the signaling pattern (e.g., of the light intensity fluctuations, vibrations, or sounds) may resemble an animate (e.g., human) breathing pattern. The tag may comprise a (e.g., manual) on/off switch.

In some embodiments, a cover of the tag housing is configured to facilitate visible light transmission. The cover may have a hole disposed above a light emitter disposed in the tag interior. For example, the cover hole may be aligned with an LED disposed on the PCB board inside the tag. The cover may be made of a material that facilitates light to come through. For example, the material may be of a light color (e.g., white, pastel, transparent, or at least partially transparent), e.g., a light hue (e.g., yellow). The material may be a polymeric material. The cover may be of a width that facilitates sufficient visible light transmission detectable by an average human eye. For example, the cover may have a width of at most 0.5 millimeters (mm), 1 mm, 1.5 mm, or 2 mm. The cover material may have a width between any of the aforementioned widths. The thickness of the cover may be configured to allow penetration of visible light therethrough. The tag (e.g., cover and/or framing) may comprise one or more holes configured to facilitate sound emission, e.g., such that sounds generated by a sound emitter in the tag (e.g., buzzer or loudspeaker) may be auditable by an average human ear.

The tag may comprise a housing having at least one framing portion and at least one cover portion. The framing and/or cover portion may provide structure to the tag housing. The framing and/or cover portion may provide structure to the tag interior. The framing and/or cover portion may be a chassis (e.g., framework) for internal elements of the tag. For example, the framing and/or cover portion may be configured to support the circuitry, antenna, transceiver, emitters (e.g., sound and/or light), connector, wiring, and/or battery. The chassis may comprise any material disclosed herein (e.g., metal or plastic). The chassis may include a surface treatment (e.g., chemical or physical surface treatment). The surface treatment may comprise anodizing, abrading, polishing, or coating the surface. Coating may comprise a protective coat and/or color. coating may comprise powder coating or wet coating.

FIG. 32 shows an example of a transitory component 3200 (e.g., tag), which may be a badge or tag that is carried by a person and/or an object. Since this tag 3200 may be carried with a person, minimizing dimensions and/or weight may be desired. A framing portion 3201 and attached covers 3202 may define the external surfaces of the tag 3200. The framing portion may be a supportive portion configured to support the internal portions of the tag. The framing portion may comprise one or more extensions towards an interior of the tag. The framing portion may have two opposing sides 3201a and 3201b, a bottom portion 3201c configured to external connectivity, and a top portion 3201d configured to facilitate attachment to a carrier. The tag 3200 may have an overall height 3203 of at most about 50 mm, 60 mm, 70 mm, 80 mm, 86 mm, 90 mm, 100 mm, 110 mm and/or about 120 mm. The tag 3200 may have an overall height 3203 of any length value between any one of the aforementioned length values. The tag 3200 may have an overall width 3204 of about 30 mm, 40 mm, 50 mm, 55 mm, 60 mm, 70 mm and/or 80 mm. The tag 3200 may have an overall width value between any one of the aforementioned width values. The tag 3200 may have an overall thickness 3205 of at most about 4 mm, 5 mm, 6 mm, 7 mm, 7.7 mm, 8 mm, 9 mm, and/or 10 mm. The tag 3200 may have an overall thickness value between any one of the aforementioned thickness values. The thickness 3205 of the tag 3200 may be based at least in part on components housed in the tag 3200 (e.g. antenna thickness and/or port thickness). The thickness of the tag may be constant along its side (e.g., 3201a). The thickness of the tag may include a reduction in thickness (e.g., may be tapered) at least in one of the ends of the tag. For example, the thickness 3205a of the tag 3200 may have a taper 3206 at an end having a reduced thickness 3205b. The taper 3206 may narrow the thickness at the end to at most about 3.1 mm. The taper may narrow the thickness at the end to at most about 2 mm, 3 mm, 4 mm, 4.4 mm, and/or 5 mm. The taper 3206 may begin 3207 at about a quarter from the end of the tag. For example, taper 3206 may begin 3207 at least about 40 mm, 30 mm, 25 mm, 20 mm, 15 mm, or 10 mm from an end of the tag. The tag may comprise an area 3290 configured to transmit visible light. The area may or may not comprise a hole in the cover 3202 of the tag. The hole may be configured to align with a light emitter (e.g., LED) disposed in the tag (e.g., in the circuitry of the tag). The light may be projected from one side of the cover and not from its opposing side. The area 3290 may be symmetrically (e.g., using mirror symmetry) disposed on the front (e.g., 4012) and back (e.g., 4013) portions of the tag cover. The area 3290 may be asymmetrically disposed on the front or on the back portion of the tag cover.

In some embodiments, an external portion of the tag housing comprise symmetry. In some embodiments, an internal portion of the tag may be devoid of symmetry. The external tag housing tag may comprise mirror and/or rotational (e.g., C₂) symmetry. The tag may comprise at least one axis of symmetry. For example, a portion of the external tag housing may be symmetric along its length (e.g., 3203) and/or along its width (e.g., 3204). The axis may be symmetrically tarped along its length (e.g., along line 3270 that can be both a mirror plane running along line 3270 and a C₂ rotational symmetry axis). Tarping of the tag towards one of its ends may be symmetric. The two opposing sides of the tag (e.g., 3201a and 3201b) may be mirror images of each other and/or relate to each other along a (e.g., C₂) rotational axis (e.g., along line 3280) and/or a mirror plane (e.g., reflective plane such as one running along line 3280). The frontal and backward covers (e.g., 4012 and 4013) may be non-symmetric. For example, the frontal cover may contain a hole configured to facilitate transmission of an indicator light (e.g., LED light), and the back cover may be devoid of such hole. The frontal and backward covers may be symmetric. For example, the frontal cover may be made of a material configured to facilitate transmission of an indicator light (e.g., LED light) and be devoid of a hole, and the back cover may be made of the same material and also be devoid of such hole. The front and the back of the tag may relate to each other using mirror symmetry (e.g., mirroring though a plane running along line 3260). A portion of the external framing may be symmetric (e.g., the side of the tags such as 3201a and 3201b may be symmetric to each other), while another portion of the tag may be non-symmetric (e.g., entry of the connector (e.g., USB) may be disposed non-symmetrically along a face of the framing portion (e.g., 3201c).

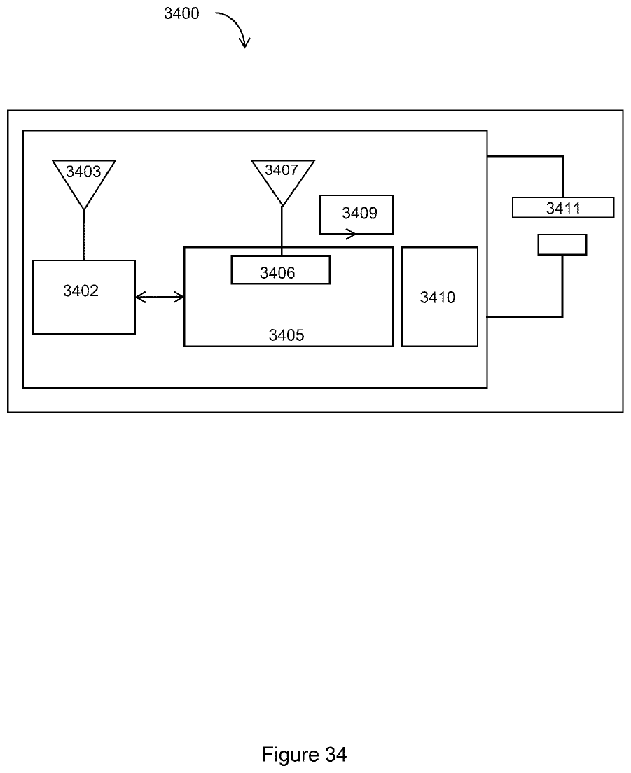

FIG. 34 shows an example of internal components for a transitory component 3400, which may be a badge or tag that is carried by a person and/or an object. The internal components may include an ultra-wideband (UWB) radio 3402 (e.g. a Decawave™ integrated circuit UWB wireless transceiver (DWM1000) or other types of UWB wireless transceivers), and UWB antenna 3403 in communication with the radio 3402. The radio 3402 may be coupled to a programmable microcontroller 3405 (e.g. ARM M4™ microcontroller and/or other type of programmable microcontroller, e.g., as disclosed herein). The microcontroller 3405 may include a short range wireless radio 3406 (e.g. a Bluetooth™ Low Energy (BLE) radio and/or other short range wireless radios). The short range wireless radio 3406 may be in communication with an antenna 3407. The tag 3400 may also include an accelerometer 3409. The accelerometer 3409 may sense movement of the tag 3400 and communicate such information to the microcontroller 3405. A charging circuit 3410 may be included in the tag 3400. The charging circuit 3410 may operatively engage the microcontroller 3405 and a rechargeable battery 3411, which may be charged via a wired port or wirelessly. The locating a tracking of a transitory component (e.g. elements 3100, 3200 and 3400) may be accomplished as discussed herein relative to at least FIG. 3, element 302b, and FIG. 20, elements 2002 that moves in path 2011.

In some embodiments, the transitory component and/or stationary component (e.g., anchor or non-anchor) comprises an accelerometer. The accelerometer may sense movement of the housing in which it is located (e.g., hosing of the tag or housing of the stationary component). Movement sensing by the accelerometer may trigger transmission of a single (e.g., beacon) from the housing in which the accelerometer is disposed (e.g., signaling by the tag or signaling by the stationary component). Usage of the accelerometer may reduce energy expenditure by the tag and/or accelerometer, e.g., by restricting location tracking of the moved housing to times in which the housing (e.g., of the tag or of the housing) has moved or is moving. Usage of the accelerometer of the stationary component may trigger location of the stationary component (e.g., by requesting a traveler to locate the stationary component and/or by initiating an automatic location of the stationary component, e.g., as disclosed herein). The stationary component may or may not be an anchor (e.g., that has a ground-truth corroborated location such as by a traveler).

In some embodiments, the transitory component (e.g., tag) has housing comprising a frame and one or more covers. The frame may be disposed in a rim of the tag. The covers may comprise a frontal cover and a real cover disposed opposite to the frontal cover. The framing portion may comprise one or more sub-portions. The framing portion may be made from one piece of material. The framing portion and/or cover may by generated by three-dimensional printing, machining, and/or injection molding. The cover and framing portion may be of the same type of material or of different material types. For example, the framing portion may comprise metal, and the cover(s) may comprise a polymer. The cover may be configured to nest on, or snap to, the framing portion. The cover may be affixed to the framing portion by at least one adhesive and/or at least one fastener (e.g., screw). A surface of the framing portion and the cover may flush to form one surface. The surface of the framing and the cover may have a height difference (e.g., by one of them being proud or recessed) by at most about 0.02 millimeters (mm), 0.06 mm, 0.09 mm, 0.12 mm, or 0.15 mm. The framing portion may comprise curvature. The framing portion may devoid of external sharp corners (e.g., susceptible to damage). The framing portion may be configured to withstand scratching, dropping from at least about 5 feet (′), 6′, 7′, or 10′. The framing portion may be configured to withstand scratching, dropping from at least about 1 meter (m), 1.5 m, 2 m, 2.5 m, 3 m, or 5 m.

In some embodiments, a framing of the tag and a cover of the tag are coupled using an adhesive. The adhesive may comprise a film. The film may be configured for adhesive contact on opposing sides (e.g., a double sided tape). The film may comprise a porous material (e.g., a foam). The film may comprise a polymer (e.g., an acrylic polymer). The adhesive may be configured for bonding materials in the electronics industry (e.g., 3M™ VHB™ Tape such as 5980). The adhesive may be sensitive to pressure. The adhesive may have a tensile strength of at least about 400 kPa, 500 Kilo Pascal (kPa), 550 kPa, 600 kPa, or 700 kPa. The adhesive may have density of at least about 550 Kg/m³, 600 Kg/m³, 700 Kg/m³, or 800 Kg/m³.

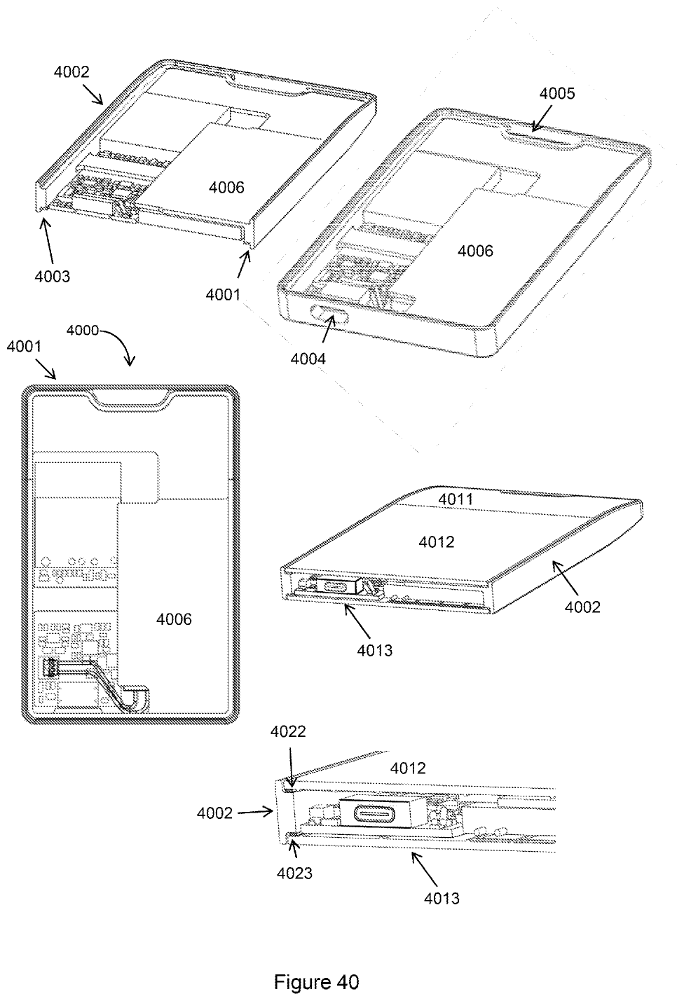

FIG. 40 shows an example of a transitory component 4000 (e.g., tag) that comprises a framing portion that as a curved edge 4002 in a first side and a curved edge 4003 in an opposing side, which curved edge extend to the external surface of the edge on the first side, and of the second side. The framing portion 4002 is made of a single piece of material having a hole 4004 configured to facilitate cabling (e.g., USB) connectivity, and a hole 4005 configured to accommodate a hanger of the tag. The framing portion 4002 extends to the internal portion of the tag and is configured to support one or more interior components of the tag. For example, the framing portion 4002 extends into the tag interior by a portion 4006. The tag comprises cover portions 4011, 4012 that cover a front face of the tag, and cover portions such as 4013 that cover the opposing back face of the tag. The front face covers may be similar to the back face covers. The front covers 4011 and 4012 flush to form an (e.g., average) surface without protrusions. The front covers 4011 and 4012 flush with the front curved edge 4002 of the tag to form an (e.g., average) surface without protrusions. The back covers (e.g., 4013) flush to form an (e.g., average) surface without protrusions. The back covers (e.g., 4013) flush with the back curved edge of the tag 4003 to form an (e.g., average) surface without protrusions. In the example shown in FIG. 40, the front covers (e.g., 4012) are adhered to the framing portion 4002 by an adhesive (e.g., tape) 4022; and the back covers (e.g., 4013) are adhered to the framing portion 4002 by an adhesive (e.g., tape) 4023.

FIG. 39 illustrates an example of a portion of the internal components for a transitory component 3900, which may be a badge or tag that is carried by a person and/or object. The internal components may include an ultra-wideband (UWB) radio 3902 (e.g. a Decawave™ integrated circuit UWB wireless transceiver (DWM1000) or other types of UWB wireless transceivers), a port 3905 (e.g. a USB, USB-C or other type of port for transferring data and/or electric power), a rechargeable battery 3904 (e.g. a lithium ion, lithium polymer and/or other type of rechargeable battery), a voltage divider 3910, and/or a light emitting diode (LED) 3911. The port 3905 may include an electrostatic discharge (ESD) protection module 3912 and connect through this module to a battery charger 3913, which connects to the rechargeable battery 3904 for charging. The rechargeable battery may also connect with a low drop out (LDO) regulator 3915. The port 3905 may connect with the circuit board of the radio 3902 via a USB to universal asynchronous receiver-transmitter (UART) converter 3916. The LED 3911 and the voltage divider 3910 may connect with and be controlled by the circuit board of the radio 3902. The circuitry comprises a thermistor, and a general purpose input/output (GPIO) integrated circuit connectivity (e.g., pin), hat may be controlled by a software. The voltages depicted in the example shown in FIG. 39 are 3.3 Volts (designated as 3V3), or 5.0 Volts (designated as 5V0).

In some embodiments an stationary component may include internal components that include at least one radio (e.g. an ultra-wide band and/or a Bluetooth radio such as a low energy radio), at least one antenna (e.g. an ultra-wide band and/or a Bluetooth antenna such as a low energy antenna), an accelerometer, a power/charging circuit, at least one transceiver circuit, at least one sensor circuit (e.g. for detecting one or more conditions around the stationary component), and/or a network adapter/connection (e.g. a wireless connection and/or an Ethernet connection, which may include power-over-ethernet). The sensor can be part of the transceiver.

In some embodiments, the transitory component comprises a controller. The controller may be a microcontroller. The controller may be configure to operatively (e.g., communicatively) coupled to the network of a facility. The controller of the tag may be configure to (i) perform, request, and/or initiate firmware (e.g., Bootloader and DFU) update, (ii) communications (e.g., BLE communication), (ii) power management (e.g., charging indication and/or battery management), (iii) motion detection (e.g., using an accelerometer internal to the tag), signal (e.g., UWB) configuration, (iv) tag application layer, (v) signal command module (e.g., very low frequency (VLF) command module), (vi) signal (e.g., UWB) transmission and/or receipt (TX/RX) scheduling, (vii) signal (e.g., UWB) Media Access Layer (MAC) implementation, and/or (viii) clock synchronization and/or calibration. The controller may be configured to perform at least a portion of the operations delineated in FIG. 37. In some embodiments, very low frequency comprise radio frequencies (RF) in the range of from about 3 Kilo Hertz (KHz) to about 30 KHz. The VLF electromagnetic waves (e.g., myriameter band or myriameter waves) may correspond to wavelengths from about 100 kilometers (km) to about 10 km.

FIG. 33 shows an example of internal components for an stationary component 3300. Such stationary components 3300 may be similar to those discussed herein relative to, e.g., FIGS. 3-14, 20, and 23-26. Examples of stationary components, their control, and their networking, can be found in U.S. Provisional Patent Application Ser. No. 63/079,851, filed Sep. 17, 2020, titled, “DEVICE ENSEMBLES AND COEXISTENCE MANAGEMENT OF DEVICES,” the disclosure of which is incorporated herein by reference in its entirety. The internal components may include an UWB radio 3302, and UWB antenna 3304 in communication with the radio 3302. The radio may operatively engage a programmable circuitry (e.g., microcontroller) 3305 (e.g. ARM M4™ microcontroller and/or other type of programmable microcontroller). The microcontroller 3305 may include a short range wireless radio 3306 (e.g. a Bluetooth™ Low Energy (BLE) radio and/or other short range wireless radios). The short range wireless radio 3306 may be in communication with an antenna 3307. The stationary component 3300 may also include an accelerometer 3309. The accelerometer 3309 may sense movement of the stationary component 3300 and communicate such information to the microcontroller 3305. A power/charging circuit 3310 may be included in the stationary component 3300. The power/charging circuit 3310 may operatively engage the microcontroller 3305 and a source of power (e.g. battery and/or power supply from a facility in which the stationary component 3300 is located). The internal components of the stationary component 3300 may include sensor circuits 3312 that detect various conditions around the stationary component 3300. The internal components of the stationary component 3300 may include a network adapter/connection 3315 (e.g., wireless connection, power-over-Ethernet (POE) connection, and/or other type of network communication connection).

In some embodiments, a location of a transitory component (e.g., tag) may be determined based at least in part on communication with a plurality of stationary components, e.g., disposed in a facility. The determination of the location of the transitory component may employ (i) a time of flight method (referred to herein as ToF), (ii) a time difference of arrival method (referred to herein as TDoA), or (iv) a hybrid combination of the time of flight and the time difference of arrival methods. The positions for the stationary components may be known (e.g., using a traveler and/or self-location of the stationary components, e.g., as disclosed herein). The stationary components may be at least three, or at least four, stationary components, depending on the methodology utilized. For example, the ToF and/or TDoA methodologies can utilize at least three stationary components (e.g., for two dimensional localization, e.g., localization on a plane defined by the three stationary components), and the TDoA method can utilize at least three stationary components (e.g., for three dimensional localization, e.g., localization on a volume defined by the four stationary components). In some embodiments, the more stationary components are utilized, the greater the location accuracy is achieved.

In some embodiments, a TDoA method is utilized for location of a transitory component (e.g., tag). The TDoA method utilizes a single sided (e.g., one way) ranging that may refer to transmission from the transitory component (e.g., tag) to the stationary components. In the TDoA methodology, the transitory component can send out a signal (also called a blink) that may be received by the stationary components. A time delay for each receipt of the signal is determined. Based at least in part on the time delay information, combined with the known positions of the stationary components, the position of the transitory component is determined. In the single sided (e.g., one way) ranging methodology, a transitory component can send out a signal (also called a blink, or a beacon) at time t₀, which signal comprises a time stamp information corresponding to. The tag transmitted signal may be received by three or more stationary components. The tag transmitted signal may be received by four stationary components. The tag transmitted signal can be received by the stationary components (e.g., four stationary components) at times t₁, t₂, t₃, or t₄, respectively. At least two of the times at which the signal is received by the stationary components may be different, e.g., when those at least two stationary components are disposed at different distances from the tag. At least two of the times at which the signal is received by the stationary components may be (e.g., substantially) the same, e.g., when those at least two stationary components are disposed at the (e.g., substantially) same distance from the tag. After receipt of the signal by the stationary components, its information that corresponds to t₀ is compared to the time at which the signal was received by the stationary component (e.g., t₁, t₂, t₃, or t₄). The time delay between signal sending time to is compared for each stationary component with the signal receipt time (e.g., t₁, t₂, t₃, or t₄). The time delay between signal sending time and signal receipt time (e.g., t₁-t₀, t₂-t₀, t₃-t₀, or t₄-t₀) is converted to the distance traveled by the signal from the tag to each of the stationary components (e.g., using the speed of light and/or trilaterations), and thus the location of the tag can be determined with respect to the stationary components. Using actual location of the stationary components (e.g., as corroborated by a traveler and/or by the self-locating procedure, e.g., as disclosed herein), an actual location of the tag at time t₀ can be determined. The location determination may be performed at a processor of an stationary component. In some embodiments, the timing related information is transmitted (e.g., by the stationary components and/or by the tag) to the network operatively coupled to the stationary components; and the tag location determination is performed by the network (e.g., in the cloud, by a processor, and/or by a controller operatively coupled to the network).

In some embodiments, the localization of the transitory component utilizes an asynchronized TDoA methodology (ATDoA), e.g., that does not require clock synchronization. The TDoA methodology may require at least three, fourth, or five stationary components (e.g., anchors) to interact (e.g., receive signal) from the transitory component. The ATDoA can be used with or without other methodologies (e.g., ToF and TDoA).

In some embodiments, a ToF method is utilized for location of a transitory component (e.g., tag). The ToF method utilizes double sided (e.g., two way, or back-and-forth) ranging. Double sided ranging may refer to a first transmission from a transitory component that is received by the stationary components (e.g., in a similar manner to the one sided signal transmission of the TDoA methodology disclosed herein), followed by a second transmission in the reverse direction from the stationary components that is received by the transitory component. In the double sided ranging methodology, a forward signal sending and a back signal sending is employed between the tag and the stationary components.

In the forward sending portion of the ToF methodology: a transitory component can send out a signal (also called a blink, or a beacon) at time to, which signal comprises a time stamp information corresponding to. The tag transmitted signal may be received by the stationary components (e.g., three stationary components) at times t₁, t₂, or t₃ respectively. At least two of the times of signal receipt by the stationary components may be different, e.g., when these at least two stationary components are disposed at different distances from the tag. At least two of the times of signal receipt by the stationary components may be (e.g., substantially) the same, e.g., when these at least two stationary components are disposed at the (e.g., substantially) same distance from the tag. After receipt of the signal by the stationary components, its information that corresponds to t₀ is compared to the time at which the signal was received by the stationary component (e.g., t₁, t₂, or t₃). The time delay between signal sending time to is compared for each stationary component with the signal receipt time (e.g., t₁, t₂, or t₃). The time delay (e.g., time difference) between signal sending time and signal receipt time (e.g., t₁-t₀, t₂-t₀, or t₃-t₀) is converted to the distance traveled by the signal from the tag to the stationary component (e.g., using the speed of light and/or trilateration), and thus location of the stationary component can be estimated with respect to the stationary components. Using actual location of the stationary components (e.g., as corroborated by a traveler and/or by the self-locating procedure, e.g., as disclosed herein), an actual location of the tag (e.g., at time to) can constitute the first location estimate. To increase accuracy of the location estimate, a back sending of signal is followed.

In the back sending portion of the ToF methodology: the (e.g., three) stationary components each can send out a signal (also called a blink, or a beacon) at times (e.g., t₅, t₆, or t₇, respectively) which each of the three signals comprises a time stamp information corresponding t₅, t₆, or t₇, respectively. The stationary component transmitted signal may be received by the transitory component at time t₈, t₉, or t₁₀, respectively. At least two of the times of signal sending by the stationary components may be different or (e.g., substantially) the same. At least two of the times or signal receipt by the tag may be different or (e.g., substantially) the same. After receipt of at least one stationary component signal by the tag (e.g., at time t₈, t₉, or t₁₀, respectively), its information that corresponds to the signal sending time (e.g., t₅, t₆, or t₇, respectively) is compared to the time at which the signal was received by the tag. The time delay (e.g., time difference) between stationary component signal sending time and tag signal receipt time (e.g., t₈-t₅, t₉-t₆, or t₁₀-t₇) is converted to the distance traveled by the signal from the stationary component to the tag (e.g., using the speed of light and/or trilateration), and thus location of the tag can be estimated with respect to the stationary components to form a second estimate. Using actual location of the stationary components (e.g., as corroborated by a traveler and/or by the self-locating procedure, e.g., as disclosed herein), an actual location of the tag can constitute the second location estimate. The first estimate can be compared to the second estimate to increase the accuracy of determining the location of the tag, e.g., if the tag did not move substantially between the back and forth communication between the stationary components and tag. For example, if the beacons are sent in a velocity and delay that is orders of magnitude faster than the tag (e.g., human) movement. In some embodiments, the timing related information is transmitted (e.g., by the stationary components and/or by the tag) to the network operatively coupled to the stationary components; and the tag location determination is performed by the network (e.g., in the cloud, by a processor, and/or by a controller operatively coupled to the network).

In some embodiments, a combination between the ToF and TDoA methodologies is employed. The ToF methodology can be more accurate than the TDoA methodology in determining the location of the transitory component. In the ToF, no clock synchronization is required across the participating stationary components. The transitory component may require increased power to perform the ToF methodology as compared to the TDoA methodology (e.g., due to the greater signal communication, and optional calculations). This may leave to higher battery of the tag when utilizing the ToF (e.g., two way) methodology as compared to the TDoA (e.g., one way) methodology. The TDoA may require clock synchronization between all participating stationary components. Since the signals are short timed, the clock synchronization may be required to be precise (e.g., to a fraction of the signal short time). The TDoA may facilitate determining more tags simultaneously as compared to the number of tags the ToF method can locate simultaneously. For example, using the TDoA methodology, the tag does not need to wait for a reply (e.g., back signal) arriving from the participating stationary components. The TDoA methodology may be employed, while supplementing with (e.g., occasional and/or prescheduled) ToF measurements. Supplementation of the ToF methodology may be to facilitate (i) clock synchronization among participating stationary components, and/or (ii) accuracy verification of determining tag location. In some embodiments, the timing related information is transmitted (e.g., by the stationary components and/or by the tag) to the network operatively coupled to the stationary components; and the tag location determination is performed by the network (e.g., in the cloud, by a processor, and/or by a controller operatively coupled to the network). The communication between the network and the stationary components can be mono or bidirectional (e.g., wired and/or wireless) communication.

The localization analysis (e.g., using ToF, TDoA, and/or ATDoA) may utilized one or more computations. The computation(s) may comprise a least squares estimation that is based at least in part on a range (e.g., between the stationary component(s) and transitory component). The computations may require solving nonlinear equation(s). The computation may utilize direct computational method, constrained iterative computational method, and/or iterative descent computational method. The Iterative descent computational method may comprise steepest descent, Newton, or Gauss-Newton, computational method. The constrained iterative computational method may comprise Kalmar filtering (e.g., linear quadratic estimation). Kalmar filtering may afford smoother position estimates as compared to the other computational methods. Some of the computational methods disclosed herein are heavier (e.g., require more computational time and/or power) than others.

In some embodiments, the localization system by be a real-time localization system, e.g., that provides localization of the transitory time in real time. The location may be an absolute location or a relative location (e.g., relative to the enclosure and/or the stationary components). The computational methodologies may comprise generation of a first set of estimates of current state variables, along with their uncertainties, based at least in part on a first set of measurements. Once an outcome of the next (e.g., second) set of measurements is observed, the first estimates are updated. The update by utilize a weighted average (e.g., with more weight being given to estimates with higher certainty). The computational methodology may be recursive. The computational method may be performed in real time. The computational method may utilize (e.g., only) present input measurements, previously calculated state, and/or its uncertainty (e.g., compiled as an uncertainty matrix). The computation methodology may assumes that the errors are of a Gaussian nature. The primary sources may be assumed to follow an independent gaussian random processes, e.g., with a zero mean. The dynamic systems may be linear. When the process and/or measurement covariances are known, the computational method may generate a good linear estimator (e.g., in the minimum mean-square-error sense).

In some embodiments, the localization methodology can locate a plurality of moving tags (e.g., in the same enclosure and/or simultaneously). For example, the localization methodology can locate at least about 2, 10, 20, 25, 50, 75, 100, 500, or 1000 tags disposed in the same enclosure (e.g., simultaneously). The localization methodology can locate any number of tags between the aforementioned values.

In some embodiments, determination of the time differentiation between signal sending and its receipt depends on an accurate account of time. The accurate account may be at least one tenth, one hundredth, or one thousandth of a length of the signal time span (e.g., beacon or blip time span), or more accurate. The accurate account may be to at most about one microsecond, nanosecond, picosecond, or femtosecond resolution. The accurate account may be to at most about ten microsecond, nanosecond, picosecond, or femtosecond resolution. The accurate account may be to at most about hundred microsecond, nanosecond, picosecond, or femtosecond resolution. The clock systems for each of the location participating stationary components, may be synchronized.

In some embodiments, the stationary component comprises a clock. The clock may comprise a crystal oscillator.

The stationary component may comprise circuitry that uses mechanical resonance of a vibrating crystal (e.g., of piezoelectric material) to create an electrical signal with a constant frequency. This frequency may be used to keep track of time, e.g., to provide a stable clock signal for digital integrated circuits, and/or to stabilize frequencies for transmitters and receivers (e.g., transceivers). The crystal may be a quartz crystal, however other piezoelectric materials including polycrystalline ceramics may be used. The crystal oscillator may consider slight change in shape of a quartz crystal under an electric field (e.g., electrostriction or inverse piezoelectricity). A voltage applied to an electrode on the crystal may indicate it to change shape; when the voltage is removed, the crystal may generate a small voltage as it elastically returns to its original shape. The crystal may oscillates at a stable resonant frequency. The crystal frequency may have a frequency of at least about 10 kilohertz (KHz), 25 KHz, 50 KHz, 75 KHz, 100 KHz, 250 KHz, 500 KHz, 750 KHz, or 1000 kHz. The crystal frequency may have a frequency of at least about 100 megahertz (MHz), 250 MHz, 500 MHz, 750 MHz, or 1000 (MHz). Once a crystal is adjusted to a frequency, it should maintain that frequency with high stability. However, over time, the frequency of the clock may drift (e.g., due to environmental influences). The oscillation of the clocks may drift. The oscillation of various clocks may be misaligned. The ToA methodology may be utilized to synchronize the clocks. The synchronization may include accounting for (I) clock domain (e.g. when the clock in each stationary component starts), (II) clock offset (e.g. clock frequency of crystal oscillations for the clock in each stationary component being slightly different), and/or (III) clock drift (e.g. changes in ambient temperature and/or aging of the clock crystals may alter its vibrational frequency). In some embodiments the sensors and/or transceivers may be operatively coupled (e.g., wired and/or wirelessly) to one clock, e.g., that is calibrated and/or synchronized (e.g. with Greenwich clock time of the Royal Observatory in Greenwich, London time).

In some embodiments, a transitory component (e.g., tag) sends out a blink, which is received by the participating stationary components. Each of the participating stationary components may detect the time of arrival of a signal. The difference in the arrival time of the signal at each of the participating stationary components (e.g., along with the known location of each of the at least three stationary components) can be utilized to determine the location of the transitory component. A hybrid usage of time of flight (TOF) and time difference of arrival (TDoA) may be employed for determining the location of the transitory component when the transitory component is in communication with the participating stationary components (e.g., whose positions may be known). The ToF method, as described herein, may be employed to determine the position of a transitory component and/or be utilized to synchronize the clocks in the stationary components. The TDoA method may be used to (e.g., repeatedly) determine the position of the transitory component over a (e.g., predetermined) time interval and/or over a (e.g., predetermined) number of transitory components location determinations. After the time interval and/or over a number of transitory components location determinations, as the case may be, the TOF method can (e.g., again) be employed to determine the position of the transitory component and/or synchronize the clocks among the stationary components. The TDoA method can be employed as discussed herein (e.g., above). The hybrid use of the two methods of transitory component location may provide clock synchronization while minimizing power usage by the tag (e.g., thus maximizing the time needed between battery charges of the transitory component battery). For example, the TDoA methodology requires one sided signal transmission between the transitory and stationary components, while the ToF methodology requires a back and forth (e.g., two sided) signal transmission. TDoA method may allow for faster determination of a position of a transitory component, as compared to the ToF method. The TDoA method may allow for tracking of more transitory components in a community than ToF, e.g., since no reply signal from stationary components is used. The TDoA method may use less computational resources on a transitory component than the ToF method, which may allow for a battery on the transitory component to last longer between charges.

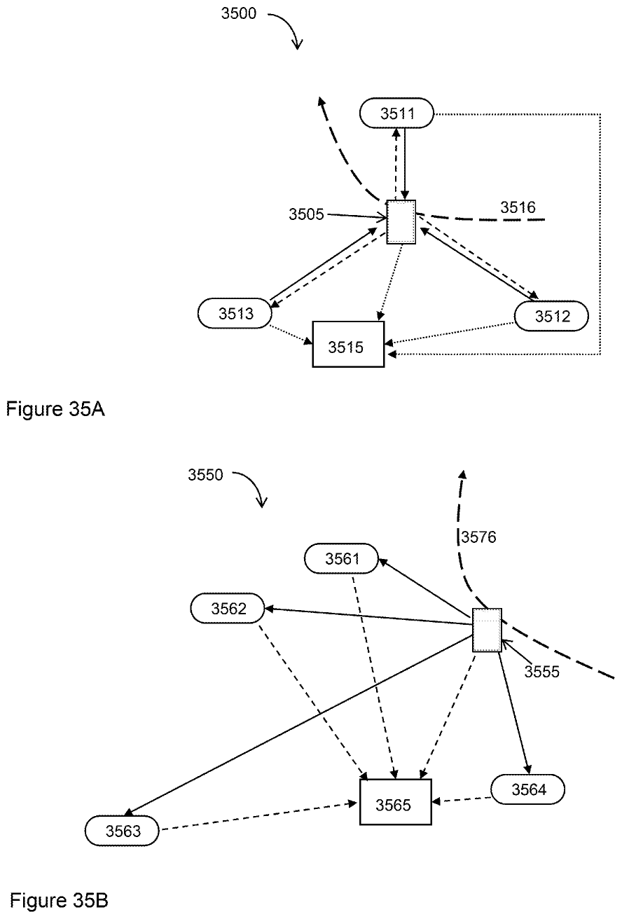

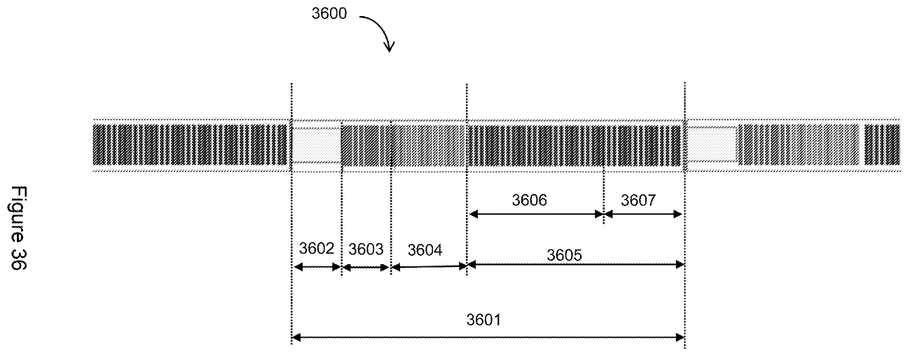

FIG. 35A shows an example of a setup 3500 for determining location of a transitory component 3505 (e.g. elements 3100 in FIG. 31, 3200 in FIG. 32, or 3400 in FIG. 34) using the ToF (e.g., two way signaling) methodology. The location determination is based at least in part on communication of the transitory component with multiple stationary components (e.g. element 3300 in FIG. 33). This method may employ three stationary components or more stationary components. In the example shown in FIG. 35A, the method employs three stationary components 3511, 3512 and 3513. The position of the stationary components 3511-3513 may be known (e.g. using the methods discussed herein, e.g., relative to FIGS. 3-14). Double sided ranging (e.g., two way, or back and forth, or round trip) ranging methodology associated with ToF may be employed. For double sided ranging, a transitory component 3505 sends out a signal (also called a blink, or a beacon) at time to, which signal comprises a time stamp information of t₀, and which signal is received by the stationary components 3511, 3512, and 3513 at times t₁, t₂, and t₃, respectively. On receipt of the signal by each of the stationary components, the time information for to is compared to the time at which the signal arrived at (e.g., is received by) the stationary components. The time delay between signal sending and signal receipt (e.g., t₁-t₀, t₂-t₀, and t₃-t₀) is converted to the distance traveled between the transitory component 3505 and each of the stationary components, and is estimated in a first estimate. This communication is designated in FIG. 35A as broken arrow lines between tag 3505 and stationary components 3511-3513 respectively. Reinforcement of the first estimated distance is performed by a return signal in which each of the stationary components 3511-3513 sends its signal with its time stamp corresponding to times t₅, t₆, and t₇, respectively. The signals are received by the transitory component at times t₈, t₉, and t₁₀, and the distance is then calculated based at least in part on the time differences (e.g., t₈-t₅, t₉-t₆, and t₁₀-t₇) to generate a second distance estimate. The return communication between the stationary components and the tag is designated in FIG. 35A by solid (e.g., non-broken) arrow lines. The transitory nature of the tag is designated by line 3516 designating the traveling path of tag 3505. The stationary components and tag may communicate (e.g., the timing information) to the network and/or any component coupled thereto such as a control system 3515. The two estimates are compared to find the distance between the transitory components and the stationary components. The communication between the stationary components and the tags, and the control system 3515 is designated in FIG. 35A by dotted arrow lines. The comparison can be done on an stationary component, or the network, or on another component coupled to the network.

FIG. 35B shows an example of a setup 3550 for determining location of a transitory component 3555 (e.g. elements 3100 in FIG. 31, 3200 in FIG. 32, or 3400 in FIG. 34) using the TDoA (e.g., one way signaling) methodology. The location determination is based at least in part on communication of the transitory component with multiple stationary components (e.g. element 3300 in FIG. 33). This method may employ at least three (e.g., four) stationary components or more stationary components. In the example shown in FIG. 35B, the method employs four stationary components 3561, 3562, 3563, and 3564. The position of the stationary components 3561-3564 may be known (e.g. using the methods discussed herein, e.g., relative to FIGS. 3-14). Single sided ranging (e.g., one way) ranging methodology associated with TDoA may be employed. For single sided ranging, a transitory component 3555 sends out a signal (also called a blink, or a beacon) at time to, which signal comprises a time stamp information of to, and which signal is received by the stationary components 3561, 3562, 3563, and 3564 at times t₁, t₂, t₃, and t₄, respectively. On receipt of the signal by each of the stationary components, the time information for to is compared to the time at which the signal arrived at (e.g., is received by) the stationary components. The time delay between signal sending and signal receipt (e.g., t₁-t₀, t₂-t₀, t₃-t₀, and t₄-t₀) is converted to the distance traveled between the transitory component 3555 and each of the stationary components, which distance is determined. This communication is designated in FIG. 35B as solid (e.g. non-broken) arrow lines between tag 3555 and stationary components 3561-3564, respectively. The transitory nature of the tag is designated by line 3576 designating the traveling path of tag 3555. The stationary components and tag may communicate (e.g., the timing information) to the network and/or any component coupled thereto such as a control system 3565. The communication between the stationary components, the tags, and the control system 3565 is designated in FIG. 35B by broken arrow lines.

FIGS. 35A and 35B show an example of two methods (ToF and TDoA) for determining location of a transitory component (e.g. elements 3100, 3200 and 3400) based on communication with stationary components (e.g. element 3300). A hybrid use of the two methods may be employed for determining and/or tracking location of the transitory component, e.g., when there are at least three (e.g., four) stationary components in the community of stationary components. The ToF method, e.g., as described herein, may be employed (e.g., occasionally) to determine the position of a transitory component and/or synchronize clocks of the stationary components. The TDoA method may be used to repeatedly and/or routinely determine the position of the transitory component over a predetermined time interval and/or over a predetermined number of transitory component location determinations. After the predetermined time interval and/or over a predetermined number of transitory component location determinations, as the case may be, the ToF method is (e.g., again) be employed, e.g., to determine the position of the transitory component and/or to synchronize the clocks in the stationary components. The TDoA method can (e.g., then) be employed as discussed herein. The hybrid use of the two methods of transitory component location may provide clock synchronization and/or accurate location determination, while maximizing efficiency of power usage (e.g., while maximizing a time needed between charges of the transitory component battery).

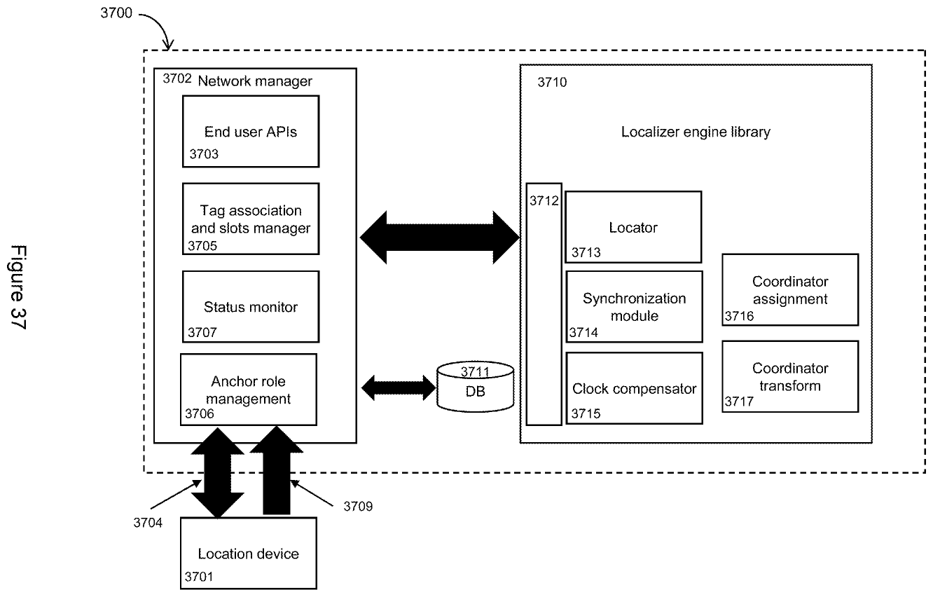

In some embodiments, signal time windows may be employed for determining position of transitory component(s), including transitory component(s) that may remain in a stationary position for longer periods of time (e.g. one or more hours, one or more days, one or more weeks, or one of more months, without moving). Such transitory components that may remain in a stationary position for longer periods of time will be referred to as “assets.” Their positional tracking may be referred to as “asset tracking.” The asset can be a furniture, an equipment, and/or a machine. The asset can belong to an organization (e.g., a company or a medical facility such as a hospital). The organization can be private or public. The longer time periods can be at least about half an hour. The tag (e.g., asset tag) may send a signal every at least about an hour (h), 4 h, 8 h, 12 h, 24 h, 36 h, 48 h, 60 h, or 168 h. The asset tag may send a signal every 1 minute (min.), 5 min, 10 min, 30 min, 1 hour (h), 4 h, 8 h, 12 h, or 24 h. The employing of (e.g., radio) signal time windows for dynamically assigning a coordinator and coordinating the transmission of signals between the coordinator, stationary components and transitory components within a community is discussed herein relative to FIGS. 15A, 15B and 16. The assignment of timing for transmission of range signals for components (e.g. stationary components and/or transitory components) in the community sensed by the coordinator are discussed herein relative to FIGS. 16-19. In the example of time signals shown in FIG. 36, a super time frame is illustrated. The coordination of the transmission from individual components within a super time frame is discussed relative to FIGS. 21A and 21B. A transitory component time interval may be used for transitory components to blink to a coordinator (a stationary component in a community assigned to be a coordinator), with the coordinator assigning signal ranging windows within this transitory component time interval for the transitory components to blink. The blink signals of the transitory components may be used, for example, for signal ranging. The transitory component time interval may be subdivided into two smaller intervals, e.g., (i) a high frequency component time interval and (ii) a low frequency component interval. The high frequency component time interval may be used for high frequency moving transitory components to blink (send a signal) to the coordinator, with each high frequency moving transitory component sending a blink signal within its time slot (ranging window) assigned by the coordinator. The high frequency moving transitory components may be, for example, tags or badges that are carried by personnel (e.g., who regularly and/or randomly move (change locations)). The low frequency component time interval may be a greater or lesser portion relative to the transitory component time interval. The number of transitory components (e.g., tags or badges) may increase or decrease depending upon how many are within the community at any given time. When the number of transitory components in the community is relatively low, then each transitory component may be assigned its own ranging window within the high frequency component time interval. When the number of transitory components in the community is relatively high (e.g., high relative to the number of ranging windows within the high frequency component time interval), the resolution (e.g., the frequency at which a transitory component updates its position, the refresh rate) for each transitory component may be reduced to allow each transitory component to be assigned a ranging window within the high frequency component time interval. For example, if the number of transitory components in the community is greater than the number of ranging windows but less than X number of ranging windows, then each transitory component may reduce its refresh rate to a fraction of X that is 1/X, and (e.g., only) sending a blink signal every other super time frame. For example, if the number of transitory components in the community is greater than the number of ranging windows but less than twice the number of ranging windows, then each transitory component may reduce its refresh rate to half, (e.g., only) sending a blink signal every other super time frame. This reduced frequency of refresh rates may be applied for larger numbers of transitory components relative to the number of ranging windows, with the frequency reduced accordingly (e.g. three to four times the number of transitory components as ranging windows, then the frequency is reduced to one third or one quarter, respectively). The low frequency component time interval may be used for slow frequency transitory components (e.g., assets) to send signal (e.g., blink or beacon) to the coordinator. The slow frequency transitory components may be, for example, asset tracking tags attached to objects that are moved infrequently. Such objects may be moved occasionally (e.g., generally not more than once about every hour, generally not more than once about every day, generally not more than once about every week, generally not more than once about every month, and/or other longer term time intervals including anywhere within the aforementioned time intervals). The low frequency time interval may a greater or lesser portion of the transient component time interval, depending upon the desired ratio of the two transient component subintervals. The transitory components of the assets (e.g., asset tracking tags) may be assigned by the coordinator to signal (e.g., blink) within the low frequency component time interval, e.g., without being assigned a specific ranging window. The coordinator may miss some of the times when the particular asset tracking tag blinks, e.g., since each asset tracking tag may send a blink signal within any portion of the low frequency tracking time interval.

In some embodiments, the tag may be assigned to an individual (a person). The personal tag may send signals at a higher frequency as compared to the asset tag. The tag (e.g., personal tag) may send a signal every most about 5 seconds (sec), 10 sec, 12 sec, 15 sec, 20 sec, 30 sec, 1 minute (min), 5 min, or 10 min. The frequency of signal sending may depend on detection of any movement by an accelerator component of the tag, battery life, at least one characteristic of the carrier (e.g., carrier type), and/or localization method utilized (e.g. TDoA or ToF).

In some embodiments, signal transmission frequency by the transitory component may depend on at least one characteristic of its carrier. The at least one characteristics may comprise movement rate and/or carrier type. For example, the carrier of the transitory component may be a person or an asset. A tag carried by the person may transmit signals at a higher frequency than a tag attached to an asset. For example, the carrier of the transitory component may be a laptop, a desktop, or a heavy manufacturing machinery. The laptop may be more mobile than the desktop that may be more mobile than the heavy manufacturing machinery. The signaling frequency of a tag attached to the laptop may signal in higher frequency than the tag attached to the desktop that may signal at a higher frequency than the tag attached to the heavy manufacturing machinery. The asset tracking tags may be assigned to transmit signal (e.g., blink or beacon) with a frequency (e.g., less often) that depend on (I) the length of the super time frame and/or (II) at least one characteristic of their carrier. For example, the asset tracking tags may be assigned to transmit signal (e.g., blink or beacon) with a lower frequency (e.g., less often) as compared to (I) the length of the super time frame and/or (II) the signal transmission frequency of the transitory frequency that are assigned to non-assets (e.g., that are assigned to personnel). Accordingly, the location of each asset tracking tag may be determined with a lower frequency (less often). The power expenditure of the tag may depend on the signaling frequency and/or processing performed by the tag circuitry. For example, the battery usage may be reduced for the asset tracking tags as compared to the personnel tags as the asset tags blink at a lower frequency than the personnel tags. The lower frequency for determining the position of each asset tracking tag may be acceptable since the objects to which the asset tracking tags have been attached generally do not move very often as compared to the assigned blinking frequency of their associated tags.

In some embodiment, a lowering of the energy expenditure of the tag is requested. For example, when the tag comprises a battery, it may be advantageous to expand the battery life, and/or expand the time between recharging the battery (when the battery is rechargeable). The battery may have at least about 12 hours, 1 day (d), 5 d, 7 d, 14 d, 1 month (M), 3M, 6M, 9M or 12M battery life and/or time between recharge. The energy expenditure of the tag may depend on signals sent, signals received, and/or processing (e.g. performed) performed by the tag (e.g., circuitry thereof). The energy expenditure of the tag may be lowered when a feedback mechanism is utilized for sending the signal in which (i) the tag enters a sleep mode (e.g., standby mode) during a period in which no signal is transmitted when no movement of the tag is detected by an accelerator embedded in the tag, and (ii) the tag exits the sleep mode when a movement of the tag is detected by the accelerator. The tag controller may facilitate entry into, and exit from, the sleep (e.g., standby) mode. There may be a difference in energy expenditure between signal sending mode of the tag, and signal receipt mode of the tag. For example, the signal sending mode may require at least about 5 times (*), 10*, 50*, 100*, or 500* less energy (e.g., power) as compared to the signal receipt mode. The signal seeing mode may require less energy (e.g., be more energy efficient) than the signal receipt mode. The signal receipt mode may require signal processing, e.g., by the tag circuitry (e.g., by the controller and/or processor that is part of the tag). A methodology that requires only one way communication in which the tag sends signals to stationary components (e.g., anchors) such as TDoA, may expand the life of the tag as compared to using a methodology that requires two way communication in which the tag sends and receives signals, such as ToF. A hybrid methodology that minimizes usage of two way communication (e.g., minimizes usage of ToF methodology) may be able to minimize energy expenditure by the tag while providing its accurate localization.

FIG. 36 illustrates an example of (e.g., radio) signal time windows 3600, some of which may be employed for transitory components that may remain in a stationary position for longer periods of time (e.g. one or more hours and/or one or more days without moving). In the example of radio time signals shown in FIG. 36, a super time frame 3601 is illustrated. The coordination of the transmission from individual components within a super time frame is discussed relative to FIGS. 21A and 21B. The length of the super time frame 3601 may be, for example, at most about 1 nanosecond (ns), 10 ns, 50 ns, 100 ns, 1 milliseconds (ms), 10 ms, 100 ms, 200 ms, or 300 ms. The length of the super time frame may be other intervals of time, with examples of the variations in length of time discussed relative to FIGS. 15A-21B. A first time interval 3602 may be used for the coordinator sending a signal to the other components indicating a beginning of a location signaling process (see FIGS. 15A-21B for a discussion of this time interval). The first time interval 3602 may be, for example, of a length of at most about 10 ms. The first time interval may be a longer or shorter period of time, with examples of the variations in the length of time discussed relative to FIGS. 15A-21B. A second time interval 3603 may be used for the non-stationary components to join the community. The second time interval 3603 may be, for example, of a length of at most about 20 ms. The second time interval 3603 may be a longer or shorter period of time, with examples of the variations in the length of time discussed relative to FIGS. 15A-21B. A third time interval 3604 may be used for stationary components to blink (send a signal) to the coordinator, with each stationary component sending a blink signal within its time slot assigned by the coordinator. The blink signals of the stationary components may be used, for example, for range signaling, and so may be referred to herein as range signaling windows. The third time interval 3604 may be, for example, of a length of at most about 20 ms. The third time interval 3604 may be a longer or shorter period of time, with examples of the variations in the length of time discussed relative to FIGS. 15A-21B. A fourth time interval 3605 may be used for transitory components to blink to the coordinator, with the coordinator assigning signal ranging windows for the transitory components to blink. The blink signals of the transitory components may be used, for example, for signal ranging. The fourth time interval 3605 may be, for example, of a length of at most about 150 ms. The fourth time interval 3605 may be a longer or shorter period of time, with examples of the variations in the length of time discussed relative to FIGS. 15A-21B. The fourth time interval 3605 may be subdivided into two smaller intervals, fifth time interval 3606 and a sixth time interval 3607. The fifth time interval 3606 may be used for high frequency moving transitory components to blink (send a signal) to the coordinator, with each high frequency moving transitory component sending a blink signal within its time slot (ranging window) assigned by the coordinator. The high frequency moving transitory components may be, for example, tags or transitory components that are carried by people who regularly and randomly move (change locations). The fifth time interval 3606 may be, for example, of a length of at most about 100 ms. The fifth time interval 3606 may be a greater or lesser portion of the fourth time interval 3605. The number of transitory components may increase or decrease depending upon how many are within the community at any given time. When the number of transitory components in the community is relatively low, then each transitory component may be assigned its own ranging window within the fifth time interval 3606. For example, if the fifth time interval 3606 includes at least about 100 ranging windows. The number of transitory components in the community may be less than about 100 (e.g., in that case, each transitory component may be assigned its own ranging window). The number of ranging windows within the fifth time interval 3606 was given merely as an example for illustrative purposes. When the number of transitory components in the community is relatively high (e.g., high relative to the number of ranging windows within the fifth time interval 3606), the resolution (e.g., the frequency at which each transitory component updates its position, the refresh rate) for each transitory component may be reduced, e.g., to allow at least one (e.g., each) transitory component to be assigned a ranging window within the fifth time interval 3605. For example, if the number of transitory components in the community is greater than the number of ranging windows, but less than X number of ranging windows, then each transitory component may reduce its refresh rate to 1/X, (e.g., only) sending a blink signal every other super time frame 3601. The sixth time interval 3607 may be used for slow frequency transitory components to blink the coordinator. The slow frequency transitory components may be, for example, asset tracking tags attached to objects that are moved infrequently. The sixth time interval 3607 may be, for example, of a time interval that spans at most about 50 ms. The sixth time interval 3607 may a greater or lesser portion of the fourth time interval 3506, e.g., depending upon the desired ratio of the sixth to the seven time interval. The asset tracking tags may be assigned by the coordinator to blink within the sixth time interval 3607, e.g., without being assigned a specific ranging window. When each asset tracking tag sends a blink signal within any portion of the sixth time interval 3607, the coordinator may miss some of the times when the particular asset tracking tag blinks. The asset tracking tags may be assigned to blink less often than the length of the super time frame 3601. The location of each asset tracking tag may be determined with a lower frequency.

In some embodiments, a software and hardware that forms part of a location framework for a facility includes wired and/or wireless communication that connects devices (e.g. stationary components, transitory components and other devices, e.g., as disclosed herein) via one or more networks together to one or more central computing and/or control systems (e.g. central computers, cloud based computer systems). A location device (e.g. stationary component and/or transitory component) may communicate (e.g. via wired (e.g. ethernet) and/or wireless (e.g. UWB) transmission) with a network manager, which may include end user application programming interfaces (APIs). The communication may include a bidirectional control channel relating to location network management functions, with data relating to, for example, network association of transitory components, stationary component role management (e.g. dynamic selection of stationary components as coordinators for various communities), status monitoring (e.g. low battery level in a component), and/or coordinate system mapping. A wireless location device may communicate with the network manager via a one-way data channel that originates from a location device. The data channel may transmit location related data (e.g., ToF and/or TDoA related data) of the transitory components to the network manager. The network manager may communicate with a localizer engine library and/or a database, which may store data relating to stationary components and/or transitory components (e.g. location data for each transitory component). The localizer engine library may include, for example a localizer application programming interface (API), a location computational scheme, a synchronization module, a clock synchronization module (e.g., to account for time drifts), and/or at least one coordinator (e.g., a location coordinator assignment computational scheme, and/or a coordinator computational scheme). The synchronization module synchronizes the clock and provides an output to the at least one coordinator. For example, the coordinator may record that 1 second (s) in the coordinator clock (e.g., in a clock of a stationary component in which the coordinator is disposed or to which the coordinator is operatively coupled to) equals 1.00001 s in the tag clock, thus the coordinator clock and the transitory component (e.g., tag) clock have a synchronization factor of 1.000001. The time compensation module utilizes the synchronization factor for removing the clock misalignment in the transmission or receipt (TX/RX) signal. For example, when a signal is received from a tag, which signal has a timestamp 1000001 generated by the tag according to the tag clock, the time compensation module would convert the tag to 1000000 to align with the stationary component time. The synchronization module and/or time compensation module may be required when the clock is integrated in a fixed hardware that cannot be altered, and/or when the clocks cannot be otherwise physically synchronized with the coordinator clock. The clock synchronization may be achieve by utilizing one or more modules (e.g., software), e.g., as disclosed herein.

FIG. 37 shows an example of software and hardware that forms part of a location framework 3700, which may include wired and wireless communication that connects devices (e.g. stationary components, transitory components and other devices) via one or more networks together to one or more central computing systems (e.g. central computers, cloud based computer systems). An example of a central computing system and networks connected together is discussed herein relative to FIG. 1. Examples of determination of the number of stationary components and transitory components that make up each community, location of the stationary components and transitory components, locations of transitory components relative to each other for further analysis (e.g. tracing locations of transitory components in a grid and/or use of transitory component locations for contact tracing), the analysis, and control and networking of the components, can be found in U.S. Provisional Patent Application Ser. No. 63/115,886, filed Nov. 19, 2020, titled, “IDENTIFYING AND REDUCING HEALTH RISKS IN A FACILITY,” which is incorporated by reference herein in its entirety. Examples of components (e.g., devices or device ensembles), their location and data analysis, their control and networking, can be found in U.S. Provisional Patent Application Ser. No. 63/033,474, filed Jun. 2, 2020, titled, “ENVIRONMENTAL ADJUSTMENT USING ARTIFICIAL INTELLIGENCE.” which is incorporated by reference herein in its entirety.

As shown in FIG. 37, a location device 3701 (e.g. stationary component and/or transitory component) communicates (e.g. via wired (e.g. ethernet) and/or wireless (e.g. UWB) transmission) with a network manager 3702, which may include end user application programming interfaces (APIs) 3703. The communication may include a bidirectional control channel 3704 relating to location network management functions, with data relating to, for example, network association of transitory components 3705, stationary component role management 3706 (e.g. dynamic selection of stationary components as coordinators for various communities), status monitoring 3707 (e.g., alerting for low battery level in a component), and/or coordinate system mapping. A wireless location device 3701 may communicate with the network manager 3702 via a one-way data channel 3709 that originates from a location device 3701. The data channel 3709 may transmit ToF and/or TDoA data of the transitory components to the network manager 3702. The network manager 3702 may communicate with a localizer engine library 3710 and/or a database 3711, which stores data relating to stationary components and/or transitory components (e.g. location and/or timing data for the transitory components and/or stationary components). The localizer engine library 3710 may include, for example a localizer API 3712, a location computational scheme (e.g., calculation) 3713, a synchronization module 3714, and a drift compensation and clock error compensation module 3715, a location coordinator assignment computational scheme 3716, and/or a coordinator computational scheme 3717.

In some embodiments, transitory component (e.g., tag) location and tracking is achieved. A tag may transmit a wireless (e.g. UWB) signal, which may be detected by one or more stationary components in a facility. Upon detection of a tag by one or more stationary components, the tag may be joined to a network and assigned to a community. The location of the tag may be determined and/or tracked. The locating of the tag may be accomplished employing ToF and/or TDoA. Tracking of tag locations may be transmitted to a network manager and/or may be stored in a database. A determination may be made as to whether the location of the tag relative to over tags is requested. If not, the locating and tracking of the tag may continue. If so, identification of tags meeting requested criteria (e.g. time frame in question and/or location near a particular other tag) may be identified. Upon identifying tags meeting the requested criteria, the length of time within the determined relative locations of the tag to the identified tags may be calculated. For example, the control system may notify a user and/or tag holder in case the tag approached another tag at a distance below a minimum distance threshold, for a period of time exceeding the minimum time threshold. Such application may be utilized for social distance tracing. Examples for usage of components (e.g., devices and/or tags) for contact tracing, related analysis, and component control and networking, can be found in U.S. Provisional Patent Application Ser. No. 63/115,886, filed Nov. 19, 2020, entitled, “IDENTIFYING AND REDUCING HEALTH RISKS IN A FACILITY,” which is incorporated by reference herein in its entirety.

In some embodiments, a Building Information Modeling (BIM) (e.g., Revit file) is utilized at least in part to determine and/or estimate location of the stationary components in a facility. Examples of components (e.g., devices or device ensembles), their location (e.g., using a BIM file) and data analysis, their control and networking, can be found in U.S. Provisional Patent Application Ser. No. 63/033,474, filed Jun. 2, 2020, titled, “ENVIRONMENTAL ADJUSTMENT USING ARTIFICIAL INTELLIGENCE,” which is incorporated by reference herein in its entirety.

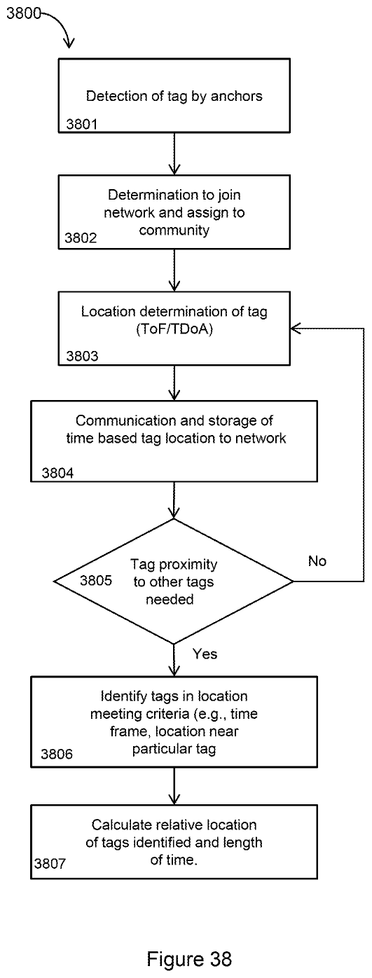

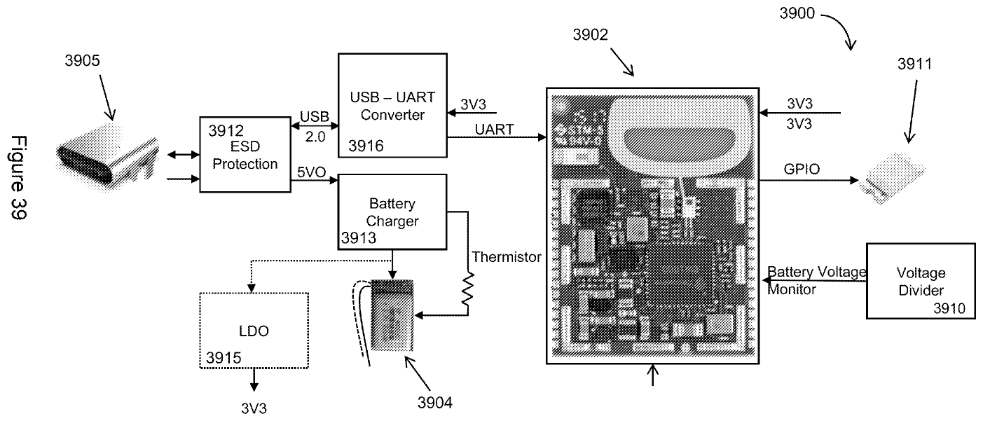

FIG. 38 shows an example of a flow chart illustrating transitory component (tag) location and tracking 3800. The tag may be, for example, a tag as described herein in relation to FIGS. 30A-32 and 34. A tag may transmit a wireless (e.g. UWB) signal, which is detected by one or more stationary components in a facility 3801. Upon detection of a tag by the one or more stationary components, the tag may be joined to the network and assigned to a community 3802. FIG. 37 illustrates an example of a network manager that may perform such a function. The detection of the tag and assignment to a community has been described herein, e.g., relative to FIGS. 3-7 and 20. The location of the tag may be determined 3803 and tracked 3804. The locating of the tag may be accomplished employing ToF and/or TDoA, discussed herein, in relation to FIGS. 35A-35B. Tracking of the tag locations may be transmitted to a network manager and stored in a database, such as those discussed herein, e.g., in relation to FIG. 37. A determination may be made as to whether the location of the tag relative to over tags is requested 3805. The determination may be made to certain tags (e.g., personnel tags) and not to other tags (e.g., asset tags), e.g., based on one or more characteristics of the tag carrier (e.g., to which the tag was assigned). If not, the locating and tracking of the tag continues. If so, identification of tags meeting requested criteria (e.g. time frame in question and/or location near a particular other tag) are identified 3806. This may employ the database and localizer engine library, discussed relative to FIG. 37. Upon identifying tags meeting the requested criteria, the length of time within the determined relative locations of the tag to the identified tags are calculated 3807. This analysis (e.g., calculation) may be employed for reporting (e.g. contact tracing). Examples of such contact tracing related analysis, reporting, components and their control and networking, can be found, in U.S. Provisional Patent Application No. 63/115,886, filed Nov. 19, 2020, titled, “IDENTIFYING AND REDUCING HEALTH RISKS IN A FACILITY,” which, is incorporated by reference in its entirety.

In some embodiments, the transitory component (e.g., tag) is linked to a carrier. The tag may be linked (e.g., in a database) to an identity of its carrier that can be animate or inanimate (e.g., person or asset). When carried by the carrier the tag may identify location of the carrier at a particular time. For example, a tag having a first identification is linked to a person having a certain name. For example, a tag having a second identification is linked to a machine having a certain name and/or Serial Number.

While preferred embodiments of the present invention have been shown, and described herein, it will be obvious to those skilled in the art that such embodiments are provided by way of example only. It is not intended that the invention be limited by the specific examples provided within the specification. While the invention has been described with reference to the afore-mentioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations, or relative proportions set forth herein which depend upon a variety of conditions and variables. It should be understood that various alternatives to the embodiments of the invention described herein might be employed in practicing the invention. It is therefore contemplated that the invention shall also cover any such alternatives, modifications, variations, or equivalents. It is intended that the following claims define the scope of the invention and that methods and structures within the scope of these claims and their equivalents be covered thereby.

1. A method of locating a transceiver, the method comprising:
(a) using a coordinator transceiver to coordinate transmission of a plurality of signals by a plurality of transceivers that includes the coordinator transceiver, a first transceiver and a second transceiver;
(b) using the first transceiver to transmit a first signal at a first time scheduled by the coordinator transceiver; and
(c) using the second transceiver to sense the first signal at a second time to facilitate determination of a location of the first transceiver relative to the second transceiver.

2. The method of claim 1, wherein the plurality of transceivers are stationary and are disposed in a facility, and wherein the plurality of transceivers are configured to locate a transitory transceiver in the facility.

3. The method of claim 1, wherein at least one transceiver of the plurality of transceivers is disposed in a housing comprising (i) sensors or (ii) a sensor and an emitter.

4. The method of claim 1, wherein the plurality of transceivers are operatively coupled to a network of a facility in which the plurality of transceivers are disposed.

5. The method of claim 4, wherein the network (i) is configured to facilitate power and data communication on a single cable, (ii) is configured to facilitate at least a third generation, fourth generation or fifth generation cellular communication, (iii) comprises at least a portion that is the first network installed in the facility, (iv) comprises at least a portion disposed in an envelope of the facility, (v) is configured to facilitate control of the facility, (vi) is configured to facilitate media communication, data communication, cellular communication, and power communication, (vii) comprises a coaxial cable, an optical cable, and/or a twisted wire and/or (vii) comprises wired and/or wireless communication.

6. The method of claim 1, wherein the coordinator transceiver coordinates transmission of a second signal by the second transceiver.

7. The method of claim 1 wherein the first signal comprises identification data, time data, and/or location data.

8. The method of claim 7, wherein:
the location data comprises a distance and/or an angle,
the distance comprises a distance between two transceivers, and
the angle is an angle between two transceivers.

9. The method of claim 8, wherein the time and/or location data is utilized to find a topology of the plurality of transceivers.

10-15. (canceled)

16. A method of locating a transitory transceiver, the method comprising:
(a) transmitting at a first time a wireless signal from the transitory transceiver operatively coupled to a clock, which wireless signal is received by at least three stationary sensors at one or more second time, which at least three stationary sensors (I) have known locations in a facility and (II) are operatively coupled to at least three clocks that are synchronized among the at least three stationary sensors;
(b) calculating one or more time differences between (i) the one or more second times and (ii) the first time, to generate one or more results; and
(c) using the one or more results to locate the transitory transceiver with respect to the at least three stationary sensors.

17. The method of claim 16, wherein the at least three stationary sensors are included in at least three stationary transceivers, wherein the one or more time differences are one or more first time differences, wherein the one or more results are one or more first results, and wherein the method further comprises:
(d) transmitting at one or more third times at least three wireless signals from the at least three stationary transceivers, which at least three wireless signals are received by the transitory transceiver at one or more fourth third times;
(e) calculating one or more second time differences between (A) the one or more fourth times and (B) the one or more third times, to generate one or more second results; and
(f) using the one or more first results and the one or more second results to re-synchronize the at least three clocks.

18. The method of claim 17, wherein each of the at least three stationary transceivers transmit a wireless signal of the at least three wireless signals.

19. The method of claim 17, wherein synchronization of the at least three clocks corrects for a clock domain, a clock offset, and/or time drift for the at least three stationary transceivers.

20. The method of claim 17, wherein synchronization of the at least three clocks corrects for a clock domain, a clock offset, and/or time drift for each of the at least three stationary transceivers.

21. The method of claim 17, wherein the synchronization further comprises synchronization of the clock of the transitory transceiver.

22-29. (canceled)

30. A method of locating a transitory transceiver, the method comprising:
(a) transmitting at a first time a wireless signal from the transitory transceiver operatively coupled to a clock, which wireless signal is received by at least three stationary transceivers at one or more second time, which at least three stationary transceivers (i) have at least three known locations in a facility and (ii) are operatively coupled to at least three clocks;
(b) calculating one or more first time differences between (iii) the one or more second times and (iv) the first time, to generate one or more first results;
(c) transmitting at one or more third times at least three wireless signals from the at least three stationary transceivers, which at least three wireless signals are received at one or more fourth times by the transitory transceiver;
(d) calculating one or more second time differences between (v) the one or more fourth times and (vi) the one or more third times, to generate one or more second results; and
(e) using the one or more first results and the one or more second results to (vii) locate the transitory transceiver and/or (viii) synchronize the at least three clocks.

31. The method of claim 30, wherein synchronization of the at least three clocks corrects for a clock domain, a clock offset, and/or time drift for the at least three stationary transceivers.

32. The method of claim 30, wherein synchronization of the at least three clocks corrects for a clock domain, a clock offset, and/or time drift for each of the at least three stationary transceivers.

33. The method of claim 30, wherein the synchronization further comprises synchronization of the clock of the transitory transceiver.

34. The method of claim 30, wherein the at least three stationary transceivers each (A) has a known location of the locations in the facility and (B) is operatively coupled to a clock of the at least three clocks.

35-68. (canceled)
